(19) United States
(12) Patent Application Publication
(10) Pub. No.: US 2023/0165132 A1
(43) Pub. Date: May 25, 2023

(54) ORGANIC LIGHT EMITTING DIODE AND ORGANIC LIGHT EMITTING DEVICE INCLUDING THEREOF

(71) Applicant: LG Display Co., Ltd., Seoul (KR)

(72) Inventors: Suk-Young BAE, Paju-si (KR); Dong-Ryun LEE, Paju-si (KR); Jong-Uk KIM, Paju-si (KR); Han-Jin AHN, Paju-si (KR); Jun-Yun KIM, Paju-si (KR)

(73) Assignee: LG Display Co., Ltd., Seoul (KR)

(21) Appl. No.: 17/976,239

(22) Filed: Oct. 28, 2022

(30) Foreign Application Priority Data
Nov. 19, 2021 (KR) 10-2021-0160442

(51) Int. Cl. H01L 51/00; C07F 5/02; C09K 11/06

(52) U.S. Cl. CPC H01L 51/008; C07F 5/027; C09K 11/06; H01L 51/5044

(57) ABSTRACT

An organic light emitting diode (OLED) and an organic light emitting device comprising the OLED are described. The OLED can comprise at least one emitting material (EML) disposed between two electrodes, where the EML can comprise a first compound comprising a fused ring having boron and oxygen and substituted with at least two fused hetero aromatic group, and a second compound comprising a fused ring having boron and nitrogen. The first compound and the second compound can be the same emitting material layer or be present in adjacently disposed emitting material layers. The luminous efficiency and luminous lifespan of the OLED can be improved by applying the first and second compounds, and adjusting their photoluminescence wavelength, absorbance wavelength and energy levels.

### CROSS-REFERENCE TO RELATED APPLICATIONS

This application claims the priority benefit under 35 U.S.C. § 119(a) to Korean Patent Application No. 10-2021-0160442, filed in the Republic of Korea on Nov. 19, 2021, the entire contents of which are incorporated herein by reference into the present application.

### BACKGROUND

### Technical Field

The present disclosure relates to an organic light emitting diode, and more specifically, to an organic light emitting diode having excellent luminous properties and an organic light emitting device having the organic light emitting diode.

### Discussion of the Related Art

As display devices have become larger, there exists a need for a flat display device which take up less space. Among the flat display devices, a display device using an organic light emitting diode (OLED) has come into the spotlight.

The OLED can be formed as a thin film having a thickness less than 2000 Å and can be used to implement unidirectional or bidirectional images as electrode configurations. Also, the OLED can be formed on a flexible transparent substrate such as a plastic substrate so that OLED can be used in a flexible or foldable display with ease. In addition, the OLED has advantages over liquid crystal display devices (LCD devices); for example, the OLED can be driven at a low voltage of 10 V or less and has very high color purity.

In the OLED, when electrical charges are injected into an emitting material layer between an electron injection electrode (i.e., cathode) and a hole injection electrode (i.e., anode), electrical charges are recombined to form excitons, and then emit light as the recombined excitons are shifted to a stable ground state.

Luminescent materials such as fluorescent and phosphorescent materials can be used in OLEDs. Of these, fluorescent materials from the related art have shown low luminous efficiency, because only the singlet excitons are involved in the luminescence process thereof. Phosphorescent materials, in which triplet excitons as well as the singlet excitons are involved in the luminescence process have relatively high luminous efficiency compared to the fluorescent material.

However, many metal complexes from the prior art, which are used as phosphorescent materials may have a luminous lifespan that is too short for many commercial devices. In particular, blue phosphorescent materials, which have a longer triplet lifetime compared to blue fluorescent materials, have short luminous lifespan as the triplet energy level thereof increases. Accordingly, the blue phosphorescent materials with relatively high triplet energy level for inducing deep blue color light can have a disadvantage of reduced luminous lifespan.

### SUMMARY OF THE DISCLOSURE

Accordingly, embodiments of the present disclosure are directed to an OLED and an organic light emitting device including the OLED that substantially obviates one or more of the problems due to the limitations and disadvantages of the related art.

An aspect of the present disclosure is to provide an OLED that can improve luminous efficiency, color purity and luminous lifespan and an organic light emitting device including the diode.

Additional features and aspects will be set forth in the description that follows, and in part will be apparent from the description, or can be learned by practice of the inventive concepts provided herein. Other features and aspects of the inventive concepts can be realized and attained by the structure particularly pointed out in the written description, or derivable therefrom, and the claims hereof as well as the appended drawings.

To achieve these and other aspects of the inventive concepts, as embodied and broadly described, an organic light emitting diode can comprise a first electrode; a second electrode facing the first electrode; and an emissive layer disposed between the first and second electrodes and comprising at least one emitting material layer, wherein the at least one emitting material layer can comprise at least one of a first compound and/or a second compound, and wherein the first compound has the following structure of Formula 1 and the second compound has the following structure of Formula 7:

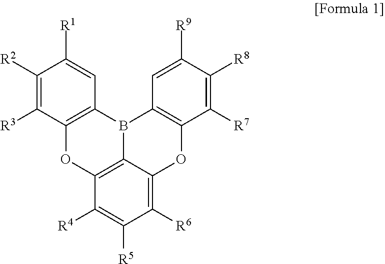

wherein, in Formula 1,

each of R¹ to R⁹ is independently hydrogen, deuterium, tritium, halogen, unsubstituted or substituted C₁-C₂₀ alkyl, unsubstituted or substituted C₁-C₂₀ alkyl amino, an unsubstituted or substituted C₆-C₃₀ aromatic group or an unsubstituted or substituted C₃-C₃₀ hetero aromatic group, wherein two to four of R¹ to R⁹ are a moiety having the following structure of Formula 2,

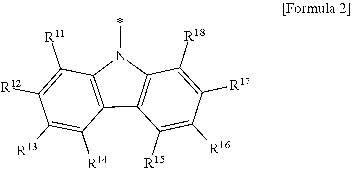

wherein, in Formula 2,

each of R¹¹ to R¹⁸ is independently hydrogen, deuterium, tritium, halogen, unsubstituted or substituted C₁-C₂₀ alkyl, unsubstituted or substituted C₁-C₂₀ alkyl silyl, unsubstituted or substituted C₁-C₂₀ alkyl amino, an unsubstituted or substituted C₆-C₃₀ aromatic group or an unsubstituted or substituted C₃-C₃₀ hetero aromatic group, or

adjacent two of R¹¹ to R¹⁸ form an unsubstituted or substituted hetero aromatic ring having the following structure of Formula 3,

wherein at least adjacent two of R¹¹ to R¹⁸ form an unsubstituted or substituted hetero aromatic ring having the following structure of Formula 3; and

asterisk indicates a linking position,

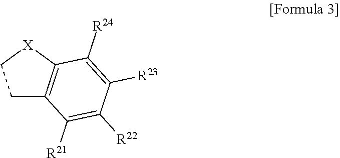

wherein, in Formula 3,

X is NR²⁵, O or S;

each of R²¹ to R²⁵ is independently hydrogen, deuterium, tritium, halogen, unsubstituted or substituted C₁-C₂₀ alkyl, unsubstituted or substituted C₁-C₂₀ alkyl silyl, unsubstituted or substituted C₁-C₂₀ alkyl amino, an unsubstituted or substituted C₆-C₃₀ aromatic group or an unsubstituted or substituted C₃-C₃₀ hetero aromatic group; and

a dotted line indicates a fused portion,

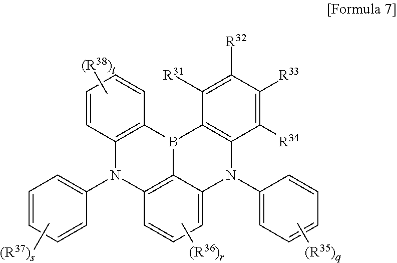

wherein, in Formula 7,

each of R³¹ to R³⁴ is independently hydrogen, deuterium, tritium, halogen, unsubstituted or substituted C₁-C₂₀ alkyl, unsubstituted or substituted C₁-C₂₀ alkyl silyl, unsubstituted or substituted C₁-C₂₀ alkyl amino, an unsubstituted or substituted C₆-C₃₀ aromatic group or an unsubstituted or substituted C₃-C₃₀ hetero aromatic group, optionally,

two adjacent elements of R³¹ to R³⁴ form an unsubstituted or substituted fused ring having boron and nitrogen;

each of R³⁵ to R³⁸ is independently deuterium, tritium, halogen, unsubstituted or substituted C₁-C₂₀ alkyl, unsubstituted or substituted C₁-C₂₀ alkyl silyl, unsubstituted or substituted C₁-C₂₀ alkyl amino, an unsubstituted or substituted C₆-C₃₀ aromatic group or an unsubstituted or substituted C₃-C₃₀ hetero aromatic group, wherein each R³⁵ is identical to or different from each other when q is an integer of two or more, each R³⁶ is identical to or different from each other when r is an integer of two or more, each R³⁷ is identical to or different from each other when s is an integer of two or more and each R³⁸ is identical to or different from each other when t is an integer of two or more;

each of q and s is independently an integer of 0 to 5;

r is an integer of 0 to 3; and

t is an integer of 0 to 4.

An onset wavelength of the first compound can be less than a maximum absorbance wavelength of the second compound. As an example, the onset wavelength of the first compound can be between about 430 nm and about 440 nm.

The first compound can comprise an organic compound having the following structure of Formula 4:

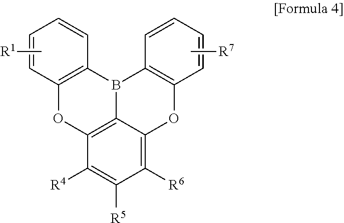

wherein, in Formula 4,

each of R¹, R⁴, R⁵, R⁶ and R⁷ is independently hydrogen, deuterium, protium, halogen, unsubstituted or substituted C₁-C₂₀ alkyl, unsubstituted or substituted C₁-C₂₀ alkyl amino, unsubstituted or substituted C₆-C₃₀ aryl or unsubstituted or substituted C₃-C₃₀ hetero aryl, wherein two of R¹, R⁴, R⁵, R⁶ and R⁷ have the structure of Formula 2.

As an example, the moiety having the structure of Formula 2 can be selected from the following moieties:

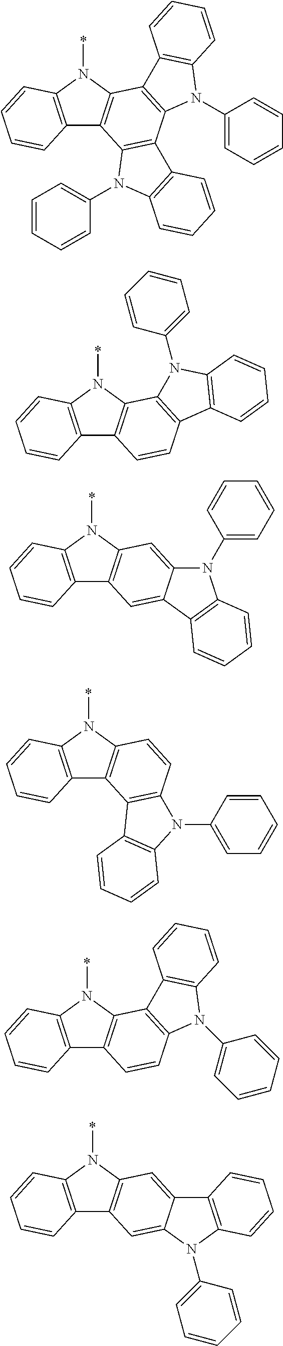

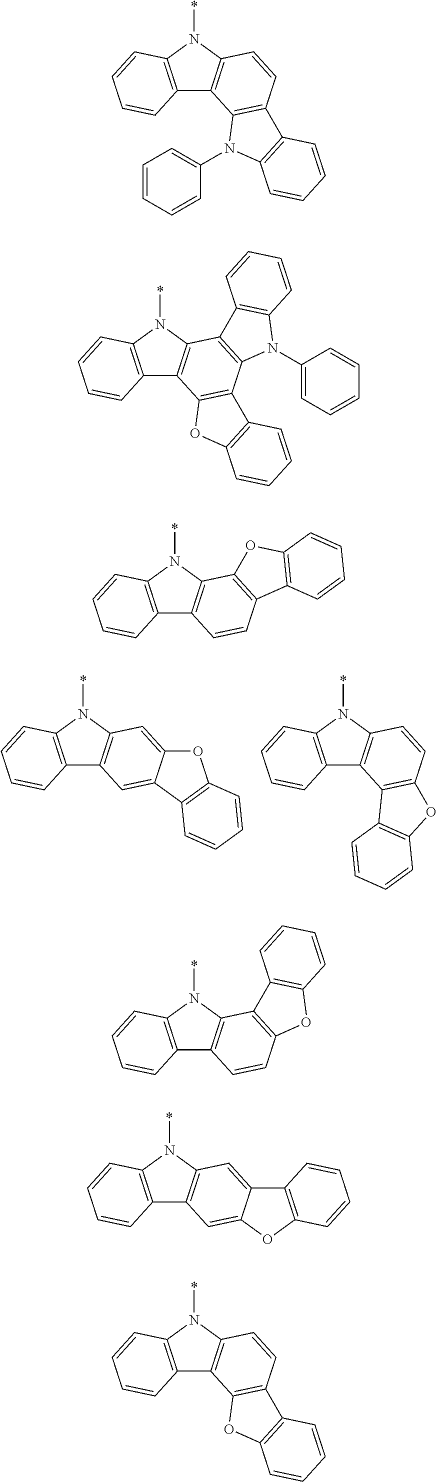

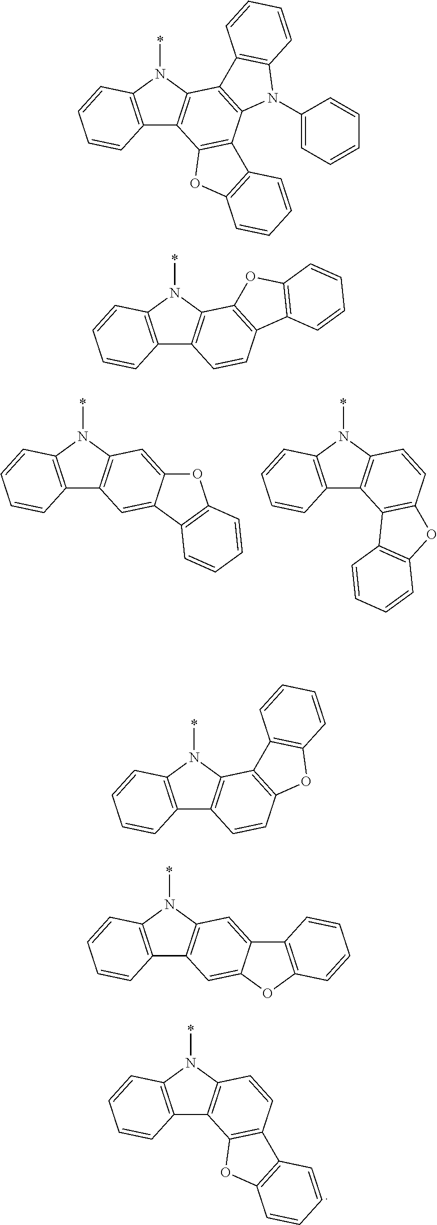

The second compound can comprise an organic compound having the following structure of Formula 8A to 8C:

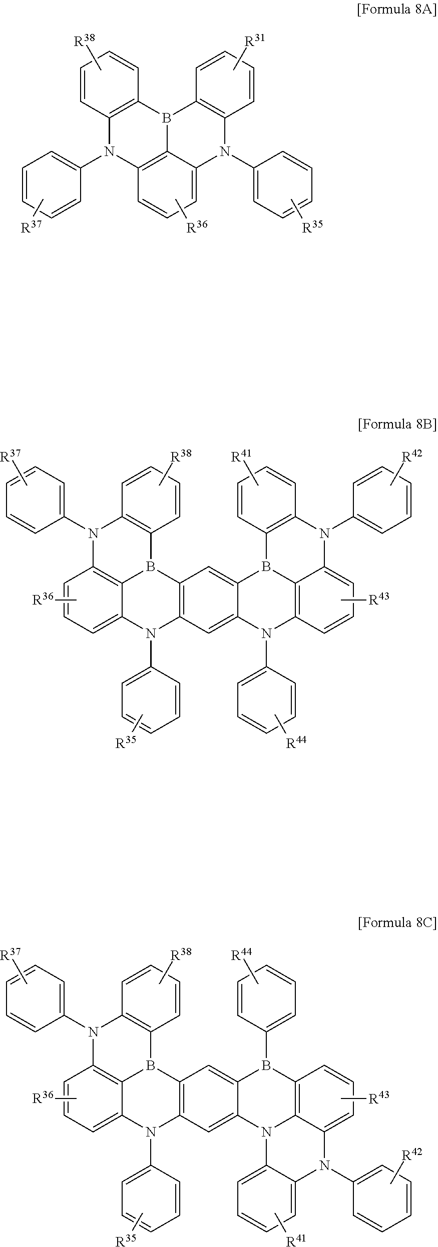

wherein, in Formulae 8A to 8C,

each of R³¹, R³⁵ to R³⁸ and R⁴¹ to R⁴⁴ is independently hydrogen, deuterium, tritium, halogen, unsubstituted or substituted C₁-C₂₀ alkyl, unsubstituted or substituted C₁-C₂₀ alkyl silyl, unsubstituted or substituted C₁-C₂₀ alkyl amino, unsubstituted or substituted C₆-C₃₀ aryl or unsubstituted or substituted C₃-C₃₀ hetero aryl.

In a preferred embodiment, in Formula 1, each of R⁴ to R⁶ is independently hydrogen, deuterium, or tritium. Preferably, in Formula 1, at least two of R², R⁵ and R⁸ is a moiety having the structure of Formula 2. In an embodiment, in Formula 1, R⁴ and R⁶ are each independently a moiety having the structure of Formula 2. In an embodiment, in Formula 1, R² and R⁸ are each independently a moiety having the structure of Formula 2. In an embodiment, in Formula 1, R² and R⁵ are each independently a moiety having the structure of Formula 2. In an embodiment, wherein in Formula 1, R⁵ and R⁸ are each independently a moiety having the structure of Formula 2.

In a preferred embodiment, in Formula 7, each of R³¹ to R³⁸ is independently hydrogen, deuterium, tritium, halogen, or an unsubstituted or substituted C₁-C₈ alkyl. In another embodiment, in Formula 7, each of R³¹ to R³⁴ is independently hydrogen, deuterium, tritium, halogen, or an unsubstituted or substituted C₁-C₈ alkyl. In another embodiment, in Formula 7, at least two of R³¹ to R³⁸ is independently an unsubstituted or substituted C₁-C₂₀ alkyl amino, an unsubstituted or substituted C₆-C₃₀ aromatic group or an unsubstituted or substituted C₃-C₃₀ hetero aromatic group. In another embodiment, in Formula 7, at least two of R³¹ to R³⁸ is independently an unsubstituted or substituted carbazole.

In one aspect, the at least one emitting material layer can have a single-layered emitting material layer. The single-layered emitting material layer can further comprise a third compound. In this case, the single-layered emitting material layer can comprise the first compound of about 10 to about 40% by weight, the second compound of about 0.1 to about 5% by weight and the third compound of about 55 to about 85% by weight.

Alternatively, the at least one emitting material layer can comprise a first emitting material layer disposed between the first and second electrodes and a second emitting material layer disposed between the first electrode and the first emitting material layer or between the first emitting material layer and the second electrode, and wherein the first emitting material layer comprises the first compound and the second emitting material layer comprises the second compound. The first emitting material layer can further comprise a third compound and the second emitting material layer can further comprise a fourth compound.

As an example, an excited triplet exciton energy level of the third compound and/or the fourth compound can be higher than an excited triplet exciton energy level of the first compound and the exited triplet exciton energy level of the first compound can be higher than an excited triplet exciton energy level of the second compound.

Alternatively, an excited singlet exciton energy level of the third compound and/or the fourth compound can be higher than an excited singlet exciton energy level of the first compound and the excited singlet exciton energy level of the first compound can be higher than an excited singlet exciton energy level of the second compound.

Alternatively, an excited singlet energy level of the fourth compound can be higher than an excited singlet energy level of the second compound.

Optionally, when the at least one emitting material layer comprises the first and second emitting material layers, the at least one emitting material layer can further comprises a third emitting material layer disposed oppositely to the second emitting material layer with respect to the first emitting material layer.

The third emitting material layer can comprise a fifth compound and a sixth compound, and the fifth compound can comprise the organic compound having the structure of Formula 7.

In one aspect, the emissive layer can comprise a first emitting part disposed between the first and second electrodes, a second emitting part disposed between the first emitting part and the second electrode and a charge generation layer disposed between the first and second emitting parts, and wherein at least one of the first emitting part and the second emitting part can comprise the at least one emitting material layer.

As an example, the first emitting part can comprise the at least one emitting material layer, and the second emitting part can emit at least one of red light and green light.

Alternatively, the emissive layer can further comprise a third emitting part disposed between the second emitting part and the second electrode and a second charge generation layer disposed between the second and third emitting part, and wherein at least one of the first emitting part and the third emitting part can comprise the at least one emitting material layer.

In another aspect, an organic light emitting device, such as an organic light emitting display device or an organic light emitting luminescent device comprises a substrate and the OLED disposed over the substrate, as described above. For instance, an organic light emitting display device, may comprise a substrate; and an OLED display comprising an array of light emitting pixels on the substrate, wherein each pixel comprises one or more individually addressable organic light emitting diodes described above.

It is to be understood that both the foregoing general description and the following detailed description are exemplary and explanatory and are intended to provide further explanation of the inventive concepts as claimed.

### BRIEF DESCRIPTION OF THE DRAWING

The accompanying drawings, which are included to provide a further understanding of the disclosure, are incorporated in and constitute a part of this application, illustrate embodiments of the disclosure and together with the description serve to explain principles of the disclosure.

FIG. 1 is a schematic circuit diagram of an organic light emitting display device in accordance with the preset disclosure.

FIG. 2 is a schematic cross-sectional view illustrating an organic light emitting display device in accordance with an aspect of the present disclosure.

FIG. 3 is a schematic cross-sectional view illustrating an organic light emitting diode (OLED) in accordance with an aspect of the present disclosure.

FIG. 4 is a schematic graph illustrating that the luminous efficiency and color purity of an OLED can be improved by controlling an onset wavelength of the first compound and a maximum absorbance wavelength of the second compound in accordance with an aspect of the present disclosure.

FIG. 5 is a schematic graph illustrating that the luminous efficiency of an OLED is deteriorated in case an onset wavelength of the first compound does not have specific wavelength ranges.

FIG. 6 is a schematic graph illustrating that the luminous efficiency and color purity of an OLED is deteriorated in case an onset wavelength of the first compound is more than a maximum absorbance wavelength of the second compound.

FIG. 7 is a schematic diagram illustrating luminous mechanism by singlet and triplet energy levels among luminous material in an EML in accordance with an aspect of the present disclosure.

FIG. 8 is a schematic cross-sectional view illustrating an OLED in accordance with another aspect of the present disclosure.

FIG. 9 is a schematic diagram illustrating luminous mechanism by singlet and triplet energy levels among luminous materials in EMLs in accordance with another aspect of the present disclosure.

FIG. 10 is a schematic cross-sectional view illustrating an OLED in accordance with still another aspect of the present disclosure.

FIG. 11 is a schematic diagram illustrating luminous mechanism by singlet and triplet energy levels among luminous materials in EMLs in accordance with still another aspect of the present disclosure.

FIG. 12 is a schematic cross-sectional view illustrating an OLED in accordance with still another aspect of the present disclosure.

FIG. 13 is a schematic cross-sectional view illustrating an organic light emitting display device in accordance with another aspect of the present disclosure.

FIG. 14 is a schematic cross-sectional view illustrating an OLED in accordance with still another aspect of the present disclosure.

FIG. 15 is a schematic cross-sectional view illustrating an organic light emitting display device in accordance with still another aspect of the present disclosure.

FIG. 16 is a schematic cross-sectional view illustrating an OLED in accordance with still another aspect of the present disclosure.

FIG. 17 is a schematic cross-sectional view illustrating an OLED in accordance with still another aspect of the present disclosure.

### DETAILED DESCRIPTION OF THE EMBODIMENTS

Reference and discussions will now be made below in detail to aspects, embodiments and examples of the disclosure, some examples of which are illustrated in the accompanying drawings.

The present disclosure relates to an organic light emitting diode (OLED) into which a first compound and a second compound having adjusted energy levels are applied in an identical EML or adjacently disposed EMLs and an organic light emitting device having the OLED. The OLED can be applied into an organic light emitting device such as an organic light emitting display device and an organic light emitting luminescent device. As an example, a display device applying the OLED will be described.

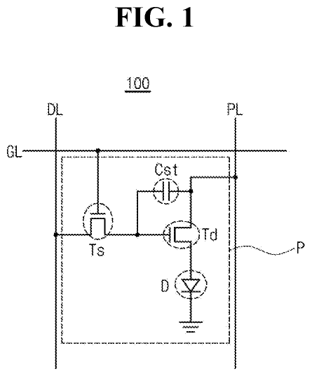

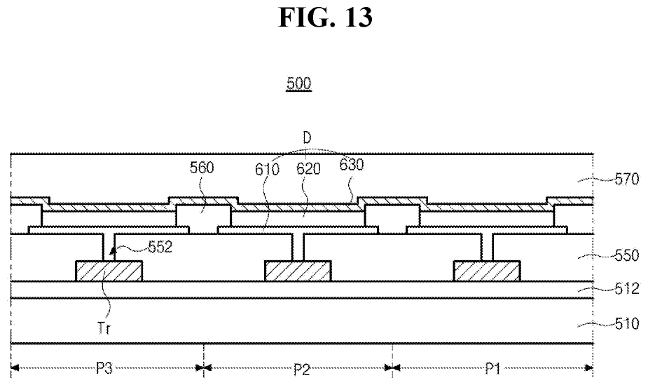

FIG. 1 is a schematic circuit diagram of an organic light emitting display device in accordance with the present disclosure. As illustrated in FIG. 1, a gate line GL, a data line DL and power line PL, each of which cross each other to define a pixel region P, in an organic light emitting display device 100. A switching thin film transistor Ts, a driving thin film transistor Td, a storage capacitor Cst and an organic light emitting diode D are formed within the pixel region P. The pixel region P can include a first pixel region P1, a second pixel region P2 and a third pixel region P3 (FIG. 13).

The switching thin film transistor Ts is connected to the gate line GL and the data line DL, and the driving thin film transistor Td and the storage capacitor Cst are connected between the switching thin film transistor Ts and the power line PL. The organic light emitting diode D is connected to the driving thin film transistor Td. When the switching thin film transistor Ts is turned on by a gate signal applied into the gate line GL, a data signal applied into the data line DL is applied into a gate electrode of the driving thin film transistor Td and one electrode of the storage capacitor Cst through the switching thin film transistor Ts.

The driving thin film transistor Td is turned on by the data signal applied into the gate electrode so that currents proportional to the data signal are supplied from the power line PL to the organic light emitting diode D through the driving thin film transistor Td. And then, the organic light emitting diode D emits light with a luminance proportional to the currents flowing through the driving thin film transistor Td. In this case, the storage capacitor Cst is charged with voltages proportional to the data signal so that the voltage of the gate electrode in the driving thin film transistor Td is kept constant during one frame. Therefore, the organic light emitting display device 100 can display a desired image.

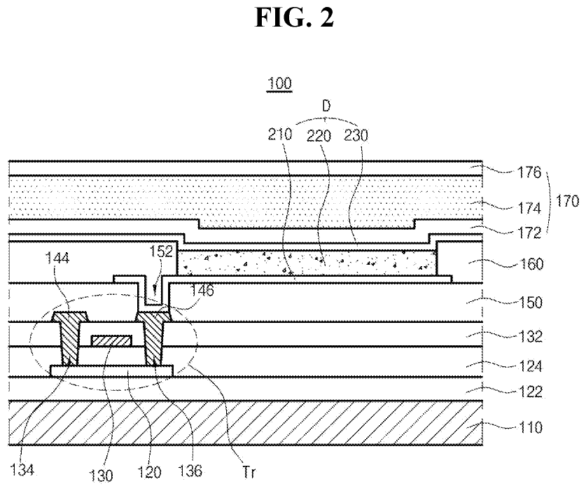

FIG. 2 is a schematic cross-sectional view of an organic light emitting display device 100 in accordance with an aspect of the present disclosure. All components of the organic light emitting device in accordance with all aspects of the present disclosure are operatively coupled and configured. As illustrated in FIG. 2, the organic light emitting display device 100 includes a substrate 110, a thin-film transistor Tr on the substrate 110, and an organic light emitting diode (OLED) D over the substrate 110 and connected to the thin film transistor Tr.

The substrate 110 can include, but is not limited to, glass, thin flexible material and/or polymer plastics. For example, the flexible material can include, but is not limited to, polyimide (PI), polyethersulfone (PES), polyethylenenaphthalate (PEN), polyethylene terephthalate (PET), polycarbonate (PC) and combination thereof. The substrate 110, over which the thin film transistor Tr and the OLED D are arranged, forms an array substrate.

A buffer layer 122 can be disposed over the substrate 110, and the thin film transistor Tr is disposed over the buffer layer 122. The buffer layer 122 can be omitted.

A semiconductor layer 120 is disposed over the buffer layer 122 (or over the substrate 110 when the buffer layer 122 is not present). In one aspect, the semiconductor layer 120 can include, but is not limited to, oxide semiconductor materials. In this case, a light-shield pattern can be disposed under the semiconductor layer 120, and the light-shield pattern can prevent light from being incident toward the semiconductor layer 120, and thereby, preventing the semiconductor layer 120 from being deteriorated by the light. Alternatively, the semiconductor layer 120 can include, but is not limited to, polycrystalline silicon. In this case, opposite edges of the semiconductor layer 120 can be doped with impurities.

A gate insulating layer 124 made of an insulating material is disposed on the semiconductor layer 120. The gate insulating layer 124 can include, but is not limited to, an inorganic insulating material such as silicon oxide (SiOₓ) or silicon nitride (SiNₓ).

A gate electrode 130 made of a conductive material such as metal is disposed over the gate insulating layer 124 so as to correspond to a center of the semiconductor layer 120. While the gate insulating layer 124 is disposed over a whole area of the substrate 110 in FIG. 2, the gate insulating layer 124 can be patterned identically as the gate electrode 130.

An interlayer insulating layer 132 made of an insulating material is disposed on the gate electrode 130 with covering over an entire surface of the substrate 110. The interlayer insulating layer 132 can include, but is not limited to, an inorganic insulating material such as silicon oxide (SiOₓ) or silicon nitride (SiNₓ), or an organic insulating material such as benzocyclobutene or photo-acryl.

The interlayer insulating layer 132 has first and second semiconductor layer contact holes 134 and 136 that expose both sides of the semiconductor layer 120. The first and second semiconductor layer contact holes 134 and 136 are disposed over opposite sides of the gate electrode 130 with spacing apart from the gate electrode 130. The first and second semiconductor layer contact holes 134 and 136 are formed within the gate insulating layer 124 in FIG. 2. Alternatively, the first and second semiconductor layer contact holes 134 and 136 are formed only within the interlayer insulating layer 132 when the gate insulating layer 124 is patterned identically as the gate electrode 130.

A source electrode 144 and a drain electrode 146, which are made of conductive material such as a metal, are disposed on the interlayer insulating layer 132. The source electrode 144 and the drain electrode 146 are spaced apart from each other with respect to the gate electrode 130, and contact both sides of the semiconductor layer 120 through the first and second semiconductor layer contact holes 134 and 136, respectively.

The semiconductor layer 120, the gate electrode 130, the source electrode 144 and the drain electrode 146 constitute the thin film transistor Tr, which acts as a driving element. The thin film transistor Tr in FIG. 2 has a coplanar structure in which the gate electrode 130, the source electrode 144 and the drain electrode 146 are disposed over the semiconductor layer 120. Alternatively, the thin film transistor Tr can have an inverted staggered structure in which a gate electrode is disposed under a semiconductor layer and a source and drain electrodes are disposed over the semiconductor layer. In this case, the semiconductor layer can include amorphous silicon.

The gate line GL and the data line DL, which cross each other to define the pixel region P, and the switching element Ts, which is connected to the gate line GL and the data line DL, can be further formed in the pixel region P of FIG. 1. The switching element Ts is connected to the thin film transistor Tr, which is a driving element. Besides, the power line PL is spaced apart in parallel from the gate line GL or the data line DL, and the thin film transistor Tr can further include a storage capacitor Cst configured to constantly keep voltage of the gate electrode 130 for one frame.

In addition, the organic light emitting display device 100 can include a color filter layer that includes dyes or pigments for transmitting specific wavelength light of light emitted from the OLED D. For example, the color filter layer can transmit light of specific wavelength such as red (R), green (G) and/or blue (B). Each of red, green, and blue color filter patterns can be disposed separately in each pixel region P. In this case, the organic light emitting display device 100 can implement full-color through the color filter layer.

For example, when the organic light emitting display device 100 is a bottom-emission type, the color filter layer can be disposed on the interlayer insulating layer 132 with corresponding to the OLED D. Alternatively, when the organic light emitting display device 100 is a top-emission type, the color filter layer can be disposed over the OLED D, for example, a second electrode 230.

A passivation layer 150 is disposed on the source and drain electrodes 144 and 146 over the whole substrate 110. The passivation layer 150 has a flat top surface and a drain contact hole 152 that exposes the drain electrode 146 of the thin film transistor Tr. While the drain contact hole 152 is disposed on the second semiconductor layer contact hole 136, it can be spaced apart from the second semiconductor layer contact hole 136.

The OLED D includes a first electrode 210 that is disposed on the passivation layer 150 and connected to the drain electrode 146 of the thin film transistor Tr. The OLED D further includes an emissive layer 220 and a second electrode 230 each of which is disposed sequentially on the first electrode 210.

The first electrode 210 is disposed in each pixel region. The first electrode 210 can be an anode and include a conductive material having a relatively high work function value. For example, the first electrode 210 can include a transparent conductive oxide (TCO). More particularly, the first electrode 210 can include, but is not limited to, indium tin oxide (ITO), indium zinc oxide (IZO), indium tin zinc oxide (ITZO), tin oxide (SnO), zinc oxide (ZnO), cerium doped indium oxide (ICO), aluminum doped zinc oxide (Al:ZnO, AZO), and the like.

In one aspect, when the organic light emitting display device 100 is a bottom-emission type, the first electrode 210 can have a single-layered structure of a transparent conductive material. Alternatively, when the organic light emitting display device 100 is a top-emission type, a reflective electrode or a reflective layer can be disposed under the first electrode 210. For example, the reflective electrode or the reflective layer can include, but is not limited to, silver (Ag) or aluminum-palladium-copper (APC) alloy. In the OLED D of the top-emission type, the first electrode 210 can have a triple-layered structure of ITO/Ag/ITO or ITO/APC/ITO. In addition, a bank layer 160 is disposed on the passivation layer 150 in order to cover edges of the first electrode 210. The bank layer 160 exposes a center of the first electrode 210 corresponding to the pixel region P.

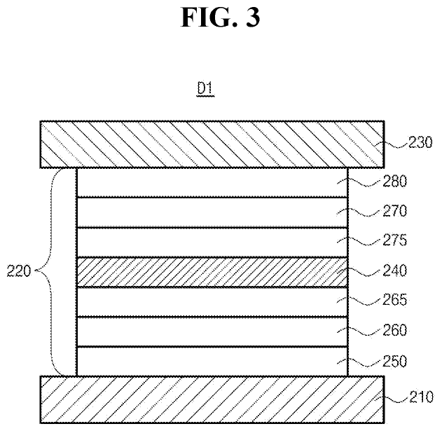

The emissive layer 220 is disposed on the first electrode 210. In one aspect, the emissive layer 220 can have a single-layered structure of an emitting material layer (EML). Alternatively, the emissive layer 220 can have a multiple-layered structure of a hole injection layer (HIL), a hole transport layer (HTL), an electron blocking layer (EBL), an EML, a hole blocking layer (HBL), an electron transport layer (ETL) and/or an electron injection layer (EIL) (FIGS. 3, 8, 10 and 12). In one aspect, the emissive layer 220 can have single emitting part. Alternatively, the emissive layer 220 can have multiple emitting parts to form a tandem structure.

The second electrode 230 is disposed over the substrate 110 above which the emissive layer 220 is disposed. The second electrode 230 can be disposed over a whole display area and can include a conductive material with a relatively low work function value compared to the first electrode 210. The second electrode 230 can be a cathode. For example, the second electrode 230 can include, but is not limited to, aluminum (Al), magnesium (Mg), calcium (Ca), silver (Ag), alloy thereof or combination thereof such as aluminum-magnesium alloy (Al—Mg). When the organic light emitting display device 100 is a top-emission type, the second electrode 230 is thin so as to have light-transmissive (semi-transmissive) property.

In addition, an encapsulation film 170 can be disposed over the second electrode 230 in order to prevent outer moisture from penetrating into the OLED D. The encapsulation film 170 can have, but is not limited to, a laminated structure of a first inorganic insulating film 172, an organic insulating film 174 and a second inorganic insulating film 176.

Moreover, the organic light emitting display device 100 can have a polarizer in order to decrease external light reflection. For example, the polarizer can be a circular polarizer. When the organic light emitting display device 100 is a bottom-emission type, the polarizer can be disposed under the substrate 110. Alternatively, when the organic light emitting display device 100 is a top-emission type, the polarizer can be disposed over the encapsulation film 170. In addition, a cover window can be attached to the encapsulation film 170 or the polarizer. In this case, the substrate 110 and the cover window can have a flexible property, thus the organic light emitting display device 100 can be a flexible display device.

Now, we will describe the OLED in more detail. FIG. 3 is a schematic cross-sectional view illustrating an OLED in accordance with an aspect of the present disclosure. As illustrated in FIG. 3, the OLED D1 comprises first and second electrodes 210 and 230 facing each other, and an emissive layer 220 having single emitting part disposed between the first and second electrodes 210 and 230. The organic light emitting display device 100 includes a red pixel region, a green pixel region and a blue pixel region, and the OLED D1 can be disposed in the blue pixel region.

The emissive layer 220 includes an EML 240 disposed between the first and second electrodes 210 and 230. Also, the emissive layer 220 can include at least one of an HTL 260 disposed between the first electrode 210 and the EML 240 and an ETL 270 disposed between the second electrode 230 and the EML 240. In addition, the emissive layer 220 can further include at least one of an HIL 250 disposed between the first electrode 210 and the HTL 260 and an EIL 280 disposed between the second electrode 230 and the ETL 270. Alternatively, the emissive layer 220 can further include an EBL 265 265 disposed between the HTL 260 and the EML 240 and/or an HBL 275 disposed between the EML 240 and the ETL 270.

The first electrode 210 can be an anode that provides holes into the EML 240. The first electrode 210 can include, but is not limited to, a conductive material having a relatively high work function value, for example, a transparent conductive oxide (TCO). In an aspect, the first electrode 210 can include, but is not limited to, ITO, IZO, ITZO, SnO, ZnO, ICO, AZO, and the like.

The second electrode 230 can be a cathode that provides electrons into the EML 240. The second electrode 230 can include, but is not limited to, a conductive material having a relatively low work function values, i.e., a highly reflective material such as Al, Mg, Ca, Ag, alloy thereof, combination thereof, and the like.

The EML 240 can include a first compound (Compound 1) DF, a second compound (Compound 2) FD and, optionally a third compound (Compound 3) H. For example, the first compound DF can be delayed fluorescent material, the second compound FD can be fluorescent material, and the third compound H can be host.

When holes and electrons meet each other to form excitons in the EML 240, singlet exciton with a paired spin state and triplet exciton with an unpaired spin state are generated in a ratio of 1:3 by spin arrangement. Since the conventional fluorescent materials can utilize only the singlet excitons, they exhibit low luminous efficiency. The phosphorescent materials can utilize the triplet excitons as well as the singlet excitons, while they show too short luminous lifespan to be applicable to commercial devices.

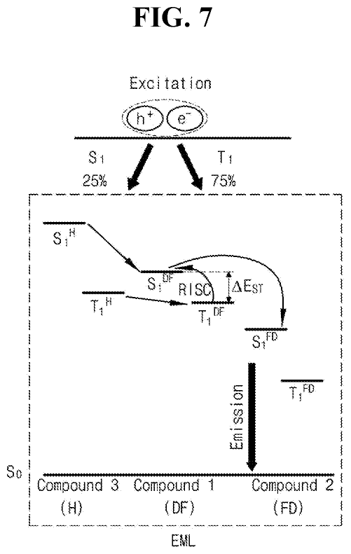

The first compound DF can be delayed fluorescent material having thermally activated delayed fluorescence (TADF) properties that can solve the problems accompanied by the conventional art fluorescent and/or phosphorescent materials. The delayed fluorescent material has very narrow energy level bandgap ΔE_{ST} between a singlet energy level S₁^{DF} and a triplet energy level T₁^{DF} (FIG. 7). Accordingly, the excitons of singlet energy level S₁^{DF} as well as the excitons of triplet energy level T₁^{DF} in the first compound DF of the delayed fluorescent material can be transferred to an intermediate energy level state, i.e. ICT (intramolecular charge transfer) state (S₁^{DF}→ICT←T₁^{DF}), and then the intermediate state excitons can be shifted to a ground state (ICT→S₀).

The delayed fluorescent material must has an energy level bandgap ΔE_{ST} (FIG. 7) equal to or less than about 0.3 eV, for example, from about 0.05 to about 0.3 eV, between the singlet energy level S₁^{DF} and the triplet energy level T₁^{DF} so that exciton energy in both the singlet energy level S₁^{DF} and the triplet energy level T₁^{DF} can be transferred to the ICT state. The material having little energy level bandgap ΔE_{ST} between the singlet energy level S₁^{DF} and the triplet energy level T₁^{DF} can exhibit common fluorescence with Inter system Crossing (ISC) in which the excitons of singlet energy level S₁^{DF} can be shifted to its ground state S₀^{DF}, as well as delayed fluorescence with Reverse Inter System Crossing (RISC) in which the excitons of triplet energy level T₁^{DF} can be converted upwardly to the excitons of singlet energy level S₁^{DF}, and then the exciton of singlet energy level S₁^{DF} transferred from the triplet energy level T₁^{DF} can be transferred to the ground state S₀^{DF}.

The first compound DF can be delayed fluorescent material including a first moiety of an electron acceptor group with boron and oxygen atoms, and a second moiety of plural electron donor groups (EDGs). The first compound DF with delayed fluorescent property can have the following structure of Formula 1:

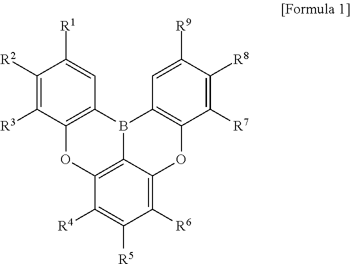

wherein, in Formula 1,

each of R¹ to R⁹ is independently hydrogen, deuterium, tritium, halogen, unsubstituted or substituted C₁-C₂₀ alkyl, unsubstituted or substituted C₁-C₂₀ alkyl amino, an unsubstituted or substituted C₆-C₃₀ aromatic group or an unsubstituted or substituted C₃-C₃₀ hetero aromatic group, wherein two to four of R¹ to R⁹ are a moiety having the following structure of Formula 2,

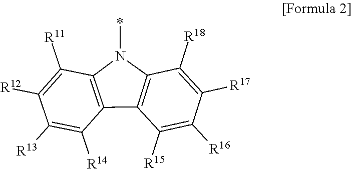

wherein, in Formula 2,

each of R¹¹ to R¹⁸ is independently hydrogen, deuterium, tritium, halogen, unsubstituted or substituted C₁-C₂₀ alkyl, unsubstituted or substituted C₁-C₂₀ alkyl silyl, unsubstituted or substituted C₁-C₂₀ alkyl amino, an unsubstituted or substituted C₆-C₃₀ aromatic group or an unsubstituted or substituted C₃-C₃₀ hetero aromatic group, or

adjacent two of R¹¹ to R¹⁸ form an unsubstituted or substituted hetero aromatic ring having the following structure of Formula 3,

wherein at least adjacent two of R¹¹ to R¹⁸ form an unsubstituted or substituted hetero aromatic ring having the following structure of Formula 3; and

asterisk indicates a linking position,

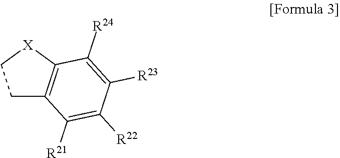

wherein, in Formula 3,

X is NR²⁵, O or S;

each of R²¹ to R²⁵ is independently hydrogen, deuterium, tritium, halogen, unsubstituted or substituted C₁-C₂₀ alkyl, unsubstituted or substituted C₁-C₂₀ alkyl silyl, unsubstituted or substituted C₁-C₂₀ alkyl amino, an unsubstituted or substituted C₆-C₃₀ aromatic group or an unsubstituted or substituted C₃-C₃₀ hetero aromatic group; and a dotted line indicates a fused portion.

As used herein, substituent in the term “substituted” includes, but is not limited to, deuterium, tritium, unsubstituted or deuterium or halogen-substituted C₁-C₂₀ alkyl, unsubstituted or deuterium or halogen-substituted C₁-C₂₀ alkoxy, halogen, cyano, —CF₃, a hydroxyl group, a carboxylic group, a carbonyl group, an amino group, a C₁-C₁₀ alkyl amino group, a C₆-C₃₀ aryl amino group, a C₃-C₃₀ hetero aryl amino group, a C₆-C₃₀ aryl group, a C₃-C₃₀ hetero aryl group, a nitro group, a hydrazyl group, a sulfonate group, a C₁-C₂₀ alkyl silyl group, a C₆-C₃₀ aryl silyl group and a C₃-C₃₀ hetero aryl silyl group.

For example, each of the C₆-C₃₀ aromatic group, the C₃-C₃₀ hetero aromatic group, the C₆-C₂₀ aromatic ring, the C₃-C₃₀ hetero aromatic ring, the C₆-C₃₀ arylene and the C₃-C₃₀ hetero arylene constituting R¹ to R⁹ in Formula 1, R¹¹ to R¹⁸ in Formula 2 and/or R²¹ to R²⁵ in Formula 3 can be independently unsubstituted or substituted with at least one of deuterium, tritium, C₁-C₂₀ alkyl, C₆-C₃₀ aryl, C₃-C₃₀ hetero aryl, C₆-C₃₀ aryl amino and C₃-C₃₀ hetero aryl amino.

As used herein, the term “hetero” in such as “a hetero aromatic group”, “hetero aryl”, “hetero aryl alkyl”, “hetero aryl oxy”, “hetero aryl amino” and “hetero arylene group” means that at least one carbon atom, for example 1-5 carbons atoms, constituting an aromatic group or ring is substituted with at least one hetero atom selected from the group consisting of N, O, S, P and combination thereof.

As used herein, the term “aromatic” or “aryl” is well known in the art. The term includes monocyclic rings linked covalently or fused-ring polycyclic groups. An aromatic group or aryl can be unsubstituted or substituted. As an example, the C₆-C₃₀ aromatic group, which can constitute R¹ to R⁹ in Formula 1, R¹¹ to R¹⁸ in Formula 2 and/or R²¹ to R²⁴ in Formula 3, can include independently, but is not limited to, C₆-C₃₀ aryl, C₇-C₃₀ aryl alkyl, C₆-C₃₀ aryl oxy and C₆-C₃₀ aryl amino. As an example, the C₆-C₃₀ aromatic group and/or the C₆-C₃₀ aryl group, which can constitute R¹ to R⁹ in Formula 1, R¹¹ to R¹⁸ in Formula 2 and/or R²¹ to R²⁴ in Formula 3, can include independently, but is not limited to, a non-fused or fused aryl group such as phenyl, biphenyl, terphenyl, naphthyl, anthracenyl, pentalenyl, indenyl, indeno-indenyl, heptalenyl, biphenylenyl, indacenyl, phenalenyl, phenanthrenyl, benzo-phenanthrenyl, dibenzo-phenanthrenyl, azulenyl, pyrenyl, fluoranthenyl, triphenylenyl, chrysenyl, tetraphenylenyl, tetracenyl, pleiadenyl, picenyl, pentaphenylenyl, pentacenyl, fluorenyl, indeno-fluorenyl and spiro-fluorenyl.

As used herein, the term “hetero aromatic” or “hetero aryl” refers to a heterocycles including hetero atoms selected from N, O and S in a ring where the ring system is an aromatic ring. The term includes monocyclic rings linked covalently or fused-ring polycyclic groups. A hetero aromatic group can be unsubstituted or substituted. As an example, the C₃-C₃₀ hetero aromatic group, which can be constitute R¹ to R⁹ in Formula 1, R¹¹ to R¹⁸ in Formula 2 and/or R²¹ to R²⁵ in Formula 3, can include independently, but is not limited to, C₃-C₃₀ hetero aryl, C₄-C₃₀ hetero aryl alkyl, C₃-C₃₀ hetero aryl oxy and C₃-C₃₀ hetero aryl amino.

As an example, the C₃-C₃₀ hetero aryl group, which can constitute R¹ to R⁹ in Formula 1, R¹¹ to R¹⁸ in Formula 2 and/or R²¹ to R²⁵ in Formula 3, can include independently, but is not limited to, an unfused or fused hetero aryl group such as pyrrolyl, pyridinyl, pyrimidinyl, pyrazinyl, pyridazinyl, triazinyl, tetrazinyl, imidazolyl, pyrazolyl, indolyl, iso-indolyl, indazolyl, indolizinyl, pyrrolizinyl, carbazolyl, benzo-carbazolyl, dibenzo-carbazolyl, indolo-carbazolyl, indeno-carbazolyl, benzo-furo-carbazolyl, benzo-thieno-carbazolyl, carbolinyl, quinolinyl, iso-quinolinyl, phthalazinyl, quinoxalinyl, cinnolinyl, quinazolinyl, quinolizinyl, purinyl, benzo-quinolinyl, benzo-iso-quinolinyl, benzo-quinazolinyl, benzo-quinoxalinyl, acridinyl, phenazinyl, phenoxazinyl, phenothiazinyl, phenanthrolinyl, perimidinyl, phenanthridinyl, pteridinyl, naphthyridinyl, furanyl, pyranyl, oxazinyl, oxazolyl, oxadiazolyl, triazolyl, dioxanyl, benzo-furanyl, dibenzo-furanyl, thiopyranyl, xanthenyl, chromenyl, iso-chromenyl, thiazinyl, thiophenyl, benzo-thiophenyl, dibenzo-thiophenyl, difluoro-pyrazinyl, benzofuro-dibenzo-furanyl, benzothieno-benzo-thiophenyl, benzothieno-dibenzo-thiophenyl, benzothieno-benzo-furanyl, benzothieno-dibenzo-furanyl, N-substituted spiro-fluorenyl, spiro-fluoreno-acridinyl and spiro-fluoreno-xanthenyl.

In addition, the C₆-C₂₀ aromatic ring and the C₃-C₂₀ hetero aromatic ring formed by two adjacent elements among R¹¹ to R¹⁸ in Formula 2, but is not limited to, a benzene ring, a naphthalene ring, an indene ring, a phenanthrene ring, an indene ring, a fluorene ring, a pyridine ring, a pyrimidine ring, a triazine ring, a quinoline ring, an indole ring, a benzo-furan ring, a benzo-thiophene ring, a dibenzo-furan ring, a dibenzo-thiophene ring and/or combination thereof, each of which can be unsubstituted or substituted with at least one of deuterium, tritium, C₁-C₂₀ alkyl, C₆-C₃₀ aryl, C₃-C₃₀ hetero aryl, C₆-C₃₀ aryl amino and C₃-C₃₀ hetero aryl amino.

For example, each of the C₆-C₂₀ aromatic group, the C₃-C₃₀ hetero aromatic group, fused aromatic ring and the fused hetero aromatic ring constituting each of R¹ to R⁹ in Formula 1, R¹¹ to R¹⁸ in Formula 2 and/or R²¹ to R²⁵ in Formula 3 can be unsubstituted or substituted with at least one of C₁-C₁₀ alkyl (ex. C₁-C₅ alkyl such as tert-butyl), C₆-C₃₀ aryl (ex. C₆-C₁₅ aryl such as phenyl), C₃-C₃₀ hetero aryl (ex. C₃-C₁₅ hetero aryl such as pyridyl) and/or C₆-C₃₀ aryl amino (ex. C₆-C₁₅ aryl as diphenyl amino).

In Formula 1, the fused hetero aromatic ring with boron and oxygen atoms acts as an electron acceptor group moiety, and the fused hetero aromatic ring with at least one nitrogen atom having the structure of Formula 2 acts as an electron donor group (EDG) moiety. Accordingly, the organic compound having the structure of Formula 1 can have delayed fluorescent property.

Since the electron donor group moiety having the structure of Formula 2 includes 5-membered ring with a nitrogen atom between side benzene rings, the moiety shows improved thermal stability as the bond strength between the electron donor group moiety and the electron acceptor group moiety maximizes. The first compound DF having the delayed fluorescent property has excellent luminous efficiency, so that exciton energy can be transferred efficiently from the first compound DF to the second compound FD, so that the EML 240 can realized hyper-fluorescence.

The first compound DF having the structure of Formula 1 includes the first moiety of the fused ring with boron and oxygen atoms as a nuclear atom as the electron acceptor group, and plural (e.g. two to four, two or three, or two) second moieties each of which has the structure of Formula 2 as the electron donor group. Since the electron acceptor group and the electron donor group each of which includes plural fused rings are bulky, steric hindrance in those moieties can be induced. In addition, since plural bulky electron donor moieties are arranged adjacently within the molecule, steric hindrance among those electron donor moieties can be induced. As such, the delayed fluorescent property of the first compound DF becomes strong.

The first compound DF has a molecular conformation where the plural electron donor moieties are arranged adjacently outward of the electron acceptor moiety of the central fused hetero ring with boron and oxygen atoms. While a part of the HOMO (Highest Occupied Molecular Orbital) function overlaps with a part of the LUMO (Lowest Unoccupied Molecular Orbital) function in the molecule of the first compound DF, it is possible to minimize the HOMO to extend toward the central electron donor moiety. Accordingly, the first compound DF having the structure of Formula 1 can implement high intra-molecular charge mobility efficiency and realize very high quantum efficiency.

The first compound DF inducing plural electron donor moieties is designed to maximize its molecular steric hindrance and to overlap partially between the HOMO function and the LUMO function. As the intra-molecular charge mobility efficiency of the first compound DF, the first compound has reinforced delayed fluorescent property. The energy level bandgap ΔE_{ST} between excited singlet energy level S₁^{DF} and excited triplet energy level T₁^{DF} are very narrow (FIG. 7), RISC can be performed rapidly as spin-orbital coupling (SOC) becomes strong.

The first compound DF having the Formulae 1 to 3 has delayed florescent property, as well as appropriate singlet and triplet energy levels, HOMO and LUMO energy levels and excellent luminous properties for transferring exciton energies efficiently to the second compound FD.

As an example, the first compound DF can have two electron donor group moieties each of which independently has the structure of Formula 2. In one aspect, two electron donor group moieties can be linked to each of the benzene ring that is formed by fusing boron atom and oxygen atom in the fused hetero ring constituting the electron acceptor group moiety in the first compound DF. In another aspect, two electron donor group moieties can be linked to one of the benzene ring that is formed by fusing boron atom and oxygen atom in the fused hetero ring constituting the electron acceptor group moiety, and another benzene ring that is formed by fusing two oxygen atoms in the first compound DF, respectively. In still another aspect, two electron donor group moieties can be linked to the benzene ring formed by fusing two oxygen atoms constituting the electron acceptor group moiety in the first compound DF. As an example, the first compound DF can have the following structure of Formula 4:

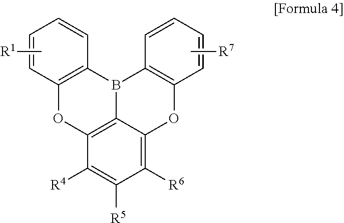

wherein, in Formula 4,

each of R¹, R⁴, R⁵, R⁶ and R⁷ is independently hydrogen, deuterium, protium, halogen, unsubstituted or substituted C₁-C₂₀ alkyl, unsubstituted or substituted C₁-C₂₀ alkyl amino, unsubstituted or substituted C₆-C₃₀ aryl or unsubstituted or substituted C₃-C₃₀ hetero aryl, wherein two of R¹, R⁴, R⁵, R⁶ and R⁷ have the structure of Formula 2.

As an example, each of the C₆-C₃₀ aryl and the C₃-C₃₀ hetero aryl of R¹, R⁴, R⁵, R⁶ and R⁷ in Formula 4 can be independently unsubstituted or substituted with at least one of deuterium, tritium, C₁-C₂₀ alkyl, C₆-C₃₀ aryl, C₃-C₃₀ hetero aryl, C₆-C₃₀ aryl amino and C₃-C₃₀ hetero aryl amino.

Adjacent at least two of R¹¹ to R¹⁸ in Formula 2 can form the fused hetero aromatic ring having the structure of Formula 3. For example, adjacent at least two of R¹¹ to R¹⁸ in Formula 2 can form an unsubstituted or substituted indene ring, an unsubstituted or substituted indole ring, an unsubstituted or substituted benzo-furan ring or an unsubstituted or substituted benzo-thiophene ring. Accordingly, the hetero aromatic moiety having the structure of Formula 2 acting as an electron donor group moiety can include, but is not limited to, an unsubstituted or substituted indeno-carbazolyl moiety, an unsubstituted or substituted indolo-carbazolyl moiety, an unsubstituted or substituted benzofuro-carbazolyl moiety and an unsubstituted or substituted benzothieno-carbazolyl moiety. As an example, the electron donor group moiety having the structure of Formula 2 can be selected from, but is not limited to, the following moieties of Formula 5:

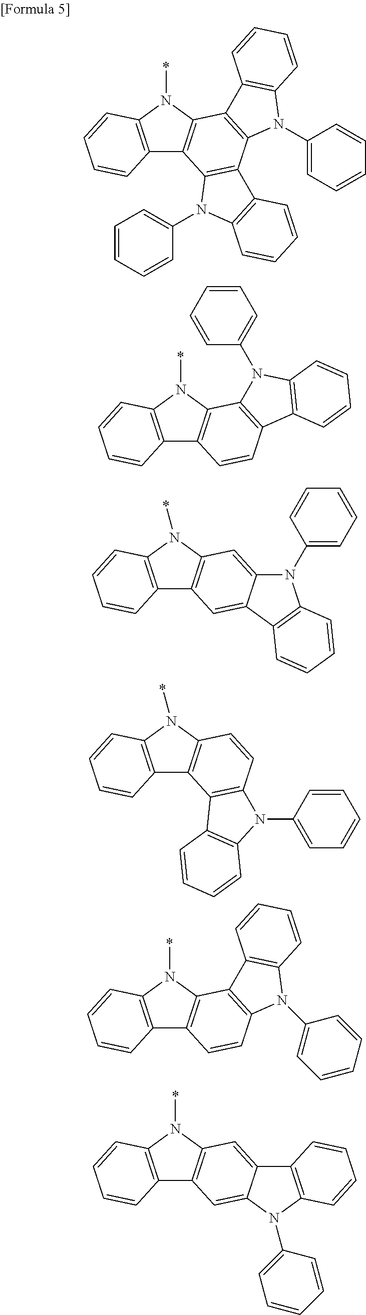

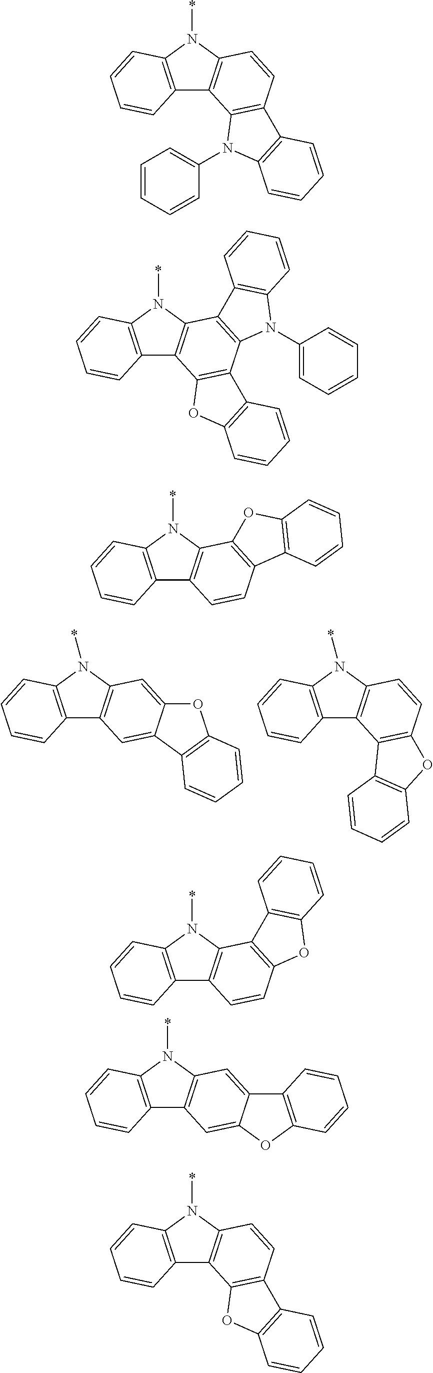

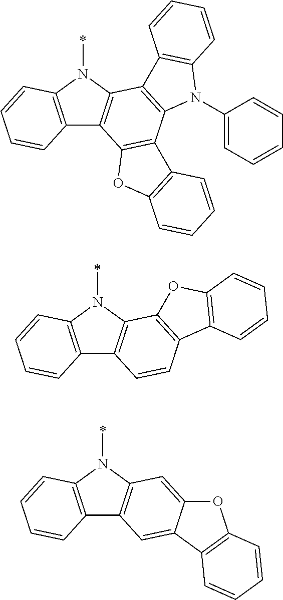 [SMILES: *n1c2ccccc2c2c3oc4ccccc4c3c3c(c4ccccc4n3-c3ccccc3)c21 ; *n1c2ccccc2c2ccc3c4ccccc4oc3c21 ; *n1c2ccccc2c2cc3c(cc21)oc1ccccc13]

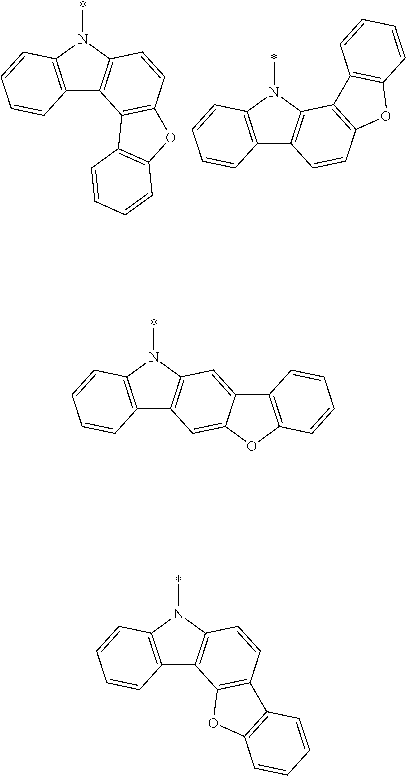

More particularly, the first compound DF can be selected from, but is not limited to, organic compounds having the following structure of Formula 6:

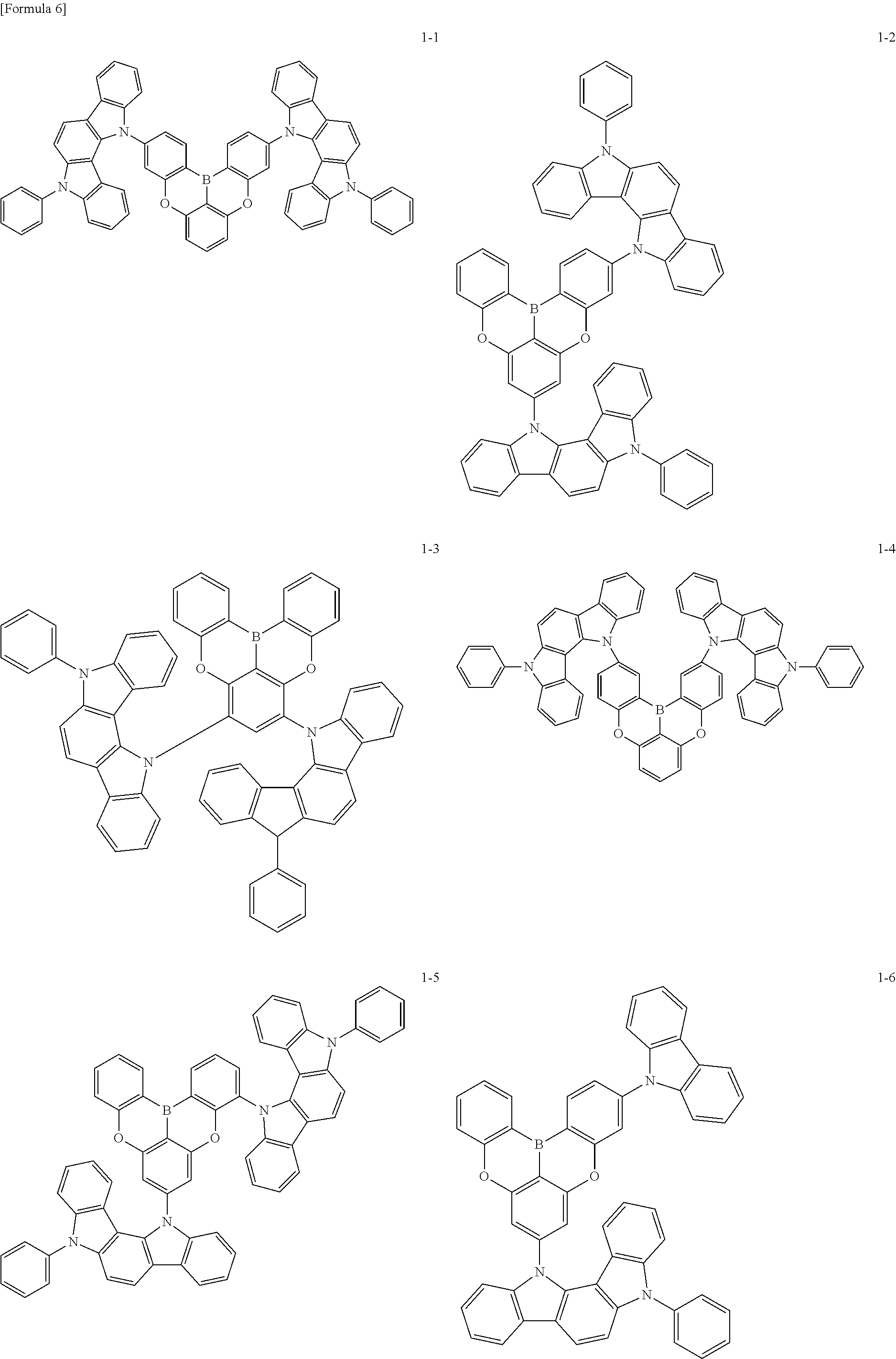

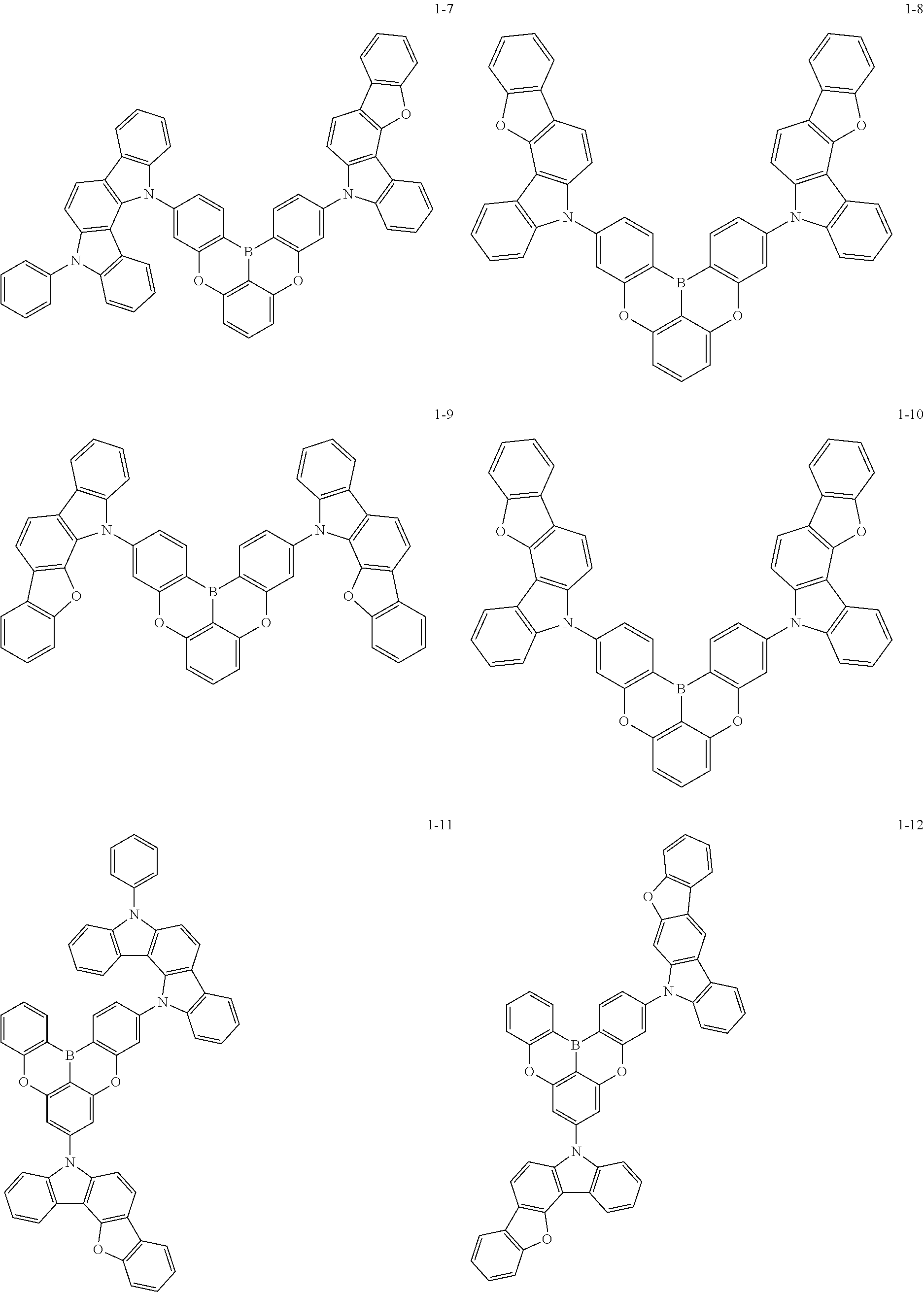

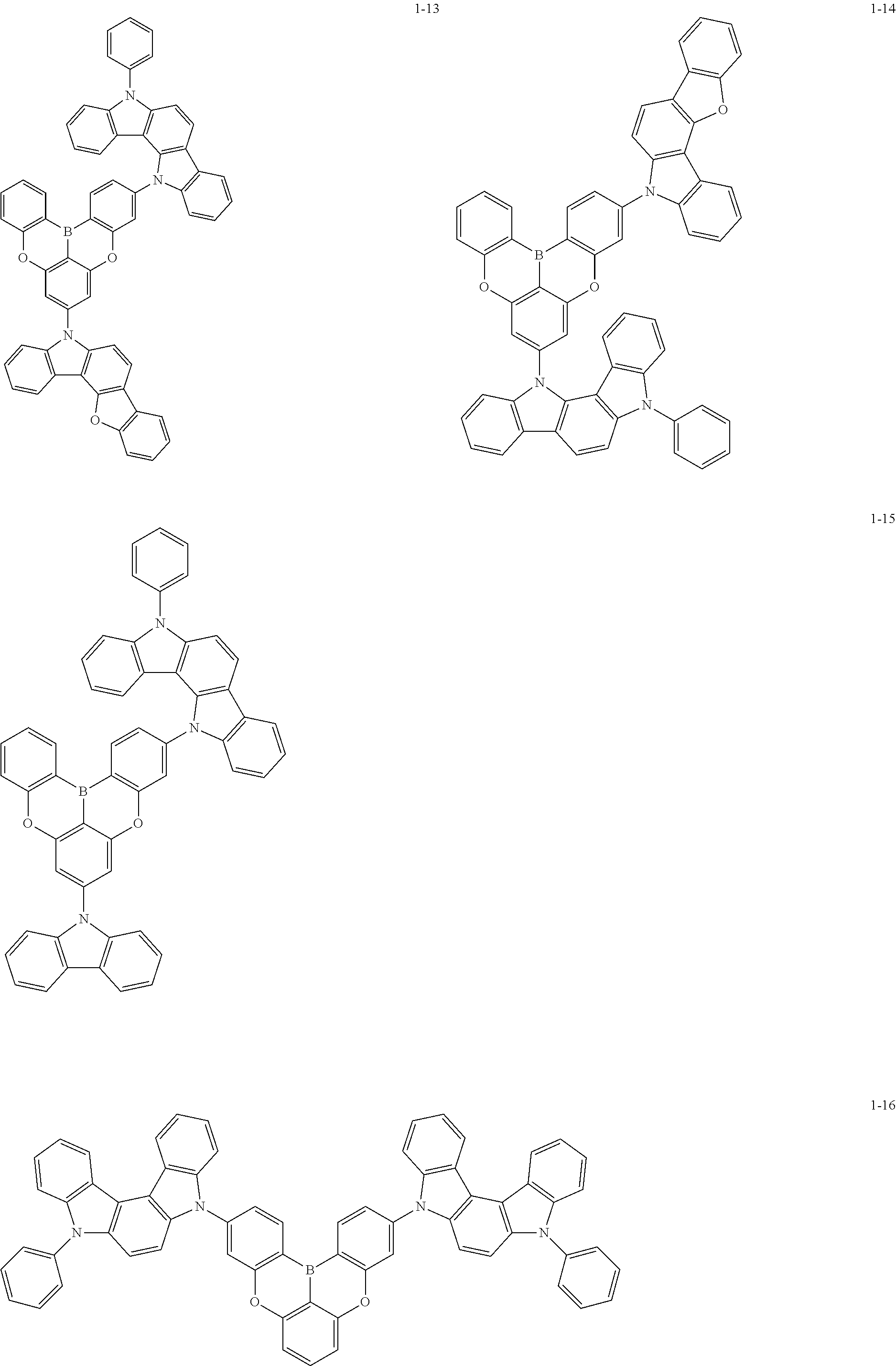 [SMILES: c1ccc(-n2c3ccccc3c3c2ccc2c4ccccc4n(-c4ccc5c(c4)Oc4cc(-n6c7ccccc7c7c8oc9ccccc9c8ccc76)cc6c4B5c4ccccc4O6)c23)cc1 ; c1ccc(-n2c3ccccc3c3c2ccc2c4ccccc4n(-c4cc5c6c(c4)Oc4cc(-n7c8ccccc8c8c9oc%10ccccc%10c9ccc87)ccc4B6c4ccccc4O5)c23)cc1 ; c1ccc(-n2c3ccccc3c3c2ccc2c4ccccc4n(-c4ccc5c(c4)Oc4cc(-n6c7ccccc7c7ccccc76)cc6c4B5c4ccccc4O6)c23)cc1 ; c1ccc(-n2c3ccccc3c3c4c5ccccc5n(-c5ccc6c(c5)Oc5cccc7c5B6c5ccc(-n6c8ccccc8c8c9c%10ccccc%10n(-c%10ccccc%10)c9ccc86)cc5O7)c4ccc32)cc1]

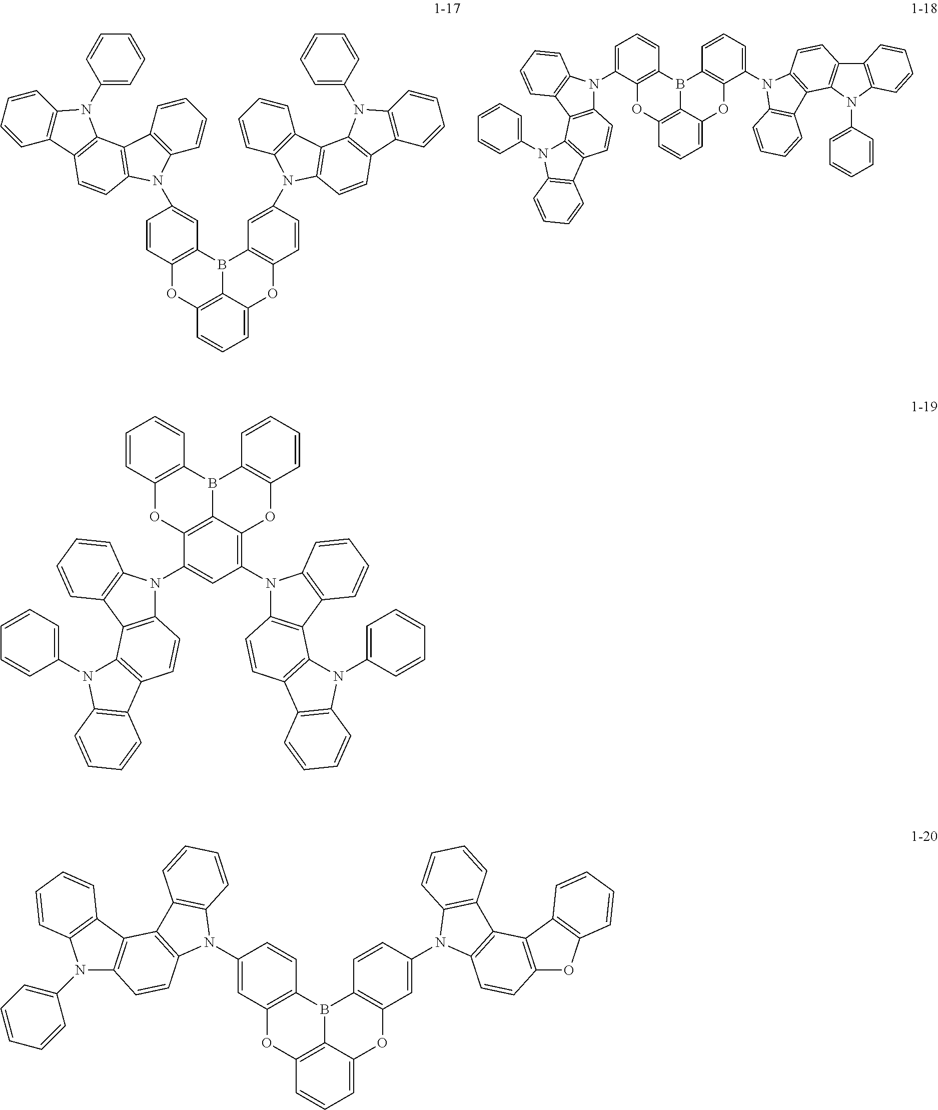

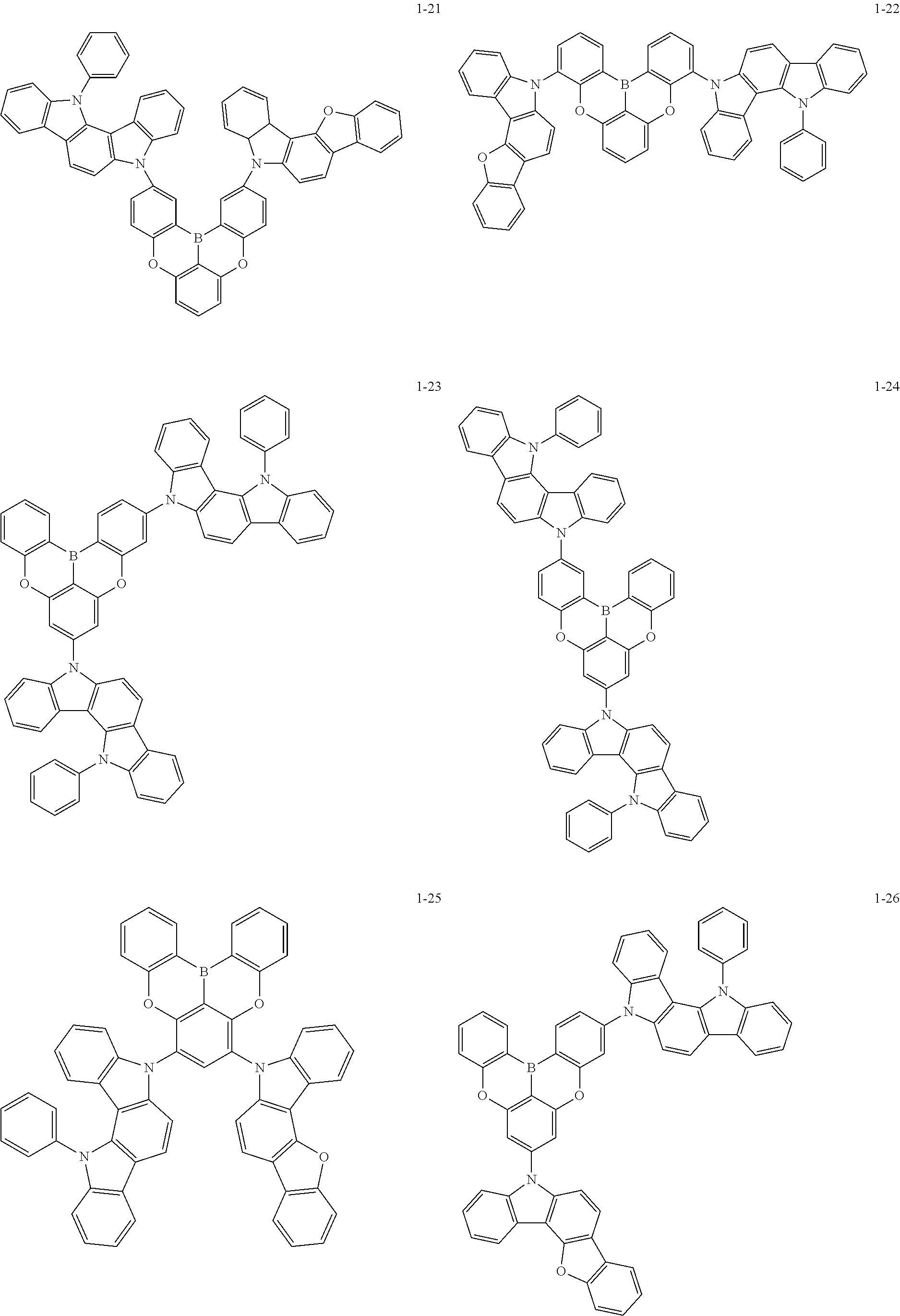

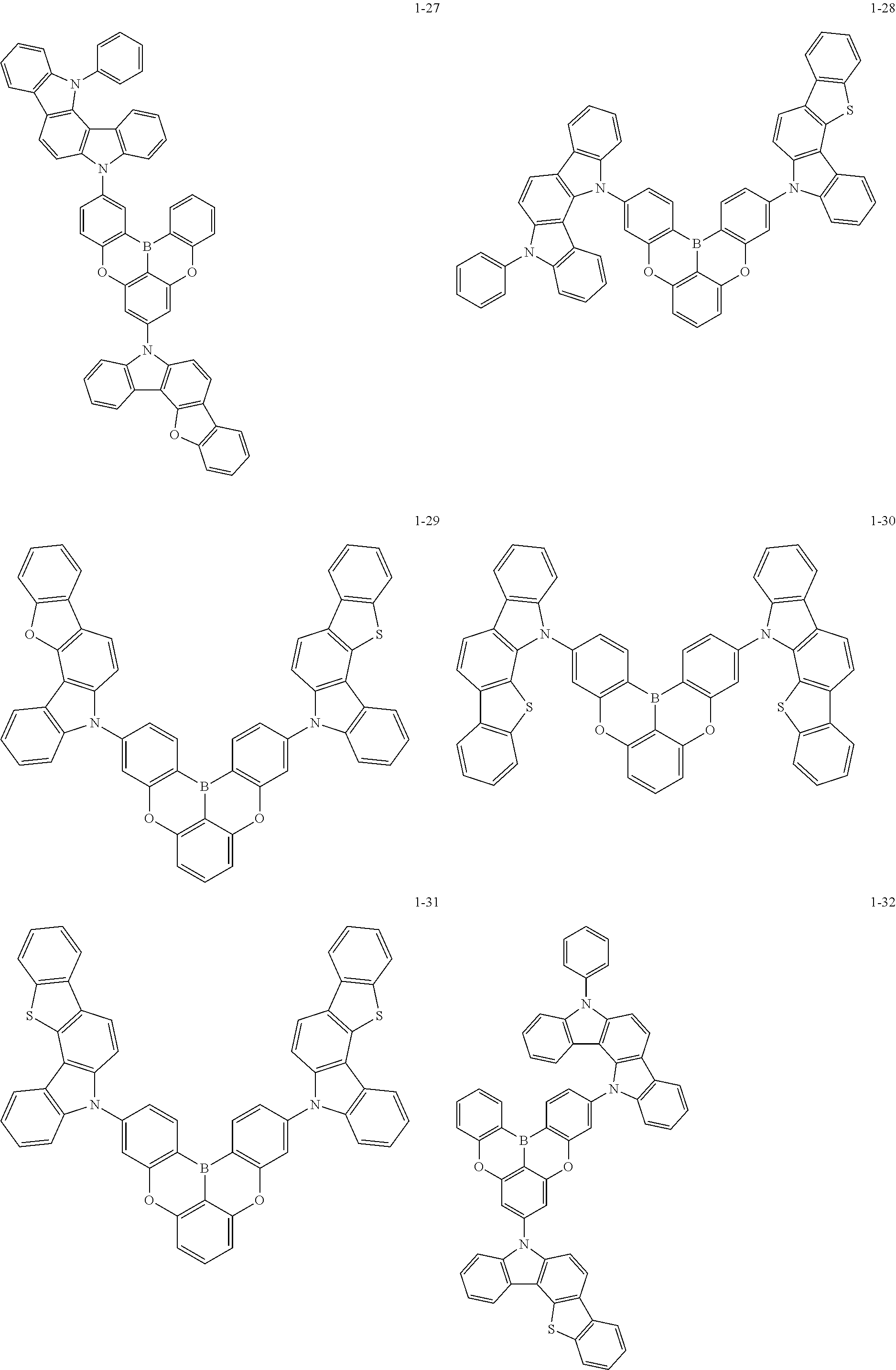

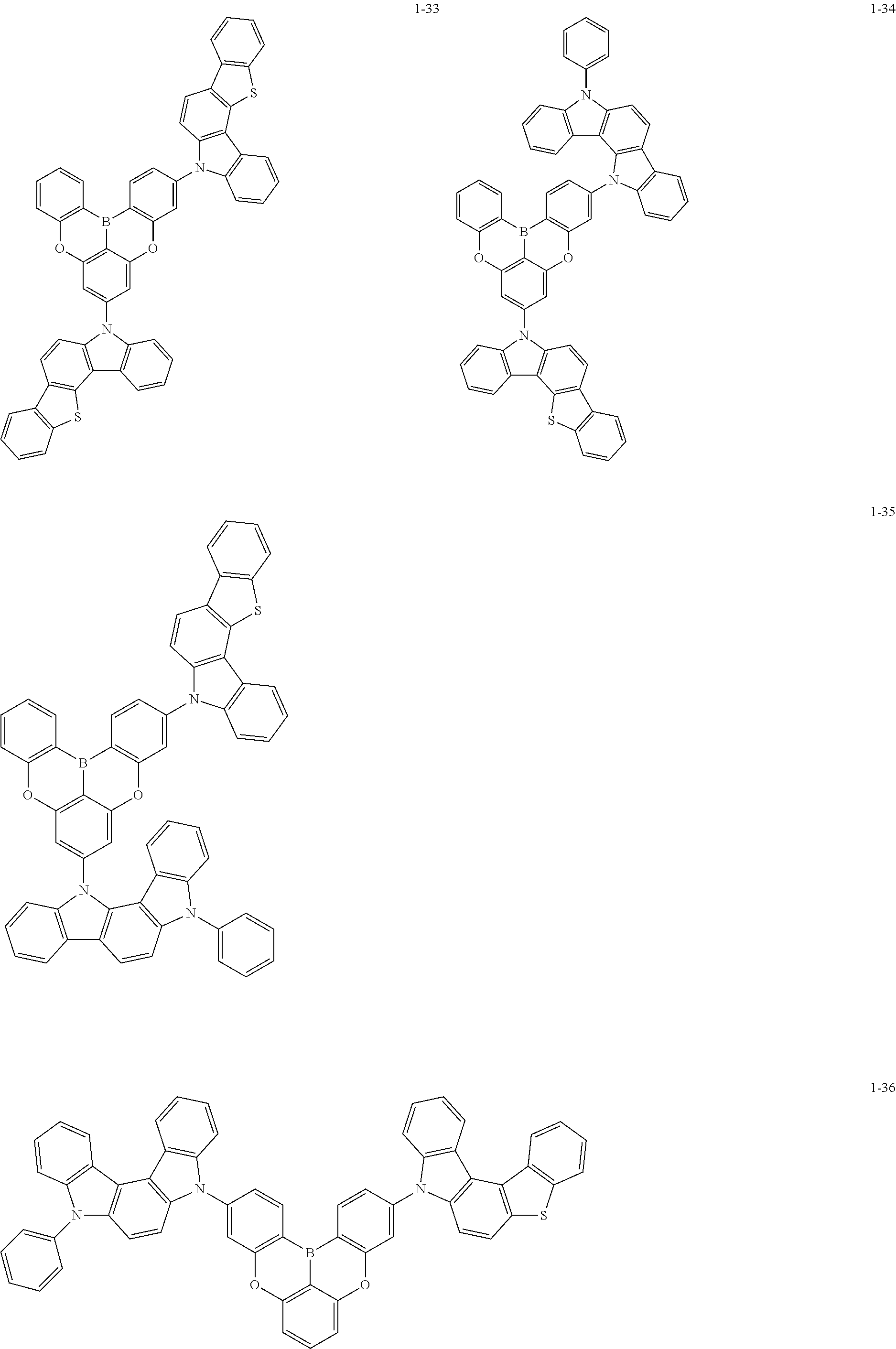 [SMILES: c1ccc2c(c1)Oc1cc(-n3c4ccccc4c4c5sc6ccccc6c5ccc43)cc3c1B2c1ccc(-n2c4ccccc4c4c5sc6ccccc6c5ccc42)cc1O3 ; c1ccc(-n2c3ccccc3c3c2ccc2c4ccccc4n(-c4ccc5c(c4)Oc4cc(-n6c7ccccc7c7c8sc9ccccc9c8ccc76)cc6c4B5c4ccccc4O6)c23)cc1 ; c1ccc(-n2c3ccccc3c3c2ccc2c4ccccc4n(-c4cc5c6c(c4)Oc4cc(-n7c8ccccc8c8c9sc%10ccccc%10c9ccc87)ccc4B6c4ccccc4O5)c23)cc1 ; c1ccc(-n2c3ccccc3c3c4c5ccccc5n(-c5ccc6c(c5)Oc5cccc7c5B6c5ccc(-n6c8ccccc8c8c9c(ccc86)sc6ccccc69)cc5O7)c4ccc32)cc1]

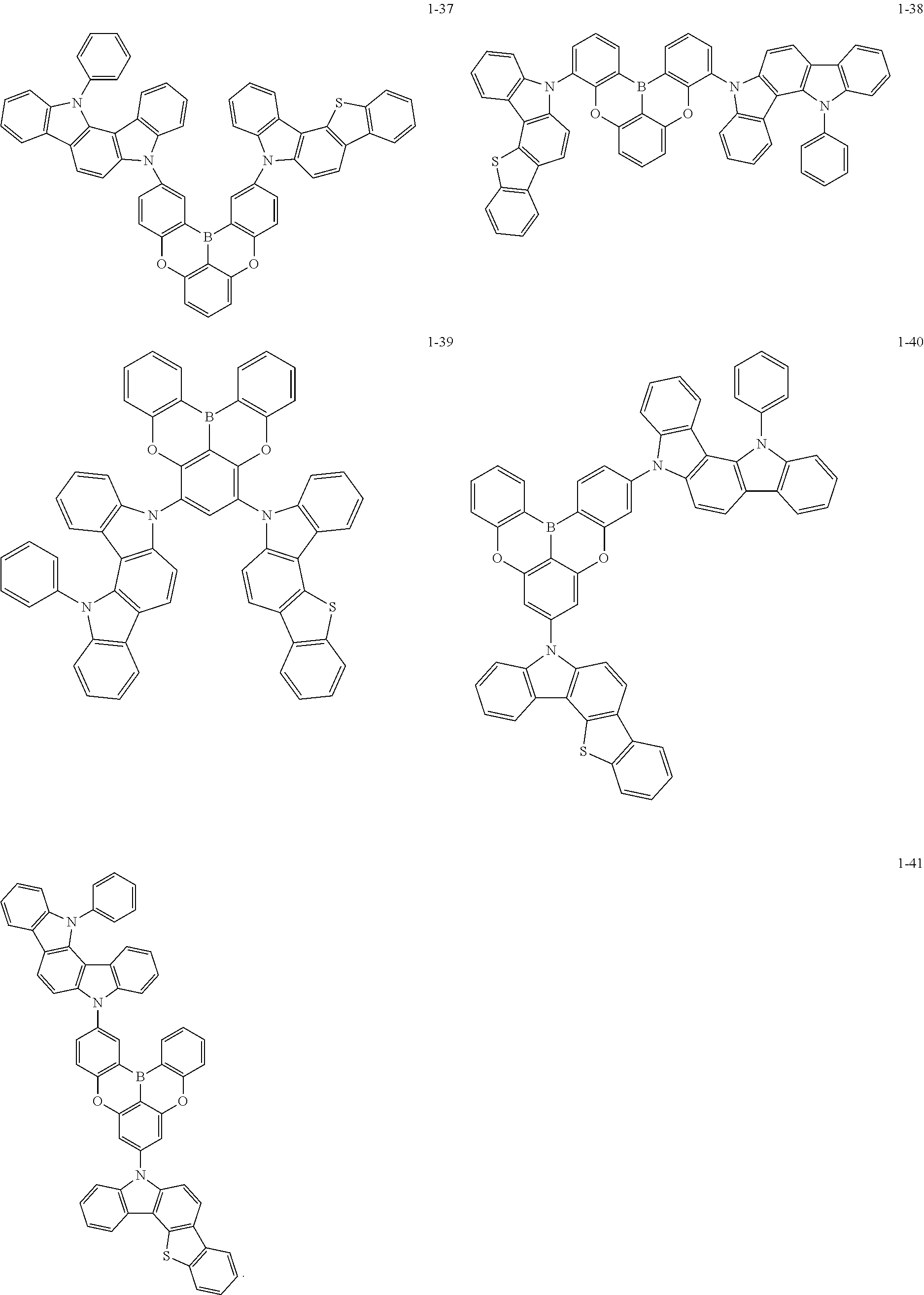

The first compound DF of the delayed fluorescent material has little energy bandgap ΔE_{ST} between the excited singlet energy level SP and the excited triplet energy level T₁^{DF} of equal to or less than about 0.3 eV (FIG. 7) and shows excellent quantum efficiency because the excited triplet exciton energy of the first compound DF is converted to the excited singlet exciton thereof by RISC. However, The first compound DF has a distorted chemical conformation due to the binding structure between the electron donor group moiety and the electron acceptor group moiety. Since the first compound DF utilizes triplet excitons, addition charge transfer transition (CT transition) is induced in the first compound DF. The first compound DF having the structure of Formulae 1 to 6 has a limit in terms of color purity owing to wide full-width at half maximum (FWHM) caused by the CT luminous mechanism.

When the EML 240 includes only the first compound DF as an emitter, the triplet exciton energy of the first compound DF cannot contribute efficiently to the light emission, and the luminous lifespan of the OLED D1 can be reduced owing to quenching mechanisms such as TTA (triplet-triplet annihilation) and/or TPA (triplet-polaron annihilation).

The EML 240 includes the second compound FD of the fluorescent material in order to maximize the luminous properties of the first compound DF of the delayed fluorescent material and to implement hyper-fluorescence. As described above, the first compound DF of the delayed fluorescent material can utilize both the singlet exciton energy and the triplet exciton energy. When the EML 240 includes the second compound FD of the fluorescent material having proper energy levels comparted to the first compound DF of the delayed fluorescent material, the second compound FD can absorb exciton energies released from the first compound DF, and then the second compound FD can generate 100% singlet excitons utilizing the absorbed exciton energies with maximizing its luminous efficiency.

The singlet exciton energy of the first compound DF, which includes the singlet exciton energy of the first compound DF converted from its own triplet exciton energy and initial singlet exciton energy of the first compound DF in the EML 240, is transferred to the second compound FD of the fluorescent material in the same EML 240 via Forster resonance energy transfer (FRET) mechanism, and the ultimate emission is occurred at the second compound FD. Organic material having an absorbance spectrum widely overlapped with a photoluminescence spectrum of the first compound DF can be used as the second compound FD so that the exciton energy generated at the first compound DF can be efficiently transferred to the second compound FD. Since the ultimately emitting second compound FD has narrow FWHM and excellent luminous lifespan, the color purity emitted from the OLED D1 and the luminous lifespan of the OLED D1 can be enhanced.

The second compound FD in the EML 240 can be blue fluorescent material. For example, the second compound FD induced into the EML 240 can be boron-based fluorescent material with equal to or less than about 35 nm of FWHM. As an example, the second compound FD of the boron-based fluorescent material can have the following structure of Formula 7:

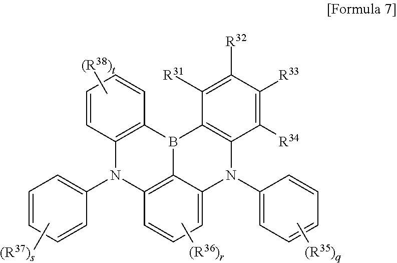

wherein, in Formula 7,

each of R³¹ to R³⁴ is independently hydrogen, deuterium, tritium, halogen, unsubstituted or substituted C₁-C₂₀ alkyl, unsubstituted or substituted C₁-C₂₀ alkyl silyl, unsubstituted or substituted C₁-C₂₀ alkyl amino, an unsubstituted or substituted C₆-C₃₀ aromatic group or an unsubstituted or substituted C₃-C₃₀ hetero aromatic group,

optionally,

two adjacent elements of R³¹ to R³⁴ form an unsubstituted or substituted fused ring having boron and nitrogen;

each of R³⁵ to R³⁸ is independently deuterium, tritium, halogen, unsubstituted or substituted C₁-C₂₀ alkyl, unsubstituted or substituted C₁-C₂₀ alkyl silyl, unsubstituted or substituted C₁-C₂₀ alkyl amino, an unsubstituted or substituted C₆-C₃₀ aromatic group or an unsubstituted or substituted C₃-C₃₀ hetero aromatic group, wherein each R³⁵ is identical to or different from each other when q is an integer of two or more, each R³⁶ is identical to or different from each other when r is an integer of two or more, each R³⁷ is identical to or different from each other when s is an integer of two or more and each R³⁸ is identical to or different from each other when t is an integer of two or more;

each of q and s is independently an integer of 0 to 5;

r is an integer of 0 to 3; and

t is an integer of 0 to 4.

For example, each of the C₆-C₃₀ aromatic group, the C₃-C₃₀ hetero aromatic group and the fused ring having boron and nitrogen constituting R³¹ to R³⁸ can be independently unsubstituted or substituted with at least one of deuterium, tritium, C₁-C₂₀ alkyl, C₆-C₃₀ aryl, C₃-C₃₀ hetero aryl C₆-C₃₀ aryl amino and/or C₃-C₃₀ hetero aryl amino.

Similar to Formulae 1 to 3, the C₆-C₃₀ aromatic group constituting each of R³¹ to R³⁸ in Formula 7 can independently include, but is not limited to, C₆-C₃₀ aryl, C₇-C₃₀ aryl alkyl, C₆-C₃₀ aryl oxy and C₆-C₃₀ aryl amino. The C₃-C₃₀ hetero aromatic group constituting each of R³¹ to R³⁸ in Formula 7 can independently include, but is not limited to, C₃-C₃₀ hetero aryl, C₄-C₃₀ hetero aryl alkyl, C₃-C₃₀ hetero aryl oxy and C₃-C₃₀ hetero aryl amino.

The second compound FD of the boron-based compound having the structure of Formula 7 has excellent luminous properties. Since the second compound FD of the boron-based compound having the structure of Formula 7 includes wide plate-like molecular conformation, the second compound FD can accept efficiently exciton energies released from the first compound DF and maximize the luminous efficiency in the EML 240.

In one aspect, R³¹ to R³⁴ in Formula 7 can be bound to each other. Alternatively, R₃₂ and R³³ in Formula 7 can form the fused ring with boron and nitrogen atoms. As an example, the second compound FD can include a boron-based organic compound having the structure of Formulae 8A to 8C.

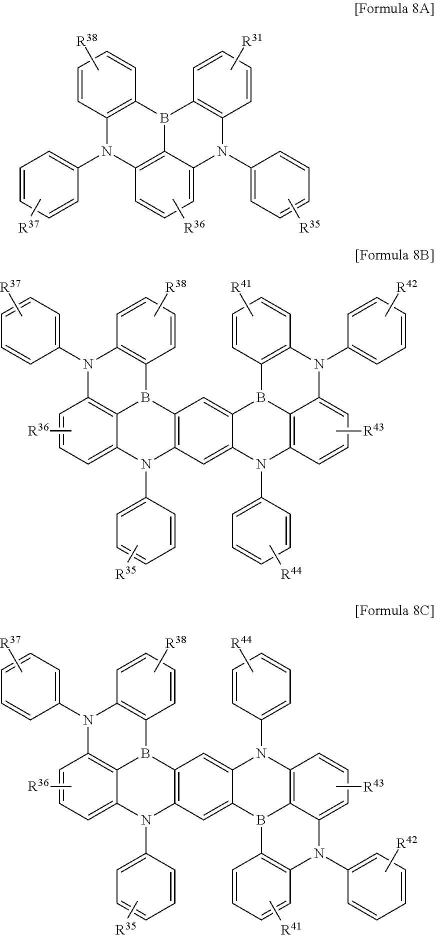

wherein, in Formulae 8A to 8C, each of R³¹, R³⁵ to R³⁸ and R⁴¹ to R⁴⁴ is independently hydrogen, deuterium, tritium, halogen, unsubstituted or substituted C₁-C₂₀ alkyl, unsubstituted or substituted C₁-C₂₀ alkyl silyl, unsubstituted or substituted C₁-C₂₀ alkyl amino, unsubstituted or substituted C₆-C₃₀ aryl or unsubstituted or substituted C₃-C₃₀ hetero aryl.

As an example, each of the C₆-C₃₀ aryl and the C₃-C₃₀ hetero aryl of R³¹, R³⁵ to R³⁸ and R⁴¹ to R⁴⁴ can be independently unsubstituted or substituted with at least one of deuterium, tritium, C₁-C₂₀ alkyl, C₆-C₃₀ aryl, C₃-C₃₀ hetero aryl C₆-C₃₀ aryl amino and/or C₃-C₃₀ hetero aryl amino.

More particularly, the second compound FD of the boron-based organic compound can be selected from, but is not limited to, organic compound having the following structure of Formula 9:

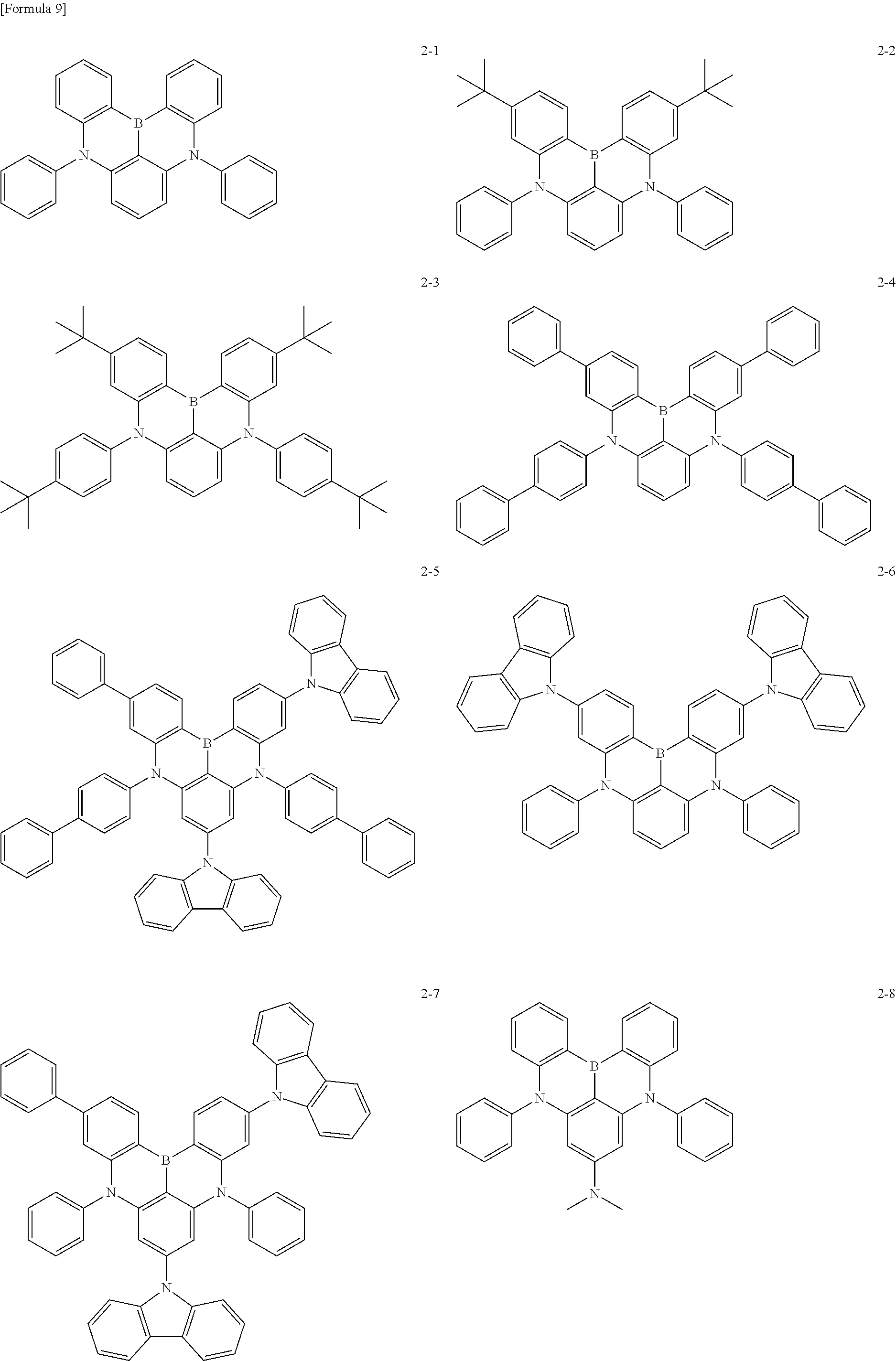

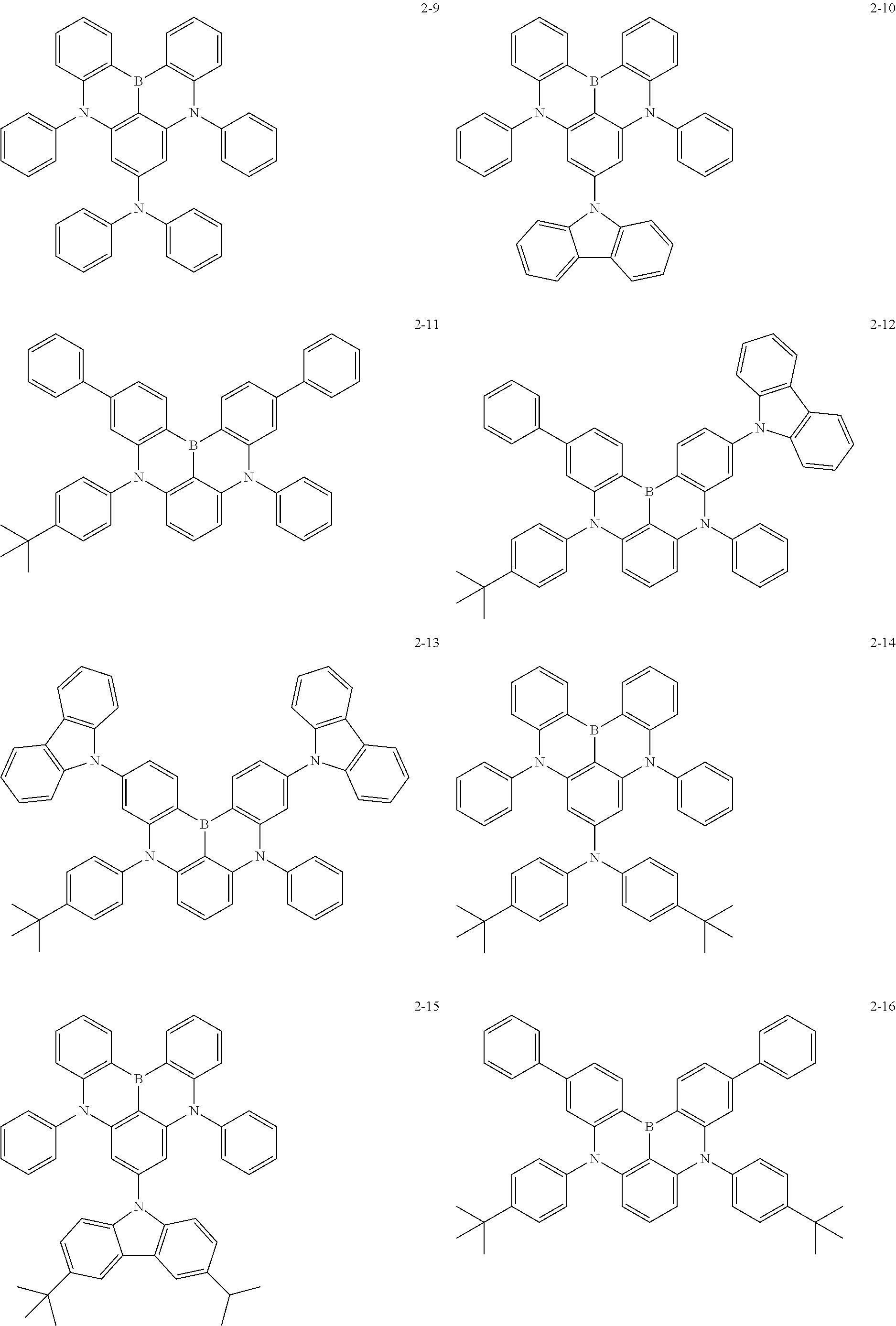

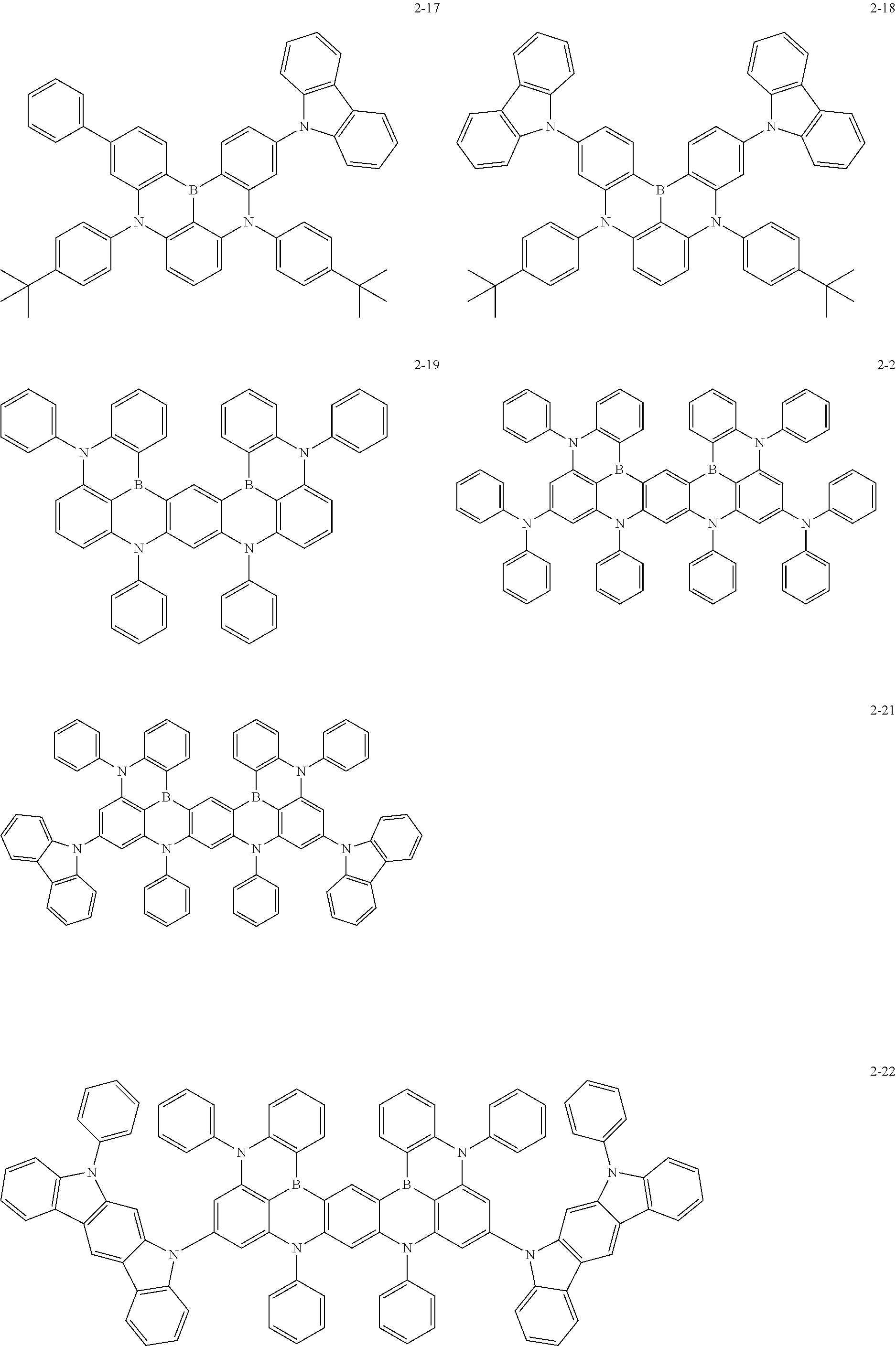

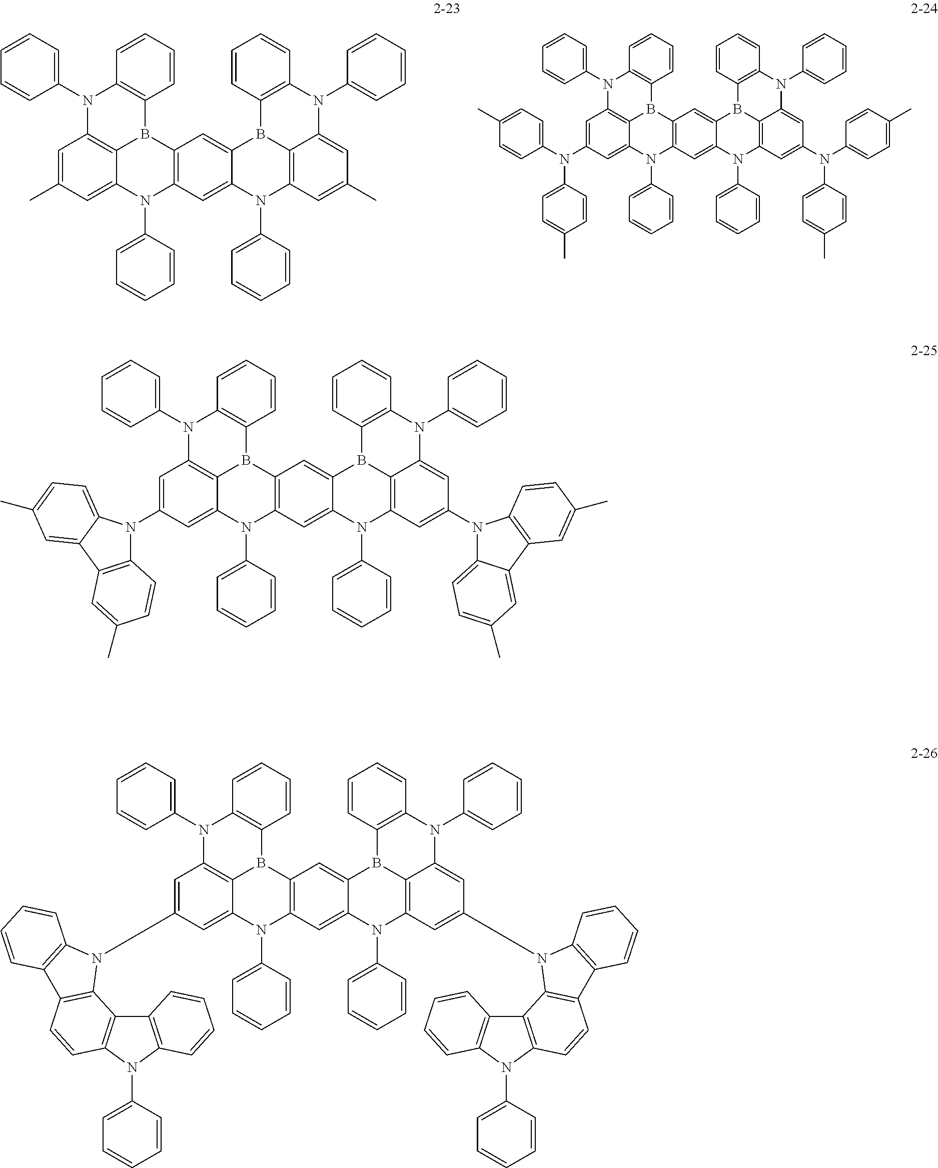

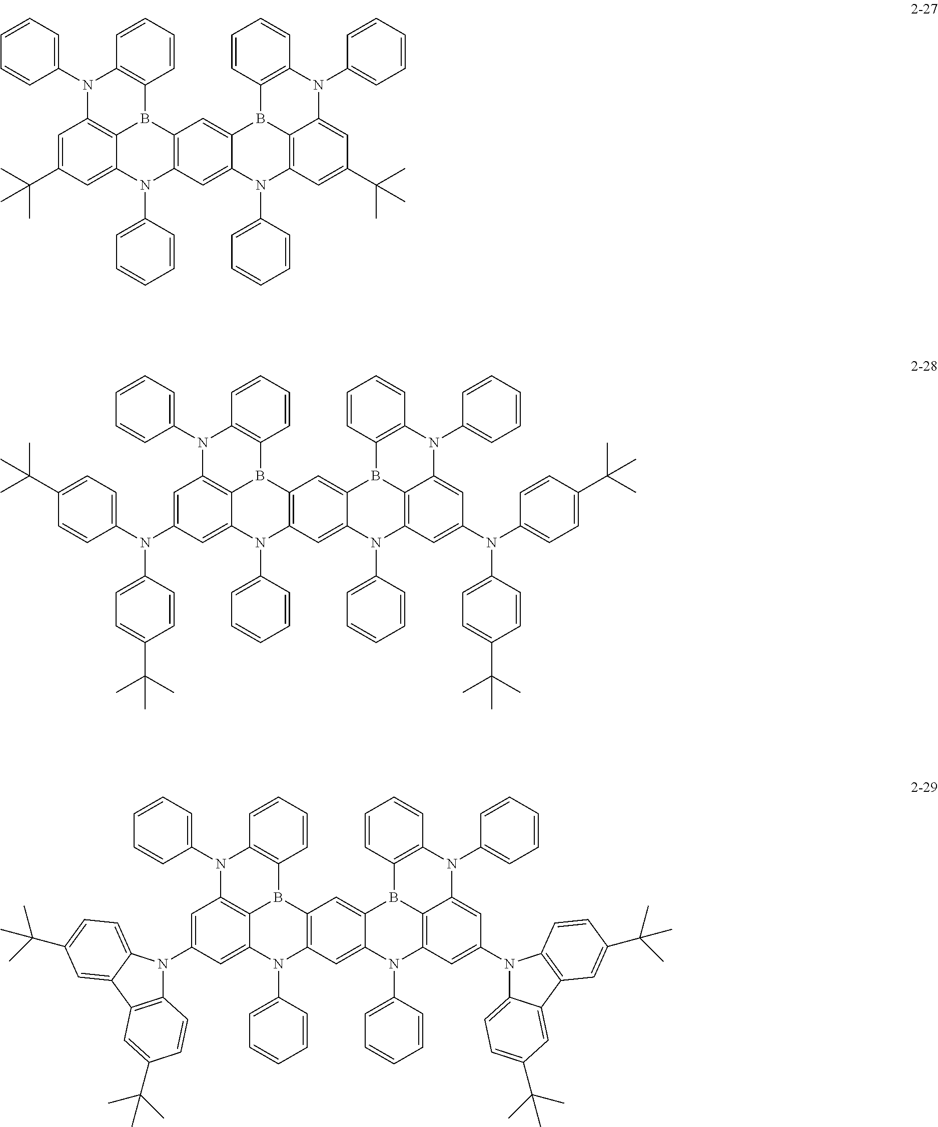

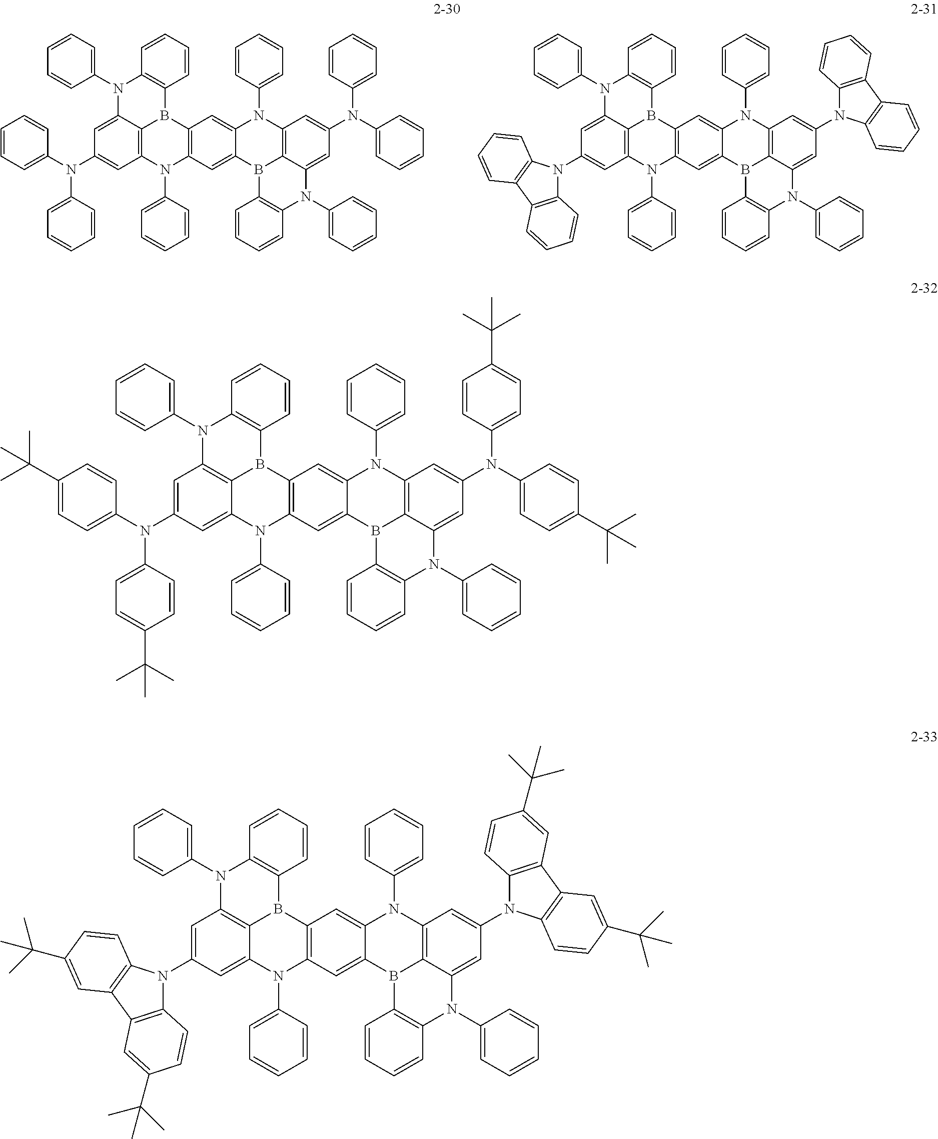

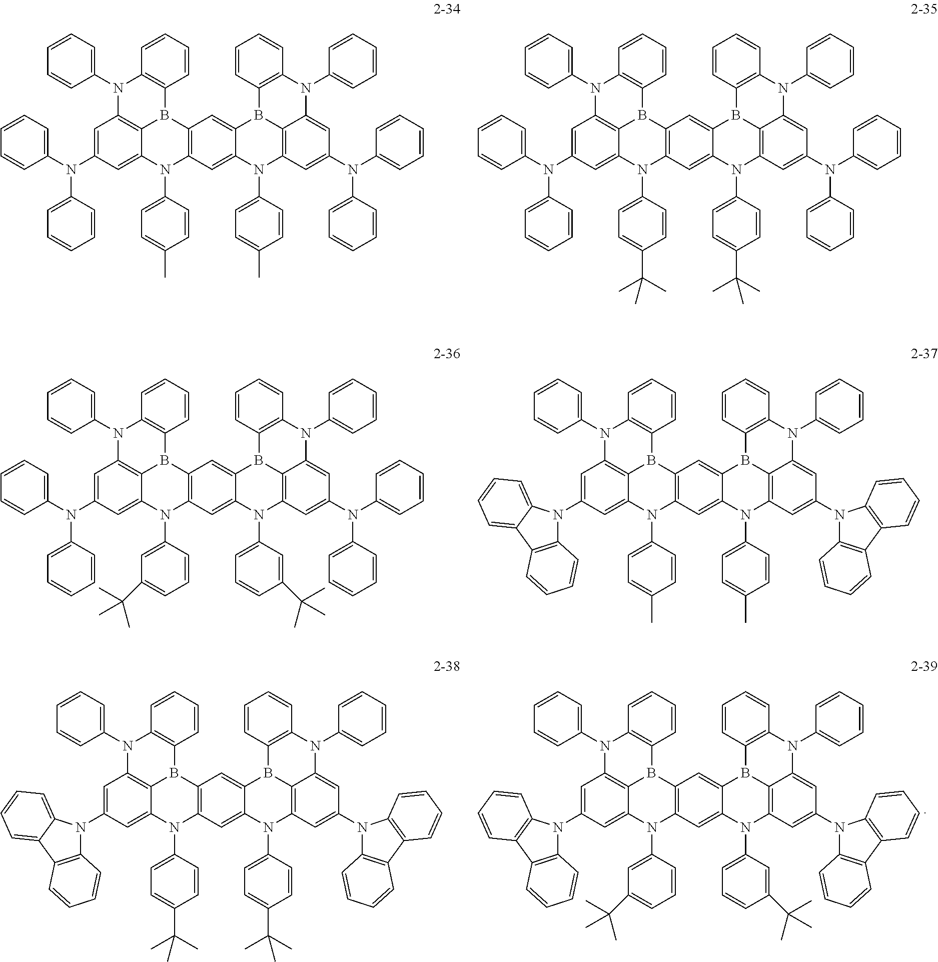

The third compound H in the EML 240 can include any organic compound having wider energy level bandgap between a HOMO energy level and a LUMO energy level compared to the first compound DF and/or the second compound FD. As an example, when the EML 240 includes the third compound H of the host, the first compound DF can be a first dopant and the second compound FD can be a second dopant.

In an aspect, the third compound H, which can be included in the EML 240, can include, but is not limited to, 4,4′-bis(N-carbazolyl)-1,1′-biphenyl (CBP), 3,3′-bis(N-carbazolyl)-1,1′-biphenyl (mCBP), 1,3-Bis(carbazol-9-yl)benzene (mCP), 9-(3-(9H-carbazol-9-yl)phenyl)-9H-carbazole-3-carbonitrile (mCP-CN), Oxybis(2,1-phenylene))bis(diphenylphosphine oxide (DPEPO), 2,8-bis(diphenylphosphoryl)dibenzothiophene (PPT), 1,3,5-Tri[(3-pyridyl)-phen-3-yl]benzene (TmPyPB), 2,6-Di(9H-carbazol-9-yl)pyridine (PYD-2Cz), 2,8-di(9H-carbazol-9-yl)dibenzo[b,d]thiophene (DCzDBT), 3′,5′-Di(carbazol-9-yl)-[1,1′-biphenyl]-3,5-dicarbonitrile (DCzTPA), 4′-(9H-carbazol-9-yl)biphenyl-3,5-dicarbonitrile(4′-(9H-carbazol-9-yl)biphenyl-3,5-dicarbonitrile (pCzB-2CN), 3′-(9H-carbazol-9-yl)biphenyl-3,5-dicarbonitrile (mCzB-2CN), Diphenyl-4-triphenylsilylphenyl-phosphine oxide (TSPO1), 9-(9-phenyl-9H-carbazol-6-yl)-9H-carbazole (CCP), 4-(3-(triphenylene-2-yl)phenyl)dibenzo[b,d]thiophene, 9-(4-(9H-carbazol-9-yl)phenyl)-9H-3,9′-bicarbazole, 9-(3-(9H-carbazol-9-yl)phenyl)-9H-3,9′-bicarbazole, 9-(6-(9H-carbazol-9-yl)pyridin-3-yl)-9H-3,9′-bicarbazole and combination thereof.

In an aspect, when the EML 240 includes the first compound DF, the second compound FD and the third compound H, the contents of the third compound H in the EML 240 can be larger than the contents of the first compound DF in the EML 240, and the contents of the first compound DF in the EML 240 can be larger than the contents of the second compound FD in the EML 240. When the contents of the first compound DF is larger than the contents of the second compound FD, exciton energy can be effectively transferred from the first compound DF to the second compound FD via FRET mechanism. For example, the contents of the third compound H in the EML 240 can be about 55 wt % to about 85 wt %, the contents of the first compound DF in the EML 240 can be about 10 wt % to about 40 wt %, for example, about 10 wt % to about 30 wt %, and the contents of the second compound FD in the EML 240 can be about 0.1 wt % to about 5 wt %, for example, about 0.1 wt % to about 2 wt %, but is not limited thereto.

It may be necessary to control an photoluminescence wavelength and an absorbance wavelength between the first compound DF and the second compound FD in order to improve the luminous efficiency and color purity of the OLED D 1. FIG. 4 is a schematic graph illustrating that the luminous efficiency and color purity of an OLED can be improved by controlling an onset wavelength of the first compound and a maximum absorbance wavelength of the second compound in accordance with an aspect of the present disclosure.

As illustrated in FIG. 4, when the degree of overlap between the photoluminescence (PL) spectrum PL^{DF} of the first compound DF and the absorbance spectrum Abs^{FD} of the second compound FD becomes large, transfer efficiency of exciton energies from the first compound DF to the second compound FD can be improved. As an example, the distance between the maximum photoluminescence wavelength λ_{PL.max}^{DF} of the first compound DF and the maximum absorbance wavelength λ_{Abs.max}^{FD} of the second compound FD can be equal to or less than about 30 nm, for example, about 20 nm. The maximum PL wavelength λ_{PL.max}^{DF} of the first compound DF can be between about 460 nm and about 480 nm, for example, about 470 nm and about 480 nm.

In one aspect, an onset wavelength λₒₙₛₑₜ^{DF} of the first compound DF can be between about 430 nm and about 440 nm. As used herein, the term “onset wavelength” indicates a wavelength value at the point wherein the extrapolation line and an X-axis (wavelength) intersect in a linear region of a short wavelength region in the PL spectrum of the organic compound. More specifically, the onset wavelength can be defined as a wavelength corresponding to a shorter wavelength among two wavelengths having an emission intensity corresponding to 1/10 of the maximum value in the PL spectrum. The onset wavelength λₒₙₛₑₜ^{DF} of the first compound DF can be identical to or shorter than the maximum absorbance wavelength λ_{Abs.max}^{FD} of the second compound FD. As an example, the maximum absorbance wavelength λ_{Abs.max}^{FD} of the second compound FD can be equal to or longer than about 440 nm, for example, between about 440 nm and about 470 nm or between about 450 nm and about 460 nm.

When the onset wavelength λₒₙₛₑₜ^{DF} of the first compound DF is between about 430 nm and about 440 nm and is equal to or shorter than the maximum absorbance wavelength λ_{Abs.max}^{FD} of the second compound FD, both the initial singlet exciton energy and the singlet exciton energy converted by RISC mechanism of the first compound DF can be transferred efficiently to the second compound FD.

Since the first compound DF includes plural electron donor group moieties, the first compound DF shows very large steric hindrance. Therefore, controlling the HOMO and LUMO in the molecule of the first compound DF can maximize its intramolecular charge mobility efficiency, and therefore, the conversion to singlet state from the triplet state in the first compound DF can be occurred rapidly. Accordingly, the triplex exciton generated in the first compound DF can be converted upwardly its own singlet exciton by RISC mechanism without transferring to the second compound FD. The singlet exciton energies generated in the first compound DF is transferred to the second compound FD via FRET mechanism, which is performed with great rapidity.

As such, as the triplet exciton generated in the first compound DF is converted upwardly its own singlet exciton, the converted singlet exciton of the first compound DF can be transferred rapidly to the singlet exciton of the second compound FD. Accordingly, the exciton energy can be efficiently to the second compound FD from the first compound DF, and thus, the luminous efficiency of the OLED D1 can be maximized.

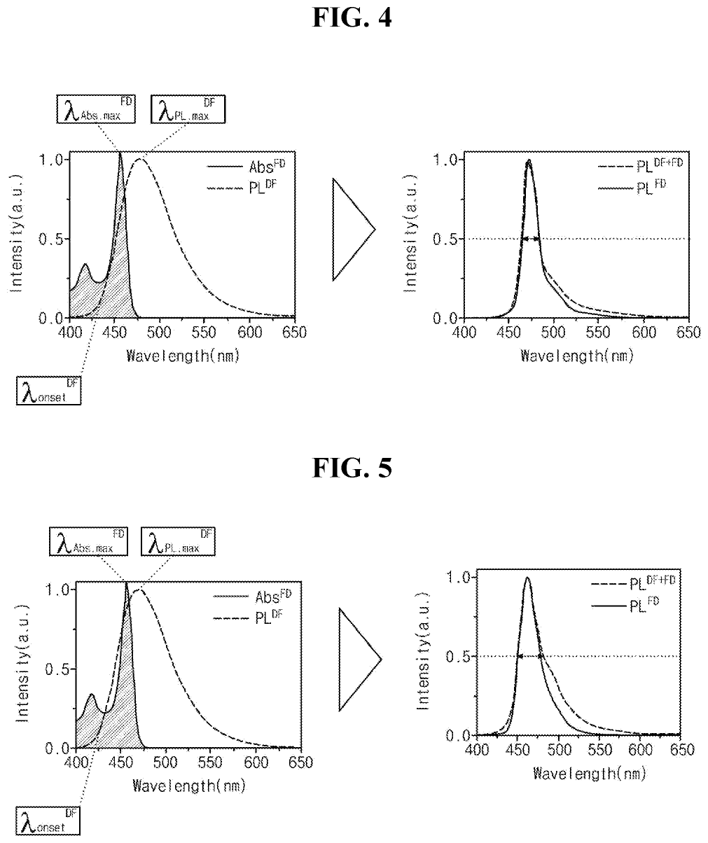

On the contrary, as illustrated in FIG. 5, when the onset wavelength λₒₙₛₑₜ^{DF} of the first compound DF is less than 430 nm, the first compound DF can show lower delayed fluorescent property and/or the second compound H as the host transferring exciton energies to the first compound DF must have very high excited triplet energy level T₁^{H}. In this case, the triplet exciton generated in the first compound DF is not converted its own singlet exciton by RISC and is transferred to the triplet exciton of the second compound FD. Since the triplex exciton transferred to the second compound FD is quenched without involving the luminous process, the luminous efficiency of the OLED can be deteriorated.

In addition, when the onset wavelength λₒₙₛₑₜ^{DF} of the first compound is longer than 440 nm, the maximum PL wavelength λPL.max^{DF} of the first compound DF is excessively spaced apart from the maximum absorbance wavelength λ_{Abs.max}^{FD} of the second compound FD. As the degree of overlap between the PL spectrum PL^{DF} of the first compound DF and the absorbance spectrum Abs^{FD} of the second compound FD decreases, the exciton energy transfer efficiency from the first compound DF to the second compound FD decreases. As the exciton not transferred to the second compound FD remains in the first compound FD, the luminous efficiency of the OLED D1 is reduced because the excitons remained in the first compound DF is quenched as non-emission. In addition, the color purity of the OLED D1 can be deteriorated as the first compound DF and the second compound FD emit light simultaneously.

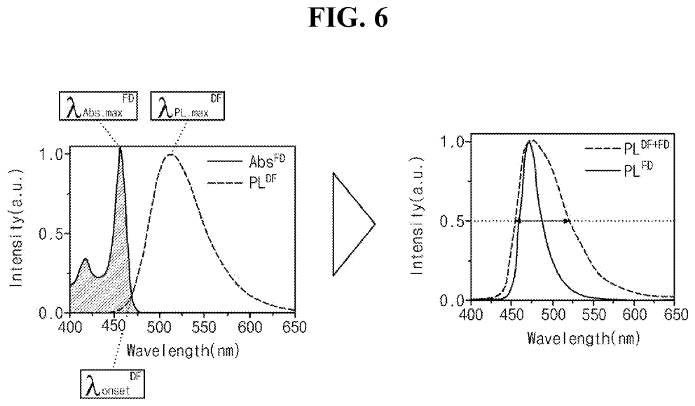

Similarly, as illustrated in FIG. 6, when the onset wavelength λₒₙₛₑₜ^{DF} of the first compound DF is longer than the maximum absorbance wavelength λ_{Abs.max}^{FD} of the second compound FD, as the degree of overlap between the PL spectrum PL^{DF} of the first compound DF and the absorbance spectrum Abs^{FD} of the second compound FD decreases, the exciton energy transfer efficiency from the first compound DF to the second compound FD decreases. As the exciton not transferred to the second compound FD remains in the first compound FD, the luminous efficiency of the OLED D1 is reduced because the excitons remained in the first compound DF is quenched as non-emission. In addition, the color purity of the OLED D1 can be deteriorated as the first compound DF and the second compound FD emit light simultaneously.

In other words, when the onset wavelength λₒₙₛₑₜ^{DF} of the first compound DF is beyond 440 nm and/or the onset wavelength λₒₙₛₑₜ^{DF} of the first compound DF is longer than the maximum absorbance wavelength λ_{Abs.max}^{FD} of the second compound FD, a part of the excitons in the state of excited singlet energy level S₁^{DF} of the first compound DF is converted to the excited triplet energy level T₁^{DF} by Inter System Crossing (ISC). The excitons at the triplet energy level T₁^{DF} in the first compound is not converted upwardly its excited singlet energy level S₁^{DF} by RISC and thus, triplet excitons remained at the excited triplet energy level T₁^{DF} are generated. As such triplet excitons interact with peripheral triplet excitons or polarons, they are quenched by TTA and/or TPA.

In addition, HOMO energy levels and/or LUMO energy levels among the third compound H of the host, the first compound DF of the delayed fluorescent material and the second compound FD of the fluorescent material in the EML 240 should be properly adjusted. For example, the host must induce the triplet excitons generated at the delayed fluorescent material to be involved in the luminescence process without quenching as non-radiative recombination in order to implement hyper fluorescence. To this end, the energy levels among the third compound H of the host, the first compound DF of the delayed fluorescent material and the second compound FD of the fluorescent material should be adjusted.

For example, the HOMO energy level HOMO^{H} of the third compound H of the host can be deeper than the HOMO energy level HOMO^{DF} of the first compound DF of the delayed fluorescent material, and the LUMO energy level LUMO^{H} of the third compound H can be shallower than the LUMO energy level LUMO^{DF} of the first compound DF. In other words, the energy level bandgap between the HOMO energy level HOMO^{H} and the LUMO energy level LUMO^{H} of the third compound H can be wider than the energy level bandgap between the HOMO energy level HOMO^{DF} and the LUMO energy level LUMO^{DF} of the first compound. DF.

As an example, an energy level bandgap (|HOMO^{H}−HOMO^{DF}|) between the HOMO energy level (HOMO^{H}) of the third compound H and the HOMO energy level (HOMO^{DF}) of the first compound DF, or an energy level bandgap (|LUMO^{H}−LUMO^{DF}|) between the LUMO energy level (LUMO^{H}) of the third compound H and the LUMO energy level (LUMO^{DF}) of the first compound DF can be equal to or less than about 0.5 eV, for example, between about 0.1 eV to about 0.5 eV. In this case, the charges can be transported efficiently from the third compound H to the first compound DF and thereby enhancing the ultimate luminous efficiency in the OLED D1.

In addition, the energy level bandgap (|HOMO^{DF}−HOMO^{FD}|) between the HOMO energy level HOMO^{DF} of the first compound DF and the HOMO energy level HOMO^{FD} of the second compound can be less than about 0.3 eV, for example, equal to or less than about 0.2 eV. In this case, the holes injected into the EML 240 can be transferred rapidly to the first compound DF. Accordingly, the first compound DF can implement 100% of internal quantum efficiency utilizing both the initial singlet exciton energy and the singlet exciton energy converted from the triplet exciton energy by RISC mechanism and the first compound DF can transfer the exciton energy efficiently to the second compound FD.

In another aspect, the LUMO energy level LUMO^{DF} of the first compound DF can be identical to or shallower than the LUMO energy level LUMO^{FD} of the second compound FD. As an example, the energy level bandgap between the LUMO energy level LUMO^{DF} of the first compound DF and the LUMO energy level LUMO^{FD} of the second compound can be equal to or less than about 0.5 eV, for example, about 0.2 eV. In this case, the electrons injected into the EML 240 can be transferred rapidly to the first compound DF.

On the contrary, when the energy level bandgap (|HOMO^{DF}−HOMO^{FD}|) between the HOMO energy level HOMO^{DF} of the first compound DF and the HOMO energy level HOMO^{FD} of the second compound FD is equal to or more than 0.3 eV, the holes injected into the EML 240 are not transferred to the first compound DF from the third compound H of the host, but are trapped in the second compound FD. The holes trapped at the second compound FD are directly recombined to form excitons with emission. Since the triplet exciton energy of the first compound DF is quenched without contributing to the light emission, the luminous efficiency of the EML 240 is reduced.

In addition, when the LUMO energy level LUMO^{DF} of the first compound DF is deeper than the LUMO energy level LUMO^{FD} of the second compound FD, an exciplex between the holes trapped in the second compound FD and the electrons transferred to the first compound FD is formed. As the triplet exciton energy of the first compound DF is quenched with non-emission, the luminous efficiency in the EML 240 can be deteriorated. In addition, as the energy bandgap between the LUMO energy level and the HOMO energy level forming the exciplex are excessively narrow, light with longer wavelengths are emitted. As the first compound DF as well as the second compound FD emits light simultaneously, the EML 240 emits light with deteriorated color purity owing to wider FWHM.

As an example, the first compound DF can have, but is not limited to, the HOMO energy level HOMO^{DF} between about −5.5 eV and about −5.7 eV and the LUMO energy level LUMO^{DF} between about −2.5 eV and about 2.8 eV. The second compound FD can have, but is not limited to, the HOMO energy level HOMO^{FD} between about −5.3 eV and about −5.6 eV and the LUMO energy level LUMO^{FD} between about −2.7 eV and about −2.9 eV.

The energy level bandgap between the HOMO energy level HOMO^{DF} and the LUMO energy level LUMO^{DF} of the first compound DF can be wider than the energy level bandgap between the HOMO energy level HOMO^{FD} and the LUMO energy level LUMO^{FD} of the second compound FD. In one aspect, the energy level bandgap between the HOMO energy level HOMO^{DF} and the LUMO energy level LUMO^{DF} of the first compound DF can be between about 2.6 eV and about 3.1 eV, for example, about 2.7 eV and about 3.0 eV. The energy level bandgap between the HOMO energy level HOMO^{FD} and the LUMO energy level LUMO^{FD} of the second compound FD can be between about 2.4 eV and about 2.9 eV, for example, about 2.5 eV and about 2.8 eV. In this case, the exciton energies generated in the first compound DF can be transferred efficiently to the second compound FD in which enough light emissions is occurred.

In case of adjusting the photoluminescence wavelength ranges of the first compound DF and absorbance wavelength ranges of the second compound FD, and HOMO and LUMO energy levels between those compounds, excitons can be recombined in the first compound DF of the delayed fluorescent material, and therefore, 100% of internal quantum efficiency can be realized using RISC mechanism. The excited singlet exciton energy generated in the first compound DF via RISC is transferred to the second compound FD of the fluorescent material by FRET, and the efficient light emission in the second compound FD can be occurred. Accordingly, the OLED D1 having excellent color purity can be realized.

Now, we will describe the luminous mechanism in the EML 240. FIG. 7 is a schematic diagram illustrating luminous mechanism by singlet and triplet energy levels among luminous materials in an EML in accordance with one aspect of the present disclosure. As schematically illustrated in FIG. 7, the singlet energy level S₁^{H} of the third compound H, which can be the host in the EML 240, is higher than the singlet energy level S₁^{DF} of the first compound DF having the delayed fluorescent property. In addition, the triplet energy level T₁^{H} of the third compound H can be higher than the triplet energy level T₁^{DF} of the first compound DF. As an example, the triplet energy level T₁^{H} of the third compound H can be higher than the triplet energy level T₁^{DF} of the first compound DF by at least about 0.2 eV, for example, at least about 0.3 eV such as at least about 0.5 eV.

When the triplet energy level T₁^{H} and/or the singlet energy level S₁^{H} of the third compound H is not high enough than the triplet energy level T₁^{DF} and/or the singlet energy level S₁^{DF} of the first compound DF, the excitons at the triplet energy level T₁^{DF} of the first compound DF can be reversely transferred to the triplet energy level T₁^{H} of the third compound H. In this case, the triplet exciton reversely transferred to the third compound H where the triplet exciton cannot be emitted is quenched as non-emission so that the triplet exciton energy of the first compound DF having the delayed fluorescent property cannot contribute to luminescence. As an example, the first compound DF having the delayed fluorescent property can have the energy level bandgap ΔE_{ST} between the singlet energy level S₁^{DF} and the triplet energy level T₁^{DF} equal to or less than about 0.3 eV, for example, between about 0.05 eV and about 0.3 eV.

In addition, the singlet exciton energy, which is generated in the first compound DF of the delayed fluorescent material that is converted to ICT complex by RISC in the EML 240, should be efficiently transferred to the second compound FD of the fluorescent material so as to implement OLED D1 having high luminous efficiency and high color purity. To this end, the singlet energy level S₁^{DF} of the first compound DF of the delayed fluorescent material is higher than the singlet energy level S₁^{FD} of the second compound FD of the fluorescent material. Optionally, the triplet energy level T₁^{DF} of the first compound DF can be higher than the triplet energy level T₁^{FD} of the second compound FD.

Since the second compound FD can utilize both the singlet exciton energy and the triplet exciton energy of the first compound DF, the luminous efficiency of the OLED D1 can be maximized. In addition, the luminous lifespan of the OLED D1 can be greatly improved owing to minimizing quenching phenomena such as TTA and/or TPA.

Returning to FIG. 3, the HIL 250 is disposed between the first electrode 210 and the HTL 260 and improves an interface property between the inorganic first electrode 210 and the organic HTL 260. In one aspect, the HIL 250 can include, but is not limited to, 4,4′,4″-Tris(3-methylphenylamino)triphenylamine (MTDATA), 4,4′,4″-Tris(N,N-diphenyl-amino)triphenylamine (NATA), 4,4′,4″-Tris(N-(naphthalene-1-yl)-N-phenyl-amino)triphenylamine (1T-NATA), 4,4′,4″-Tris(N-(naphthalene-2-yl)-N-phenyl-amino)triphenylamine (2T-NATA), Copper phthalocyanine (CuPc), Tris(4-carbazoyl-9-yl-phenyl)amine (TCTA), N,N′-Diphenyl-N,N′-bis(1-naphthyl)-1,1′-biphenyl-4,4″-diamine (NPB; NPD), 1,4,5,8,9,11-Hexaazatriphenylenehexacarbonitrile (Dipyrazino[2,3-f:2′3′-h]quinoxaline-2,3,6,7,10,11-hexacarbonitrile; HAT-CN), 1,3,5-tris[4-(diphenylamino)phenyl]benzene (TDAPB), poly(3,4-ethylenedioxythiphene)polystyrene sulfonate (PEDOT/PSS), N-(biphenyl-4-yl)-9,9-dimethyl-N-(4-(9-phenyl-9H-carbazol-3-yl)phenyl)-9H-fluoren-2-amine and combination thereof. The HIL 250 can be omitted in compliance with a structure of the OLED D1.

The HTL 260 is disposed between the HIL 250 and the EML 240. In one aspect, the HTL 260 can include, but is not limited to, N,N′-Diphenyl-N,N′-bis(3-methylphenyl)-1,1′-biphenyl-4,4′-diamine (TPD), NPB, CBP, Poly[N,N′-bis(4-butylphenyl)-N,N′-bis(phenyl)-benzidine] (Poly-TPD), Poly[(9,9-dioctylfluorenyl-2,7-diyl)-co-(4,4′-(N-(4-sec-butylphenyl)diphenylamine))] (TFB), Di-[4-(N,N-di-p-tolyl-amino)-phenyl]cyclohexane (TAPC), 5-Di(9H-carbazol-9-yl)-N,N-diphenylaniline (DCDPA), N-(biphenyl-4-yl)-9,9-dimethyl-N-(4-(9-phenyl-9H-carbazol-3-yl)phenyl)-9H-fluoren-2-amine, N-(biphenyl-4-yl)-N-(4-(9-phenyl-9H-carbazol-3-yl)phenyl)biphenyl-4-amine and combination thereof.

The ETL 270 and the EIL 280 can be laminated sequentially between the EML 240 and the second electrode 230. The ETL 270 includes material having high electron mobility so as to provide electrons stably with the EML 240 by fast electron transportation. In one aspect, the ETL 270 can include, but is not limited to, any one of oxadiazole-based compounds, triazole-based compounds, phenanthroline-based compounds, benzoxazole-based compounds, benzothiazole-based compounds, benzimidazole-based compounds, triazine-based compounds, and the like.

As an example, the ETL 270 can include, but is not limited to, tris-(8-hydroxyquinoline aluminum (Alq₃), 2-biphenyl-4-yl-5-(4-t-butylphenyl)-1,3,4-oxadiazole (PBD), spiro-PBD, lithium quinolate (Liq), 1,3,5-Tris(N-phenylbenzimidazol-2-yl)benzene (TPBi), Bis(2-methyl-8-quinolinolato-N1,08)-(1,1′-biphenyl-4-olato)aluminum (BAlq), 4,7-diphenyl-1,10-phenanthroline (Bphen), 2,9-Bis(naphthalene-2-yl)4,7-diphenyl-1,10-phenanthroline (NBphen), 2,9-Dimethyl-4,7-diphenyl-1,10-phenanthroline (BCP), 3-(4-Biphenyl)-4-phenyl tert-butylphenyl-1,2,4-triazole (TAZ), 4-(Naphthalen-1-yl)-3,5-diphenyl-4H-1,2,4-triazole (NTAZ), 1,3,5-Tri(p-pyrid-3-yl-phenyl)benzene (TpPyPB), 2,4,6-Tris(3′-(pyridin-3-yl)biphenyl-3-yl)1,3,5-triazine (TmPPPyTz), Poly[9,9-bis(3′-(N,N-dimethyl)-N-ethylammonium)-propyl)-2,7-fluorene]-alt-2,7-(9,9-dioctylfluorene)] (PFNBr), tris(phenylquinoxaline) (TPQ), TSPO1 and combination thereof.

The EIL 280 is disposed between the second electrode 230 and the ETL 270, and can improve physical properties of the second electrode 230 and therefore, can enhance the luminous lifespan of the OLED D1. In one aspect, the EIL 280 can include, but is not limited to, an alkali metal halide or an alkaline earth metal halide such as LiF, CsF, NaF, BaF₂ and the like, and/or an organic metal compound such as lithium quinolate, lithium benzoate, sodium stearate, and the like.

When holes are transferred to the second electrode 230 via the EML 240 and/or electrons are transferred to the first electrode 210 via the EML 240, the OLED D1 can have short lifespan and reduced luminous efficiency. In order to prevent these phenomena, the OLED D1 in accordance with this aspect of the present disclosure can have at least one exciton blocking layer adjacent to the EML 240.

For example, the OLED D1 of one aspect includes the EBL 265 between the HTL 260 and the EML 240 so as to control and prevent electron transfers. In one aspect, the EBL 265 can comprise, but is not limited to, TCTA, Tris[4-(diethylamino)phenyl]amine, N-(biphenyl-4-yl)-9,9-dimethyl-N-(4-(9-phenyl-9H-carbazol-3-yl)phenyl)-9H-fluorene-2-amine, TAPC, MTDATA, mCP, mCBP, CuPc, N,N′-bis[4-(bis(3-methylphenyl)amino)phenyl]-N,N′-diphenyl-[1,1′-biphenyl]-4,4′-diamine (DNTPD), TDAPB, 3,6-bis(N-carbazolyl)-N-phenyl-carbazole and combination thereof.

In addition, the OLED D1 can further include the HBL 275 as a second exciton blocking layer between the EML 240 and the ETL 270 so that holes cannot be transferred from the EML 240 to the ETL 270. In one aspect, the HBL 275 can comprise, but is not limited to, any one of oxadiazole-based compounds, triazole-based compounds, phenanthroline-based compounds, benzoxazole-based compounds, benzothiazole-based compounds, benzimidazole-based compounds, and triazine-based compounds each of which can be used in the ETL 270.

For example, the HBL 275 can include a compound having a relatively low HOMO energy level compared to the HOMO energy level of the luminescent materials in EML 240. The HBL 275 can include, but is not limited to, BCP, BAlq, Alq₃, PBD, spiro-PBD, Liq, Bis-4,5-(3,5-di-3-pyridylphenyl)-2-methylpyrimidine (B3PYMPM), DPEPO, 9-(6-(9H-carbazol-9-yl)pyridine-3-yl)-9H-3,9′-bicarbazole and combination thereof.

In the above aspect, the first compound DF having the delayed fluorescent material and the second compound FD having the fluorescent material are included within the same EML. Unlike that aspect, the first compound and the second compound are included in separate EMLs.

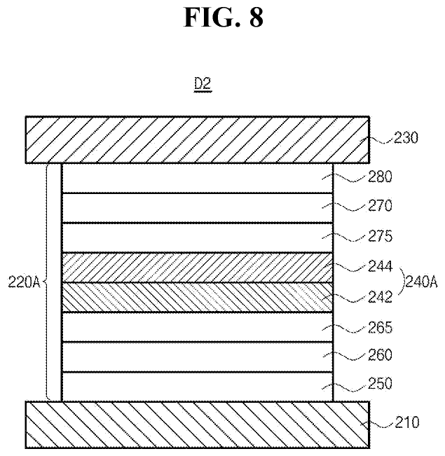

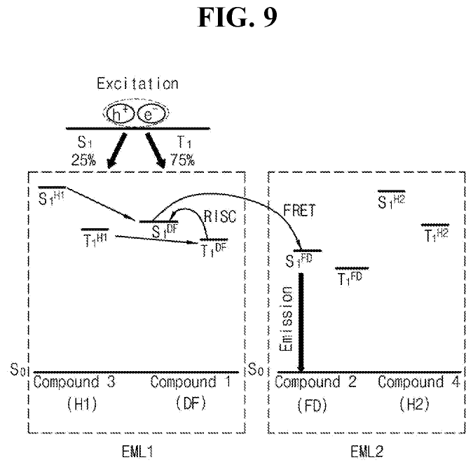

FIG. 8 is a schematic cross-sectional view illustrating an OLED in accordance with another aspect of the present disclosure. FIG. 9 is a schematic diagram illustrating luminous mechanism by singlet and triplet energy levels among luminous materials in EMLs in accordance with another aspect of the present disclosure.

As illustrated in FIG. 8, the OLED D2 includes first and second electrodes 210 and 230 facing each other and an emissive layer 220A having single emitting part disposed between the first and second electrodes 210 and 230. The organic light emitting display device 100 (FIG. 2) includes a red pixel region, a green pixel region and a blue pixel region, and the OLED D2 can be disposed in the blue pixel region.

In one aspect, the emissive layer 220A includes an EML 240A. Also, the emissive layer 220A can include at least one of an HTL 260 disposed between the first electrode 210 and the EML 240A and an ETL 270 disposed between the second electrode 230 and the EML 240A. Also, the emissive layer 220A can further comprise at least one of an HIL 250 disposed between the first electrode 210 and the HTL 260 and an EIL 280 disposed between the second electrode 230 and the ETL 270. Alternatively, the emissive layer 220A can further comprise an EBL 265 disposed between the HTL 260 and the EML 240A and/or an HBL 275 disposed between the EML 240A and the ETL 270. The configuration of the first and second electrodes 210 and 230 as well as other layers except the EML 240A in the emissive layer 220A can be substantially identical to the corresponding electrodes and layers in the OLED D1.

The EML 240A includes a first EML (EML1, lower EML, first layer) 242 disposed between the EBL 265 and the HBL 275 and a second EML (EML2, upper EML, second layer) 244 disposed between the EML1 242 and the HBL 275. Alternatively, the EML2 244 can be disposed between the EBL 265 and the EML1 242.

One of the EML1 242 and the EML2 244 includes the first compound (first dopant) DF of the delayed fluorescent material, and the other of the EML1 242 and the EML2 244 includes the second compound (second dopant) FD of the fluorescent material. Also, each of the EML1 242 and the EML2 244 includes a third compound (Compound 3) H1 of a first host and a fourth compound (Compound 4) H2 of a second host. As an example, the EML1 242 can include the first compound DF and the third compound H1, and the EML2 244 can include the second compound FD and the fourth compound H2.

The first compound DF in the EML1 242 can include any delayed fluorescent material having the structure of Formulae 1 to 6. The triplet exciton energy of the first compound DF having delayed fluorescent property can be converted upwardly to its own singlet exciton energy via RISC mechanism. While the first compound DF has high internal quantum efficiency, but it has poor color purity owing to its wide FWHM.

The EML2 244 includes the second compound FD of the florescent material. The second compound FD includes any organic compound having the structure of Formulae 7 to 9. While the second compound FD of the fluorescent material having the structure of Formulae 7 to 9 has an advantage in terms of color purity due to its narrow FWHM (e.g., equal to or less than about 35 nm).

In this aspect, the singlet exciton energy as well as the triplet exciton energy of the first compound DF having the delayed fluorescent property in the EML1 242 can be transferred to the second compound FD in the EML2 244 disposed adjacently to the EML1 242 by FRET mechanism, and the ultimate light emission occurs in the second compound FD within the EML2 244.

In other words, the triplet exciton energy of the first compound DF is converted upwardly to its own singlet exciton energy in the EML1 242 by RISC mechanism. Then, both the initial singlet exciton energy and the converted singlet exciton energy of the first compound DF is transferred to the singlet exciton energy of the second compound FD in the EML2 244. The second compound FD in the EML2 244 can emit light using the triplet exciton energy as well as the singlet exciton energy.

As the singlet exciton energy generated in the first compound DF in the EML1 242 is efficiently transferred to the second compound FD in the EML2 244, the OLED D2 can implement hyper fluorescence. In this case, while the first compound DF having the delayed fluorescent property only acts as transferring exciton energy to the second compound FD, substantial light emission is occurred in the EML2 244 including the second compound FD. The quantum efficiency and the color purity with narrow FWHM of the OLED D2 can be enhanced.

Each of the EML1 242 and the EML2 244 includes the third compound H1 and the fourth compound H2, respectively. The third compound H1 can be identical to or different from the fourth compound H2. For example, each of the third compound H1 and the fourth compound H2 can include, but is not limited to, the third compound H, as described above.

As described above, the onset wavelength λₒₙₛₑₜ^{DF} of the first compound DF can be equal to or shorter than the maximum absorbance wavelength λ_{Abs.max}^{FD} of the second compound FD, for example, can be between about 430 nm and about 440 nm. In addition, the first and second compounds DF and FD can have the HOMO and LUMO energy levels as described above.

Also, an energy level bandgap (|HOMO^{H}−HOMO^{DF}|) between the HOMO energy levels (HOMO^{H1} and HOMO^{H2}) of the third and fourth compounds H1 and H2 and the HOMO energy level (HOMO^{DF}) of the first compound DF, or an energy level bandgap (|LUMO^{H}−LUMO^{DF}|) between the LUMO energy levels (LUMO^{H1} and LUMO^{H2}) of the third and fourth compounds H1 and H2 and the LUMO energy level (LUMO^{DF}) of the first compound DF can be equal to or less than about 0.5 eV. When the HOMO or LUMO energy level bandgap between the third and fourth compounds H1 and H2 and the first compound DF does not satisfy that condition, the exciton energy in the first compound DF can be quenched as a non-radiative recombination, or exciton energies may not be transferred efficiently to the first compound DF and/or the second compound FD from the third and fourth compounds H1 and H2, thus the internal quantum efficiency in the OLED D2 can be reduced.

Also, each of the exciton energies generated in each of the third compound H1 in the EML1 242 and the fourth compound H2 in the EML2 244 should be transferred primarily to the first compound DF of the delayed florescent material and then to the second compound FD of the fluorescent material in order to realize efficient light emission. As illustrated in FIG. 9, each of the singlet energy levels S₁^{H1} and S₁^{H2} of the third and fourth compounds H1 and H2 is higher than the singlet energy level S₁^{DF} of the first compound DF having the delayed fluorescent property. Also, each of the triplet energy levels T₁^{H1} and T₁^{H2} of the third and fourth compounds H1 and H2 can be higher than the triplet energy level T₁^{DF} of the first compound DF. For example, the triplet energy levels T₁^{H1} and T₁^{H2} of the third and fourth compound H1 and H2 can be higher than the triplet energy level T₁^{DF} of the first compound DF by at least about 0.2 eV, for example, by at least 0.3 eV such as by at least 0.5 eV.

Also, the singlet energy level S₁^{H2} of the fourth compound H2 of the second host is higher than the singlet energy level S₁^{FD} of the second compound FD of the fluorescent material. Optionally, the triplet energy level T₁^{H2} of the fourth compound H2 can be higher than the triplet energy level T₁^{FD} of the second compound FD. In this case, the singlet exciton energy generated at the fourth compound H2 can be transferred to the singlet energy of the second compound FD.

In addition, the singlet exciton energy, which is generated in the first compound DF having the delayed fluorescent property that is converted to ICT complex by RISC in the EML1 242, should be efficiently transferred to the second compound FD of the fluorescent material in the EML2 244. To this end, the singlet energy level S₁^{DF} of the first compound DF of the delayed fluorescent material in the EML1 242 is higher than the singlet energy level S₁^{FD} of the second compound FD of the fluorescent material in the EML2 244. Optionally, the triplet energy level T₁^{DF} of the first compound DF in the EML1 242 can be higher than the triplet energy level T₁^{FD} of the second compound FD in the EML2 244.

Each of the contents of the third and fourth compounds H1 and H2 in the EML1 242 and the EML2 244 can be larger than or identical to each of the contents of the first and second compounds DF and FD in the same layer, respectively. Also, the contents of the first compound DF in the EML1 242 can be larger than the contents of the second compound FD in the EML2 244. In this case, exciton energy is efficiently transferred from the first compound DF to the second compound FD via FRET mechanism. As an example, the EML1 242 can include the first compound DF between about 1 wt. % and about 50 wt. %, for example, about 10 wt. % and about 40 wt. % such as about 20 wt. % and about 40 wt. %. The EML2 244 can include the second compound FD between about 1 wt % and about 10 wt. %, for example, about 1 wt. % and 5 wt. %.

In one aspect, when the EML2 244 is disposed adjacently to the HBL 275, the fourth compound H2 in the EML2 244 can be the same material as the HBL 275. In this case, the EML2 244 can have a hole blocking function as well as an emission function. In other words, the EML2 244 can act as a buffer layer for blocking holes. In one aspect, the HBL 275 can be omitted where the EML2 244 can be a hole blocking layer as well as an emitting material layer.

In another aspect, when the EML2 244 is disposed adjacently to the EBL 265, the fourth compound H2 in the EML2 244 can be the same as the EBL 265. In this case, the EML2 244 can have an electron blocking function as well as an emission function. In other words, the EML2 244 can act as a buffer layer for blocking electrons. In one aspect, the EBL 265 can be omitted where the EML2 244 can be an electron blocking layer as well as an emitting material layer.

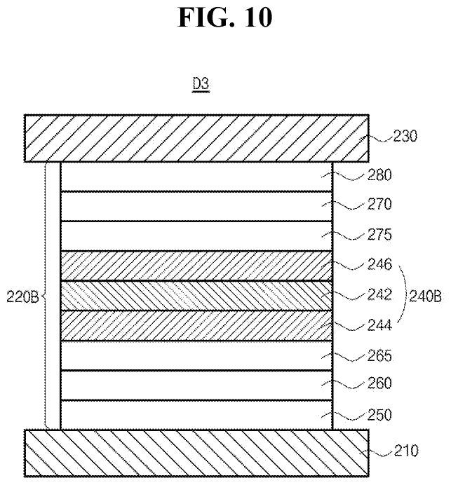

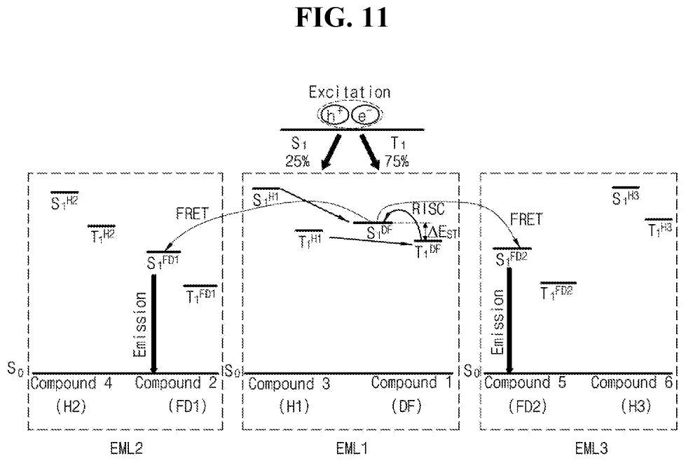

An OLED having a triple-layered EML will be explained. FIG. 10 is a schematic cross-sectional view illustrating an OLED in accordance with still another aspect of the present disclosure. FIG. 11 is a schematic diagram illustrating luminous mechanism by singlet and triplet energy levels among luminous materials in EMLs in accordance with still another aspect of the present disclosure.

As illustrated in FIG. 10, the OLED D3 includes first and second electrodes 210 and 230 facing each other and an emissive layer 220B disposed between the first and second electrodes 210 and 230. The organic light emitting display device 100 (FIG. 2) includes a red pixel region, a green pixel region and a blue pixel region, and the OLED D3 can be disposed in the blue pixel region.

In one aspect, the emissive layer 220B having single emitting part includes a triple-layered EML 240B. The emissive layer 220B can include at least one of an HTL 260 disposed between the first electrode 210 and the EML 240B and an ETL 270 disposed between the second electrode 230 and the EML 240B. Also, the emissive layer 220B can further include at least one of an HIL 250 disposed between the first electrode 210 and the HTL 260 and an EIL 280 disposed between the second electrode 230 and the ETL 270. Alternatively, the emissive layer 220B can further include an EBL 265 disposed between the HTL 260 and the EML 240B and/or an HBL 275 disposed between the EML 240B and the ETL 270. The configurations of the first and second electrodes 210 and 230 as well as other layers except the EML 240B in the emissive layer 220B is substantially identical to the corresponding electrodes and layers in the OLEDs D1 and D2.

The EML 240B includes a first EML (EML1, middle EML, first layer) 242, a second EML (EML2, lower EML, second layer) 244 and a third EML (EML3, upper EML, third layer) 246. The EML1 242 is disposed between the EBL 265 and the HBL 275, the EML2 244 is disposed between the EBL 265 and the EML1 242 and the EML3 246 is disposed between the EML1 242 and the HBL 275.

The EML1 242 includes the first compound (first dopant) DF of the delayed fluorescent material. Each of the EML2 244 and the EML3 246 includes the second compound (second dopant) FD1 and a fifth compound (Compound 5, third dopant) FD2 each of which is the fluorescent material, respectively. Also, each of the EML1 242, the EML2 244 and the EML3 246 includes the third compound H1 of the first host, the fourth compound H2 of the second host and a sixth compound (Compound 6) H3 of a third host, respectively.

In accordance with this aspect, both the singlet energy as well as the triplet energy of the first compound DF of the delayed fluorescent material in the EML1 242 can be transferred to the second and fifth compounds FD1 and FD2 of the fluorescent materials each of which is included in the EML2 244 and EML3 246 disposed adjacently to the EML1 242 by FRET mechanism. Accordingly, the ultimate emission occurs in the second and fifth compounds FD1 and FD2 in the EML2 244 and the EML3 246.

In other words, the triplet exciton energy of the first compound DF having the delayed fluorescent property in the EML1 242 is converted upwardly to its own singlet exciton energy by RISC mechanism, then the singlet exciton energy including the initial and converted singlet exciton energy of the first compound DF is transferred to the singlet exciton energy of the second and fifth compounds FD1 and FD2 in the EML2 244 and the EML3 246 because the first compound DF has the singlet energy level S₁^{DF} higher than each of the singlet energy levels S₁^{FD1} and S₁^{FD2} of the second and fifth compounds FD1 and FD2. The singlet exciton energy of the first compound DF in the EML1 242 is transferred to the second and fifth compounds FD1 and FD2 in the EML2 244 and the EML3 246 which are disposed adjacently to the EML1 242 by FRET mechanism.

Both the second and fifth compounds FD1 and FD2 in the EML2 244 and EML3 246 can emit light using the singlet exciton energy as well as the triplet exciton energy derived from the first compound DF. Each of the second and fifth compounds FD1 and FD2 has narrow FWHM (e.g., equal to or less than about 35 nm) compared to the first compound DF. The quantum efficiency and color purity owing to narrow FWHM of the OLED D3 can be enhanced. The ultimate emission occurs in the EML2 244 and the EML3 246 each of which includes the second compound FD1 and the fifth compound FD2, respectively.

The first compound DF of the delayed fluorescent material includes any organic compound having the structure of Formulae 1 to 6. Each of the second and fifth compounds FD1 and FD2 of the fluorescent material includes independently any organic compound having the structure of Formulae 7 to 9. The third compound H1, the fourth compound H2 and the sixth compound H3 can be identical to or different from each other. For example, each of the third compound H1, the fourth compound H2 and the sixth compound H3 can independently include, but is not limited to, the third compound H as described above.

Similar to the first and second aspects, the onset wavelength λₒₙₛₑₜ^{DF} of the first compound DF can identical to or shorter than each of the maximum absorbance wavelengths λ_{Abs.max}^{FD} of the second and fifth compound FD1 and FD2, for example, can be between about 430 nm and about 440 nm. In addition, the first compound DF1 and the second and fifth compounds FD1 and FD2 can have the HOMO and LUMO energy levels as described above.

Also, an energy level bandgap (|HOMO^{H}−HOMO^{D}|) between the HOMO energy levels (HOMO^{H1}, HOMO^{H2} and HOMO^{H3}) of the third, fourth and sixth compounds H1, H2 and H3 and the HOMO energy level (HOMO^{DF}) of the first compound DF, or an energy level bandgap (|LUMO^{H}−LUMO^{DF}|) between the LUMO energy levels (LUMO^{H1}, LUMO^{H2} and LUMO^{H3}) of the third, fourth and sixth compounds H1, H2 and H3 and the LUMO energy level (LUMO^{DF}) of the first compound DF can be equal to or less than about 0.5 eV.

The singlet and triplet energy levels among the luminous materials should be properly adjusted in order to implement efficient luminescence. Referring to FIG. 11, each of the singlet energy levels S₁^{H1}, S₁^{H2} and S₁^{H3} of the third, fourth and sixth compounds H1, H2 and H3 of the first to third hosts is higher than the singlet energy level S₁^{DF} of the first compound DF having the delayed fluorescent property. Also, each of the triplet energy levels T₁^{H1}, T₁^{H2} and T₁^{H}3 of the third, fourth and sixth compounds H1, H2 and H3 can be higher than the triplet energy level T₁^{DF} of the first compound DF.

In addition, the singlet exciton energy, which is generated in the first compound DF having the delayed fluorescent property that is converted to ICT complex by RISC in the EML1 242, should be efficiently transferred to each of second and fifth compounds FD1 and FD2 of the fluorescent material in the EML2 244 and the EML3 246. To this end, the triplet energy level S₁^{DF} of the first compound DF of the delayed fluorescent material in the EML1 242 is higher than each of the singlet energy levels S₁^{DF} and S₁^{FD2} of the second and fifth compounds FD1 and FD2 of the fluorescent material in the EML2 244 and the EML3 246. Optionally, the triplet energy level T₁^{DF} of the first compound DF in the EML1 242 can be higher than each of the triplet energy levels T₁^{FD1} and T₁^{FD2} of the second and fifth compounds FD1 and FD2 in the EML2 244 and the EML3 246.

In addition, exciton energy transferred to each of the second and fifth compounds FD1 and FD2 from the first compound DF should not be transferred to each of the fourth and sixth compounds H2 and H3 in order to realize efficient luminescence. To this end, each of the singlet energy levels S₁^{H2} and S₁^{H3} of the fourth and sixth compounds H2 and H3, each of which can be the second host and the third host, is higher than each of the singlet energy levels S₁^{FD1} and S₁^{FD2} of the third and sixth compounds FD1 and FD2 of the fluorescent material, respectively. Optionally, each of the triplet energy levels T₁^{H2} and T₁^{H3} of the fifth and sixth compounds H2 and H3 is higher than each of the triplet energy levels T₁^{FD1} and T₁^{FD2} of the third and sixth compounds FD1 and FD2, respectively.

As an example, the EML1 242 can include the first compounds DF between about 1 wt % and about 50 wt %, for example, about 10 wt % and about 40 wt % or about 20 wt % and about 40 wt %. Each of the EML2 244 and the EML3 246 can include the second and fifth compounds FD1 and FD2 between about 1 wt % and about 10 wt %, for example, about 1 wt % and 5 wt %.

In one aspect, when the EML2 244 is disposed adjacently to the EBL 265, the fourth compound H2 in the EML2 244 can be the same material as the EBL 265. In this case, the EML2 244 can have an electron blocking function as well as an emission function. In other words, the EML2 244 can act as a buffer layer for blocking electrons. In one aspect, the EBL 265 can be omitted where the EML2 244 can be an electron blocking layer as well as an emitting material layer.

When the EML3 246 is disposed adjacently to the HBL 275, the sixth compound H3 in the EML3 246 can be the same material as the HBL 275. In this case, the EML3 246 can have a hole blocking function as well as an emission function. In other words, the EML3 246 can act as a buffer layer for blocking holes. In one aspect, the HBL 275 can be omitted where the EML3 246 can be a hole blocking layer as well as an emitting material layer.

In still another aspect, the fourth compound H2 in the EML2 244 can be the same material as the EBL 265 and the sixth compound H3 in the EML3 246 can be the same material as the HBL 275. In this aspect, the EML2 244 can have an electron blocking function as well as an emission function, and the EML3 246 can have a hole blocking function as well as an emission function. In other words, each of the EML2 244 and the EML3 246 can act as a buffer layer for blocking electrons or hole, respectively. In one aspect, the EBL 265 and the HBL 275 can be omitted where the EML2 244 can be an electron blocking layer as well as an emitting material layer and the EML3 246 can be a hole blocking layer as well as an emitting material layer.

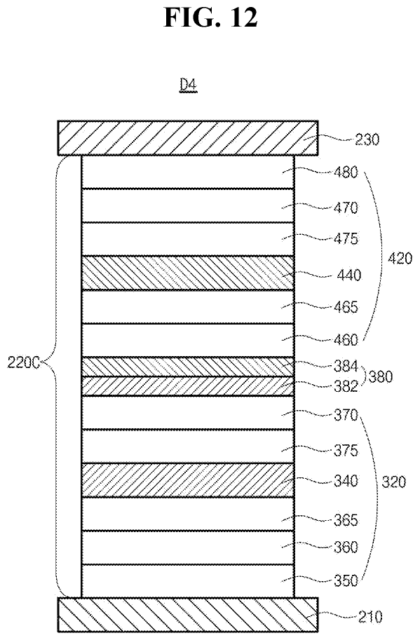

In an alternative aspect, an OLED can include multiple emitting parts. FIG. 12 is a schematic cross-sectional view illustrating an OLED in accordance with still another aspect of the present disclosure.

As illustrated in FIG. 12, the OLED D4 includes first and second electrodes 210 and 230 facing each other and an emissive layer 220C with two emitting parts disposed between the first and second electrodes 210 and 230. The organic light emitting display device 100 (FIG. 2) includes a red pixel region, a green pixel region and a blue pixel region, and the OLED D4 can be disposed in the blue pixel region. The first electrode 210 can be an anode and the second electrode 230 can be a cathode.

The emissive layer 220C includes a first emitting part 320 that includes a first EML (lower EML, EML1) 340 and a second emitting part 420 that includes a second EML (upper EML, EML2) 440. Also, the emissive layer 220C can further include a charge generation layer (CGL) 380 disposed between the first emitting part 320 and the second emitting part 420.

The CGL 380 is disposed between the first and second emitting parts 320 and 420 so that the first emitting part 320, the CGL 380 and the second emitting part 420 are sequentially disposed on the first electrode 210. In other words, the first emitting part 320 is disposed between the first electrode 210 and the CGL 380 and the second emitting part 420 is disposed between the second electrode 230 and the CGL 380.

The first emitting part 320 includes the EML1 340. The first emitting part 320 can further includes at least one of an HIL 350 disposed between the first electrode 210 and the EML1 340, a first HTL (HTL1) 360 disposed between the HIL 350 and the EML1 340 and a first ETL (ETL1) 370 disposed between the EML1 340 and the CGL 380. Alternatively, the first emitting part 320 can further include a first EBL (EBL1) 365 disposed between the HTL1 360 and the EML1 340 and/or a first HBL (HBL1) 375 disposed between the EML1 340 and the ETL1 370.

The second emitting part 420 includes the EML2 440. The second emitting part 420 can further include at least one of a second HTL (HTL2) 460 disposed between the CGL 380 and the EML2 440, a second ETL (ETL2) 470 disposed between the EML2 440 and the second electrode 230 and an EIL 480 disposed between the ETL2 470 and the second electrode 230. Alternatively, the second emitting part 420 can further include a second EBL (EBL2) 465 disposed between the HTL2 460 and the EML2 440 and/or a second HBL (HBL2) 475 disposed between the EML2 440 and the ETL2 470.

The CGL 380 is disposed between the first emitting part 320 and the second emitting part 420. The first emitting part 320 and the second emitting part 420 are connected via the CGL 380. The CGL 380 can be a PN-junction CGL that junctions an N-type CGL (N-CGL) 382 with a P-type CGL (P-CGL) 384.

The N-CGL 382 is disposed between the ETL1 370 and the HTL2 460 and the P-CGL 384 is disposed between the N-CGL 382 and the HTL2 460. The N-CGL 382 transports electrons to the EML1 340 of the first emitting part 320 and the P-CGL 384 transport holes to the EML2 440 of the second emitting part 420.

In this aspect, each of the EML1 340 and the EML2 440 can be a blue emitting material layer. For example, at least one of the EML1 340 and the EML2 440 can include the first compound DF of the delayed fluorescent material, the second compound FD of the fluorescent material, and optionally the third compound H of the host.

As an example, when the EML1 340 and/or the EML2 440 includes the first to third compounds DF, FD and H, the contents of the third compound H in the EML1 340 and/or the EML2 440 can be larger than or equal to the contents of the first compound DF, and the contents of the first compound DF can be larger than the contents of the second compound FD. In this case, exciton energy can be transferred efficiently from the first compound DF to the second compound FD.

In one aspect, the EML2 440 can include the first and second compounds DF and FD, and optionally the third compound H as the same as the EML1 340. Alternatively, the EML2 440 can include another compound that is different from at least one of the first compound DF and the second compound FD in the EML1 340, and thus the EML2 440 can emit light different from the light emitted from the EML1 340 or can have different luminous efficiency different from the luminous efficiency of the EML1 340.

In FIG. 12, each of the EML1 340 and the EML2 440 has a single-layered structure. Alternatively, each of the EML1 340 and the EML2 440, each of which can include the first to third compounds DF, FD and H, can have a double-layered structure (FIG. 8) or a triple-layered structure (FIG. 10), respectively.

In the OLED D4, the singlet exciton energy of the first compound DF of the delayed fluorescent material is transferred to the second compound FD of fluorescent material, and the ultimate emission is occurred at the second compound FD. Accordingly, the luminous efficiency and color purity of the OLED D4 can be improved. Particularly, at least the EML1 340 includes the first compound DF having the structure of Formulae 1 to 6 and the second compound FD having the structure of Formulae 7 to 9, and thus the luminous efficiency and color purity of the OLED D4 can be further enhanced. Moreover, since the OLED D4 has a double stack structure of a blue emitting material layer, the color sense of the OLED D4 can be further improved and the luminous efficiency of the OLED D4 can be further optimized.

FIG. 13 is a schematic cross-sectional view illustrating an organic light emitting display device in accordance with another aspect of the present disclosure. As illustrated in FIG. 13, an organic light emitting display device 500 includes a substrate 510 that defines first to third pixel regions P1, P2 and P3, a thin film transistor Tr disposed over the substrate 510 and an OLED D disposed over the thin film transistor Tr and connected to the thin film transistor Tr. As an example, the first pixel region P1 can be a blue pixel region, the second pixel region P2 can be a green pixel region and the third pixel region P3 can be a red pixel region.

The substrate 510 can be a glass substrate or a flexible substrate. For example, the flexible substrate can be any one of a PI substrate, a PES substrate, a PEN substrate, a PET substrate and a PC substrate. A buffer layer 512 is disposed over the substrate 510 and the thin film transistor Tr is disposed over the buffer layer 512. The buffer layer 512 can be omitted. As illustrated in FIG. 2, the thin film transistor Tr includes a semiconductor layer, a gate electrode, a source electrode and a drain electrode and acts as a driving element.

A passivation layer 550 is disposed over the thin film transistor Tr. The passivation layer 550 has a flat top surface and includes a drain contact hole 552 that exposes a drain electrode of the thin film transistor Tr.

The OLED D is disposed over the passivation layer 550, and includes a first electrode 610 that is connected to the drain electrode of the thin film transistor Tr, and an emissive layer 620 and a second electrode 630 each of which is disposed sequentially on the first electrode 610. The OLED D is disposed in each of the first to third pixel regions P1, P2 and P3 and emits different light in each pixel region. For example, the OLED D in the first pixel region P1 can emit blue light, the OLED D in the second pixel region P2 can emit green light and the OLED D in the third pixel region P3 can emit red light.

The first electrode 610 is separately formed for each of the first to third pixel regions P1, P2 and P3, and the second electrode 630 corresponds to the first to third pixel regions P1, P2 and P3 and is formed integrally.

The first electrode 610 can be one of an anode and a cathode, and the second electrode 630 can be the other of the anode and the cathode. In addition, one of the first electrode 610 and the second electrode 630 can be a transmissive (or semi-transmissive) electrode and the other of the first electrode 610 and the second electrode 630 can be a reflective electrode.

For example, the first electrode 610 can be an anode and can include conductive material having a relatively high work function value, i.e., a transparent conductive oxide layer of transparent conductive oxide (TCO). The second electrode 630 can be a cathode and can include conductive material having relatively low work function value, i.e., a metal material layer of low-resistant metal. For example, the first electrode 610 can include any one of ITO, IZO, ITZO, SnO, ZnO, ICO and AZO, and the second electrode 630 can include Al, Mg, Ca, Ag, alloy thereof (e.g. Mg—Ag) or combination thereof.

When the organic light emitting display device 500 is a bottom-emission type, the first electrode 610 can have a single-layered structure of a transparent conductive oxide layer. Alternatively, when the organic light emitting display device 500 is a top-emission type, a reflective electrode or a reflective layer can be disposed under the first electrode 610. For example, the reflective electrode or the reflective layer can include, but is not limited to, Ag or APC alloy. In the OLED D of the top-emission type, the first electrode 610 can have a triple-layered structure of ITO/Ag/ITO or ITO/APC/ITO. Also, the second electrode 630 is thin so as to have light-transmissive (or semi-transmissive) property.

A bank layer 560 is disposed on the passivation layer 550 in order to cover edges of the first electrode 610. The bank layer 560 corresponds to each of the first to third pixel regions P1, P2 and P3 and exposes a center of the first electrode 610.

An emissive layer 620 is disposed on the first electrode 610. In one aspect, the emissive layer 620 can have a single-layered structure of an EML. Alternatively, the emissive layer 620 can include at least one of an HIL, an HTL, and an EBL disposed sequentially between the first electrode 610 and the EML and/or an HBL, an ETL and an EIL disposed sequentially between the EML and the second electrode 630.

In one aspect, the EML of the emissive layer 630 in the first pixel region P1 of the blue pixel region can include the first compound DF of the delayed fluorescent material having the structure of Formulae 1 to 6, the second compound FD of the fluorescent material having the structure of Formula 7 to 9, and optionally the third compound H.

An encapsulation film 570 is disposed over the second electrode 630 in order to prevent outer moisture from penetrating into the OLED D. The encapsulation film 570 can have, but is not limited to, a triple-layered structure of a first inorganic insulating film, an organic insulating film and a second inorganic insulating film.

The organic light emitting display device 500 can have a polarizer in order to decrease external light reflection. For example, the polarizer can be a circular polarizer. When the organic light emitting display device 500 is a bottom-emission type, the polarizer can be disposed under the substrate 510. Alternatively, when the organic light emitting display device 500 is a top emission type, the polarizer can be disposed over the encapsulation film 570.

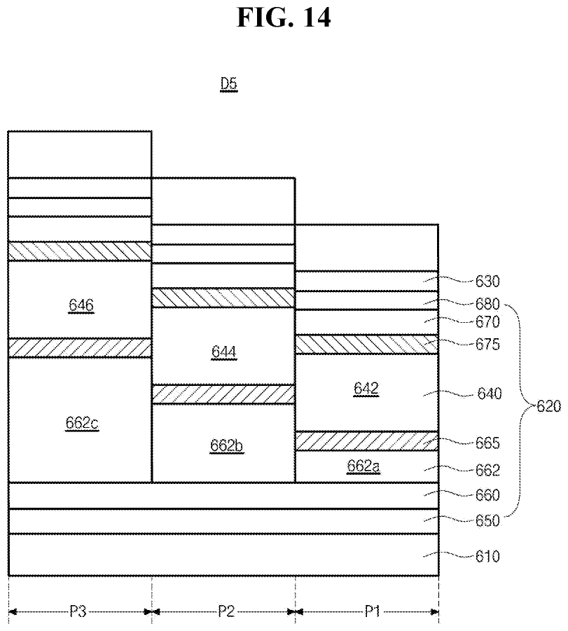

FIG. 14 is a schematic cross-sectional view illustrating an OLED in accordance with still another aspect of the present disclosure. As illustrated in FIG. 14, the OLED D5 includes a first electrode 610, a second electrode 630 facing the first electrode 610 and an emissive layer 620 disposed between the first and second electrodes 610 and 630.

The first electrode 610 can be an anode and the second electrode 630 can be a cathode. As an example, the first electrode 610 can be a reflective electrode and the second electrode 630 can be a transmissive (or semi-transmissive) electrode.

The emissive layer 620 includes an EML 640. The emissive layer 620 can include at least one of an HTL 660 disposed between the first electrode 610 and the EML 640 and an ETL 670 disposed between the EML 640 and the second electrode 630. Also, the emissive layer 620 can further include at least one of an HIL 650 disposed between the first electrode 610 and the HTL 660 and an EIL 680 disposed between the ETL 670 and the second electrode 630. In addition, the emissive layer 620 can further include at least one of an EBL 665 disposed between the HTL 660 and the EML 640 and an HBL 675 disposed between the EML 640 and the ETL 670.

In addition, the emissive layer 620 can further include an auxiliary hole transport layer (auxiliary HTL) 662 disposed between the HTL 660 and the EBL 665. The auxiliary HTL 662 can include a first auxiliary HTL 662a located in the first pixel region P1, a second auxiliary HTL 662b located in the second pixel region P2 and a third auxiliary HTL 662c located in the third pixel region P3.

The first auxiliary HTL 662a has a first thickness, the second auxiliary HTL 662b has a second thickness and the third auxiliary HTL 662c has a third thickness. The first thickness is less than the second thickness and the second thickness is less than the third thickness. Accordingly, the OLED D5 has a micro-cavity structure.

Owing to the first to third auxiliary HTLs 662a, 662b and 662c having different thickness to each other, the distance between the first electrode 610 and the second electrode 630 in the first pixel region P1 emitting light in the first wavelength range (blue light) is smaller than the distance between the first electrode 610 and the second electrode 630 in the second pixel region P2 emitting light in the second wavelength range (green light), which is longer than the first wavelength range. In addition, the distance between the first electrode 610 and the second electrode 630 in the second pixel region P2 is smaller than the distance between the first electrode 610 and the second electrode 630 in the third pixel region P3 emitting light in the third wavelength range (red light), which is longer than the second wavelength range. Accordingly, the luminous efficiency of the OLED D5 is improved.

In FIG. 14, the first auxiliary HTL 662a is located in the first pixel region P1. Alternatively, the OLED D5 can implement the micro-cavity structure without the first auxiliary HTL 662a. In addition, a capping layer can be disposed over the second electrode 630 in order to improve out-coupling of the light emitted from the OLED D5.

The EML 640 includes a first EML (EML1) 642 located in the first pixel region P1, a second EML (EML2) 644 located in the second pixel region P2 and a third EML (EML3) 646 located in the third pixel region P3. Each of the EML1 642, the EML2 644 and the EML3 646 can be a blue EML, a green EML and a red EML, respectively.

In one aspect, the EML1 642 located in the first pixel region P1 can include the first compound of the delayed fluorescent material having the structure of Formulae 1 to 6, the second compound FD of the fluorescent material having the structure of Formulae 7 to 9, and optionally the third compound H of the host. The EML1 642 can have a single-layered structure, a double-layered structure (FIG. 8) or a triple-layered structure (FIG. 10).

In the EML1 642, the contents of the third compound H can be larger than or equal to the contents of the first compound DF, and the contents of the first compound DF can be larger than the contents of the second compound FD. In this case, exciton energy can be transferred efficiently from the first compound DF to the second compound FD.

The EML2 644 located in the second pixel region P2 can include a host and a green dopant and the EML3 646 located in the third pixel region P3 can include a host and a red dopant. For example, the host in the EML2 644 and the EML3 646 can include the third compound H, and each of the green dopant and the red dopant can include independently at least one of green or red phosphorescent material, green or red fluorescent material and green or red delayed fluorescent material.

The OLED D5 emits blue light, green light and red light in each of the first to third pixel regions P1, P2 and P3 so that the organic light emitting display device 500 (FIG. 13) can implement a full-color image.

The organic light emitting display device 500 can further include a color filter layer corresponding to the first to third pixel regions P1, P2 and P3 for improving color purity of the light emitted from the OLED D. As an example, the color filter layer can comprise a first color filter layer (blue color filter layer) corresponding to the first pixel region P1, the second color filter layer (green color filter layer) corresponding to the second pixel region P2 and the third color filter layer (red color filter layer) corresponding to the third pixel region P3.

When the organic light emitting display device 500 is a bottom-emission type, the color filter layer can be disposed between the OLED D and the substrate 510. Alternatively, when the organic light emitting display device 500 is a top-emission type, the color filter layer can be disposed over the OLED D.

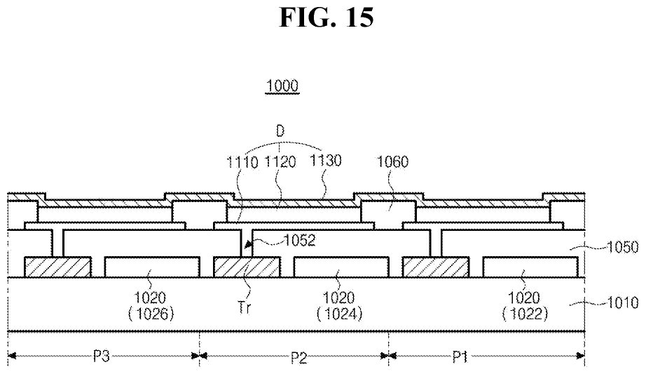

FIG. 15 is a schematic cross-sectional view illustrating an organic light emitting display device in accordance with still another aspect of the present disclosure. As illustrated in FIG. 15, the organic light emitting display device 1000 includes a substrate 1010 defining a first pixel region P1, a second pixel region P2 and a third pixel region P3, a thin film transistor Tr disposed over the substrate 1010, an OLED D disposed over the thin film transistor Tr and connected to the thin film transistor Tr and a color filter layer 1020 corresponding to the first to third pixel regions P1, P2 and P3. As an example, the first pixel region P1 can be a blue pixel region, the second pixel region P2 can be a green pixel region and the third pixel region P3 can be a red pixel region.

The substrate 1010 can be a glass substrate or a flexible substrate. For example, the flexible substrate can be any one of a PI substrate, a PES substrate, a PEN substrate, a PET substrate and a PC substrate. The thin film transistor Tr is located over the substrate 1010. Alternatively, a buffer layer can be disposed over the substrate 1010 and the thin film transistor Tr can be disposed over the buffer layer. As illustrated in FIG. 2, the thin film transistor Tr includes a semiconductor layer, a gate electrode, a source electrode and a drain electrode and acts as a driving element.

The color filter layer 1020 is located over the substrate 1010. As an example, the color filter layer 1020 can include a first color filter pattern 1022 corresponding to the first pixel region P1, a second color filter pattern 1024 corresponding to the second pixel region P2 and a third color filter pattern 1026 corresponding to the third pixel region P3. The first color filter pattern 1022 can be a blue color filter pattern, the second color filter pattern 1024 can be a green color filter pattern and the third color filter pattern 1026 can be a red color filter pattern. For example, the first color filter pattern 1022 can include at least one of blue dye or blue pigment, the second color filter pattern 1024 can include at least one of green dye or green pigment and the third color filter pattern 1026 can include at least one of red dye or red pigment.

A passivation layer 1050 is disposed over the thin film transistor Tr and the color filter layer 1020. The passivation layer 1050 has a flat top surface and includes a drain contact hole 1052 that exposes a drain electrode of the thin film transistor Tr.

The OLED D is disposed over the passivation layer 1050 and corresponds to the color filter layer 1020. The OLED D includes a first electrode 1110 that is connected to the drain electrode of the thin film transistor Tr, and an emissive layer 1120 and a second electrode 1130 each of which is disposed sequentially on the first electrode 1110. The OLED D emits white light in the first to third pixel regions P1, P2 and P3.

The first electrode 1110 is separately formed for each of the first to third pixel regions P1, P2 and P3, and the second electrode 1130 corresponds to the first to third pixel regions P1, P2 and P3 and is formed integrally. The first electrode 1110 can be one of an anode and a cathode, and the second electrode 1130 can be the other of the anode and the cathode. In addition, the first electrode 1110 can be a transmissive (or semi-transmissive) electrode and the second electrode 1130 can be a reflective electrode.

For example, the first electrode 1110 can be an anode and can include conductive material having a relatively high work function value, i.e., a transparent conductive oxide layer of transparent conductive oxide (TCO). The second electrode 1130 can be a cathode and can include conductive material having relatively low work function value, i.e., a metal material layer of low-resistant metal. For example, the transparent conductive oxide layer of the first electrode 1110 can include any one of ITO, IZO, ITZO, SnO, ZnO, ICO and AZO, and the second electrode 1130 can include Al, Mg, Ca, Ag, alloy thereof (e.g., Mg—Ag) or combination thereof.

The emissive layer 1120 is disposed on the first electrode 1110. The emissive layer 1120 includes at least two emitting parts emitting different colors. Each of the emitting part can have a single-layered structure of an EML. Alternatively, each of the emitting parts can include at least one of an HIL, an HTL, an EBL, an HBL, an ETL and an EIL. In addition, the emissive layer 1120 can further comprise a CGL disposed between the emitting parts.

At least one of the at least two emitting parts can include the first compound DF of the delayed fluorescent material having the structure of Formulae 1 to 6, the second compound FD of the boron-based fluorescent material having the structure of Formulae 7 to 9, and optionally the third compound H of the host.

A bank layer 1060 is disposed on passivation layer 1050 in order to cover edges of the first electrode 1110. The bank layer 1060 corresponds to each of the first to third pixel regions P1, P2 and P3 and exposes a center of the first electrode 1110. As described above, since the OLED D emits white light in the first to third pixel regions P1, P2 and P3, the emissive layer 1120 can be formed as a common layer without being separated in the first to third pixel regions P1, P2 and P3. The bank layer 1060 is formed to prevent current leakage from the edges of the first electrode 1110, and the bank layer 1060 can be omitted.

Moreover, the organic light emitting display device 1000 can further include an encapsulation film disposed on the second electrode 1130 in order to prevent outer moisture from penetrating into the OLED D. In addition, the organic light emitting display device 1000 can further comprise a polarizer disposed under the substrate 1010 in order to decrease external light reflection.

In the organic light emitting display device 1000 in FIG. 15, the first electrode 1110 is a transmissive electrode, the second electrode 1130 is a reflective electrode, and the color filter layer 1020 is disposed between the substrate 1010 and the OLED D. For example, the organic light emitting display device 1000 is a bottom-emission type. Alternatively, the first electrode 1110 can be a reflective electrode, the second electrode 1120 can be a transmissive electrode (or semi-transmissive electrode) and the color filter layer 1020 can be disposed over the OLED D in the organic light emitting display device 1000 with the top-emission type structure.

In the organic light emitting display device 1000, the OLED D located in the first to third pixel regions P1, P2 and P3 emits white light, and the white light passes through each of the first to third pixel regions P1, P2 and P3 so that each of a blue color, a green color and a red color is displayed in the first to third pixel regions P1, P2 and P3, respectively.

A color conversion film can be disposed between the OLED D and the color filter layer 1020. The color conversion film corresponds to the first to third pixel regions P1, P2 and P3, and includes a green color conversion film, a red color conversion film and a blue color conversion film each of which can convert the white light emitted from the OLED D into green light, red light and blue light, respectively. For example, the color conversion film can include quantum dots. Accordingly, the organic light emitting display device 1000 can further enhance its color purity. Alternatively, the color conversion film can displace the color filter layer 1020.

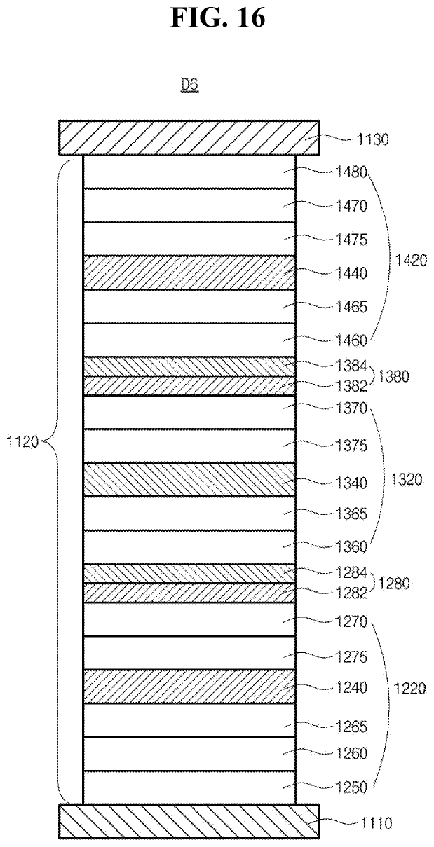

FIG. 16 is a schematic cross-sectional view illustrating an OLED in accordance with still another aspect of the present disclosure. As illustrated in FIG. 16, the OLED D6 includes first and second electrodes 1110 and 1130 facing each other and an emissive layer 1120 disposed between the first and second electrodes 1110 and 1130. The first electrode 1110 can be an anode and the second electrode 1130 can be a cathode. For example, the first electrode 1100 can be a transmissive electrode and the second electrode 1130 can be a reflective electrode.

The emissive layer 1120 includes a first emitting part 1220 including a first EML (lower EML, EML1) 1240, a second emitting part 1320 comprising a second EML (middle EML, EML2) 1340 and a third emitting part 1420 comprising a third EML (upper EML, EML3) 1440. In addition, the emissive layer 1120 can further includes a first charge generation layer (CGL1) 1280 disposed between the first emitting part 1220 and the second emitting part 1320 and a second charge generation layer (CGL2) 1380 disposed between the second emitting part 1320 and the third emitting part 1420. Accordingly, the first emitting part 1220, the CGL1 1280, the second emitting part 1320, the CGL2 1380 and the third emitting part 1420 are disposed sequentially over the first electrode 1110.

The first emitting part 1220 can further include at least one of an HIL 1250 disposed between the first electrode 1110 and the EML1 1240, a first HTL (HTL1) 1260 disposed between the EML1 1240 and the HIL 1250 and a first ETL (ETL1) 1270 disposed between the EML1 1240 and the CGL1 1280. Alternatively, the first emitting part 1220 can further include at least one of a first EBL (EBL1) 1265 disposed between the HTL1 1260 and the EML1 1240 and a first HBL (HBL1) 1275 disposed between the EML1 1240 and the ETL1 1270.

The second emitting part 1320 can further include at least one of a second HTL (HTL2) 1360 disposed between the CGL1 1280 and the EML2 1340 and a second ETL (ETL2) 1370 disposed between the EML2 1340 and the CGL2 1380. Alternatively, the second emitting part 1320 can further include a second EBL (EBL2) 1365 disposed between the HTL2 1360 and the EML2 1340 and/or a second HBL (HBL2) 1375 disposed between the EML2 1340 and the ETL2 1370.

The third emitting part 1420 can further include at least one of a third HTL (HTL3) 1460 disposed between the CGL2 1380 and the EML3 1440, a third ETL (ETL3) 1470 disposed between the EML3 1440 and the second electrode 1130 and an EIL 1480 disposed between the ETL3 1470 and the second electrode 1130. Alternatively, the third emitting part 1420 can further comprise a third EBL (EBL3) 1465 disposed between the HTL3 1460 and the EML3 1440 and/or a third HBL (HBL3) 1475 disposed between the EML3 1440 and the ETL3 1470.

The CGL1 1280 is disposed between the first emitting part 1220 and the second emitting part 1320. For example, the first emitting part 1220 and the second emitting part 1320 are connected via the CGL1 1280. The CGL1 1280 can be a PN-junction CGL that junctions a first N-type CGL (N-CGL1) 1282 with a first P-type CGL (P-CGL1) 1284.

The N-CGL1 1282 is disposed between the ETL1 1270 and the HTL2 1360 and the P-CGL1 1284 is disposed between the N-CGL1 1282 and the HTL2 1360. The N-CGL1 1282 transports electrons to the EML1 1240 of the first emitting part 1220 and the P-CGL1 1284 transport holes to the EML2 1340 of the second emitting part 1320.

The CGL2 1380 is disposed between the second emitting part 1320 and the third emitting part 1420. For example, the second emitting part 1320 and the third emitting part 1420 are connected via the CGL2 1380. The CGL2 1380 can be a PN-junction CGL that junctions a second N-type CGL (N-CGL2) 1382 with a second P-type CGL (P-CGL2) 1384.

The N-CGL2 1382 is disposed between the ETL2 1370 and the HTL3 1460 and the P-CGL2 1384 is disposed between the N-CGL2 1382 and the HTL3 1460. The N-CGL2 1382 transports electrons to the EML2 1340 of the second emitting part 1320 and the P-CGL2 1384 transport holes to the EML3 1440 of the third emitting part 1420.

In this aspect, one of the first to third EMLs 1240, 1340 and 1440 can be a blue EML, another of the first to third EMLs 1240, 1340 and 1440 can be a green EML and the third of the first to third EMLs 1240, 1340 and 1440 can be a red EML.

As an example, the EML1 1240 can be a blue EML, the EML2 1340 can be a green EML and the EML3 1440 can be a red EML. Alternatively, the EML1 1240 can be a red EML, the EML2 1340 can be a green EML and the EML3 1440 can be a blue EML. Hereinafter, the OLED D6 where the EML1 1240 is a blue EML, the EML2 1340 is a green EML and the EML3 1440 is a red EML will be described in more detail.

The EML1 1240 can include the first compound DF of the delayed fluorescent material having the structure of Formulae 1 to 6, the second compound FD of the fluorescent material having the structure of Formulae 7 to 9, and optionally, the third compound H of the host. The EML1 1240 including the first to third compounds DF, FD and H can have a single-layered structure, a double-layered structure (FIG. 8) or a triple-layered structure (FIG. 10).

In the EML1 1240, the contents of the third compound H can be equal to or larger than the contents of the first compound DF and the contents of the first compound DF can be larger than the contents of the second compound FD. When the contents of the first compound DF is larger than the contents of the second compound FD, exciton energy from the first compound DF to the second compound FD can be transferred sufficiently.

The EML2 1340 can include a host and a green dopant and the EML3 1440 can include a host a red dopant. As an example, the host can include the third compound H, and each of the green and red dopants can include at least one of green and red phosphorescent material, green and red fluorescent material and green and red delayed fluorescent material, respectively, in each of the EML2 1340 and the EML3 1440.

The OLED D6 emits white light in each of the first to third pixel regions P1, P2 and P3 and the white light passes though the color filter layer 1020 (FIG. 15) correspondingly disposed in the first to third pixel regions P1, P2 and P3. Accordingly, the organic light emitting display device 1000 (FIG. 15) can implement a full-color image.

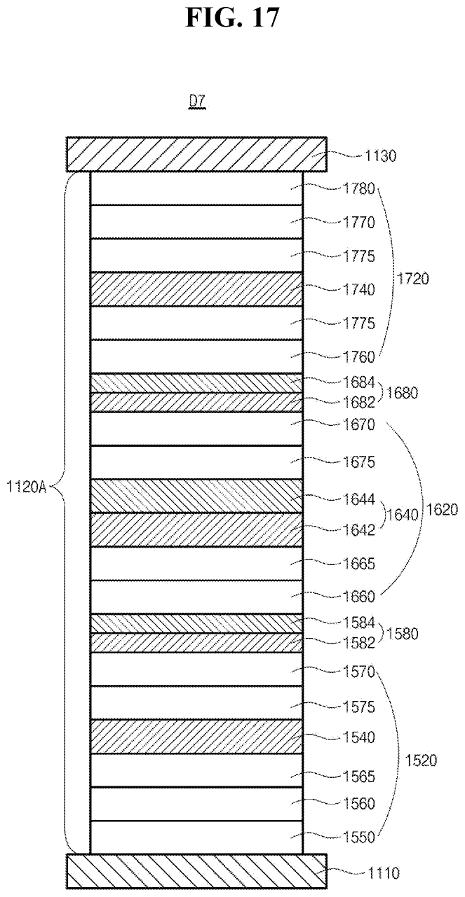

FIG. 17 is a schematic cross-sectional view illustrating an OLED in accordance with still another aspect of the present disclosure. As illustrated in FIG. 17, the OLED D7 includes first and second electrodes 1110 and 1130 facing each other and an emissive layer 1120A disposed between the first and second electrodes 1110 and 1130. The first electrode 1110 can be an anode and the second electrode 1130 can be a cathode. For example, the first electrode 1100 can be a transmissive electrode and the second electrode 1130 can be a reflective electrode.

The emissive layer 1120A includes a first emitting part 1520 comprising an EML1 (lower EML) 1540, a second emitting part 1620 comprising an EML2 (middle EML) 1640 and a third emitting part 1720 comprising an EML3 (upper EML) 1740. In addition, the emissive layer 1120A can further include a CGL1 1580 disposed between the first emitting part 1520 and the second emitting part 1620 and a CGL2 1680 disposed between the second emitting part 1620 and the third emitting part 1720. Accordingly, the first emitting part 1520, the CGL1 1580, the second emitting part 1620, the CGL2 1680 and the third emitting part 1720 are disposed sequentially on the first electrode 1110.

The first emitting part 1520 can further include at least one of an HIL 1550 disposed between the first electrode 1110 and the EML1 1540, an HTL1 1560 disposed between the EML1 1540 and the HIL 1550 and an ETL1 1570 disposed between the EML1 1540 and the CGL1 1580. Alternatively, the first emitting part 1520 can further comprise an EBL1 1565 disposed between the HTL1 1560 and the EML1 1540 and/or an HBL1 1575 disposed between the EML1 1540 and the ETL1 1570.

The EML2 1640 of the second emitting part 1620 includes a middle lower EML (first layer) 1642 and a middle upper EML (second layer) 1644. The middle lower EML 1642 is located adjacently to the first electrode 1110 and the upper middle EML 1644 is located adjacently to the second electrode 1130. In addition, the second emitting part 1620 can further include at least one of an HTL2 1660 disposed between the CGL1 1580 and the EML2 1640, an ETL2 1670 disposed between the EML2 1640 and the CGL2 1680. Alternatively, the second emitting part 1620 can further comprise at least one of an EBL2 1665 disposed between the HTL2 1660 and the EML2 1640 and an HBL2 1675 disposed between the EML2 1640 and the ETL2 1670.

The third emitting part 1720 can further include at least one of an HTL3 1760 disposed between the CGL2 1680 and the EML3 1740, an ETL3 1770 disposed between the EML3 1740 and the second electrode 1130 and an EIL 1780 disposed between the ETL3 1770 and the second electrode 1130. Alternatively, the third emitting part 1720 can further include an EBL3 1765 disposed between the HTL3 1760 and the EML3 1740 and/or an HBL3 1775 disposed between the EML3 1740 and the ETL3 1770.

The CGL1 1580 is disposed between the first emitting part 1520 and the second emitting part 1620. For example, the first emitting part 1520 and the second emitting part 1620 are connected via the CGL1 1580. The CGL1 1580 can be a PN-junction CGL that junctions an N-CGL1 1582 with a P-CGL1 1584. The N-CGL1 1582 is disposed between the ETL1 1570 and the HTL2 1660 and the P-CGL1 1584 is disposed between the N-CGL1 1582 and the HTL2 1560.

The CGL2 1680 is disposed between the second emitting part 1620 and the third emitting part 1720. For example, the second emitting part 1620 and the third emitting part 1720 are connected via the CGL2 1680. The CGL2 1680 can be a PN-junction CGL that junctions an N-CGL2 1682 with a P-CGL2 1684. The N-CGL2 1682 is disposed between the ETL2 1570 and the HTL3 1760 and the P-CGL2 1684 is disposed between the N-CGL2 1682 and the HTL3 1760.

In this aspect, each of the EML1 1540 and the EML3 1740 can be a blue EML. In an aspect, each of the EML1 1540 and the EML3 1740 can include the first compound DF of the delayed fluorescent material having the structure of Formulae 1 to 6, the second compound FD of the fluorescent material having the structure of Formulae 7 to 9, and optionally, the third compound H.

In one aspect, the EML3 1740 can include the first and second compounds DF and FD, and optionally the third compound H as the same as the EML1 1540. Alternatively, the EML3 1740 can include another compound that is different from at least one of the first compound DF and the second compound FD in the EML1 1540, and thus the EML3 1740 can emit light different from the light emitted from the EML1 1540 or can have different luminous efficiency different from the luminous efficiency of the EML1 1540.

As an example, each of the EML1 1540 and the EML3 1740 includes the first to third compounds DF, FD and H, the contents of the third compound H can be equal to or larger than the contents of the first compound DF and the contents of the first compound DF can be larger than the contents of the second compound FD in each of the EML1 1540 and the EML3 1740. In this case, energy from the first compound DF to the second compound FD can be transferred sufficiently.

One of the middle lower EML 1642 and the middle upper EML 1644 of the EML2 1640 can be a green EML and the other of the middle lower EML 1642 and the middle upper EML 1644 of the EML2 1640 can be a red EML. The green EML and the red EML are sequentially disposed to form the EML2 1640.

As an example, the middle lower EML 1642 of the green EML can include the host and the green dopant and the middle upper EML 1644 can include the host and the red dopant. As an example, the host in the middle lower EML 1642 and the middle upper EML 1644 can include the third compound H, and each of the green and red dopants can include at least one of the green and red phosphorescent material, the green and red fluorescent material and the green and red delayed fluorescent material, respectively.

The OLED D7 emits white light in each of the first to third pixel regions P1, P2 and P3 and the white light passes though the color filter layer 1020 (FIG. 15) correspondingly disposed in the first to third pixel regions P1, P2 and P3. Accordingly, the organic light emitting display device 1000 (FIG. 16) can implement a full-color image.

In FIG. 17, the OLED D7 has a three-stack structure including the first to three emitting parts 1520, 1620 and 1720 which includes the EML1 1540 and the EML3 1740 as a blue EML. Alternatively, the OLED D7 can have a two-stack structure where one of the first emitting part 1520 and the third emitting part 1720 each of which includes the EML1 1540 and the EML3 1740 as a blue EML is omitted.

### Example 1 (Ex. 1): Fabrication of OLED

An OLED in which an EML includes 2,8-di(9H-carbazol yl)dibenzo[b,d]thiophene (DCzDBT) as a host and the Compound 1-1 of Formula 6 (HOMO: −5.58 eV, LUMO: −2.6 eV, maximum photoluminescence wavelength (PL λmax): 472 nm, onset wavelength: 433 nm) as the first compound DF was fabricated. The ITO substrate was washed by UV-Ozone treatment before using, and was transferred to a vacuum chamber for depositing emission layer. Subsequently, an anode, an emission layer and a cathode were deposited by evaporation from a heating boat under 10⁻⁷ torr vacuum condition with setting deposition rate of 1 Å/s in the following order:

An anode (ITO, 50 nm); an HIL (HAT-CN, 7 nm); an HTL (NPB, 45 nm); an EBL (TAPC, 10 nm), an EML (DCzDBT (70 wt %), Compound 1-1 (30 wt %), 30 nm); an HBL (B3PYMPM, 10 nm); an ETL (TPBi, 25 nm), an EIL (LiF); and a cathode (Al).

After the emissive layer and the cathode were deposited, the OLED was transferred from the deposition chamber to a dry box in order to form a film, and then the OLED was encapsulated with UV-cured epoxy and water getter. The materials applied in the emissive layer are indicated below:

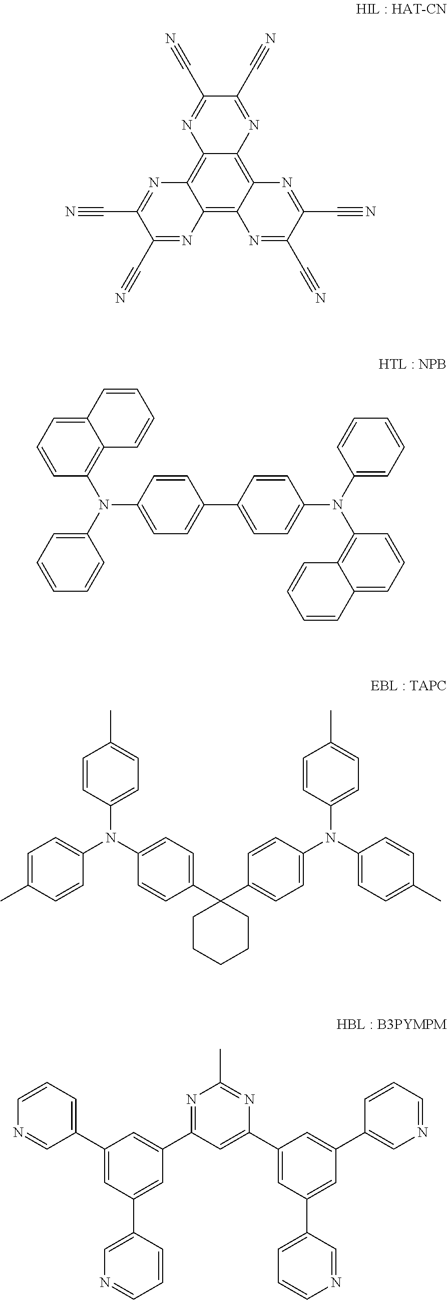

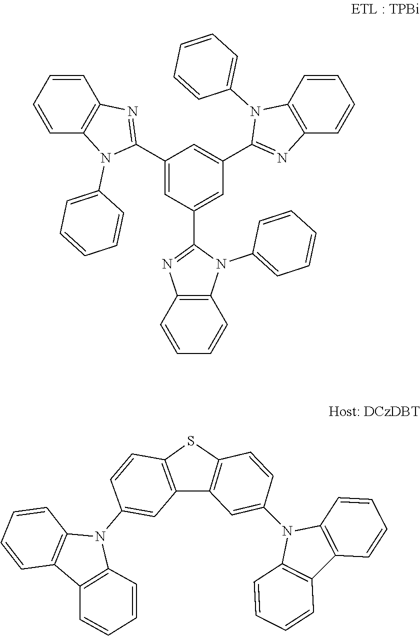 [SMILES: c1ccc(-n2c(-c3cc(-c4nc5ccccc5n4-c4ccccc4)cc(-c4nc5ccccc5n4-c4ccccc4)c3)nc3ccccc32)cc1 ; c1ccc2c(c1)c1ccccc1n2-c1ccc2sc3ccc(-n4c5ccccc5c5ccccc54)cc3c2c1]

### Example 2 (Ex. 2): Fabrication of OLED

An OLED was fabricated using the same materials as Example 1, except that DczDBT (69 wt %) as the host, the Compound 1-1 (30 wt %) as the first compound and Compound 2-20 (HOMO: −5.4 eV, LUMO: −2.8 eV, maximum absorbance wavelength: 457 nm, 1 wt %) of Formula 9 as the second compound FD were applied in the EML.

### Example 3 (Ex. 3): Fabrication of OLED

An OLED was fabricated using the same materials as Example 2, except that Compound 2-21 (HOMO: −5.5 eV, LUMO: −2.8 eV, maximum absorbance wavelength (Abs λmax): 459 nm) of Formula 9 as the second compound FD in the EML was used instead of the Compound 2-20.

### Example 4 (Ex. 4): Fabrication of OLED

An OLED was fabricated using the same materials as Example 2, except that Compound 2-36 (HOMO: −5.4 eV, LUMO: −2.8 eV, Abs λmax: 457 nm) of Formula 9 as the second compound FD in the EML was used instead of the Compound 2-20.

### Example 5 (Ex. 5): Fabrication of OLED

An OLED was fabricated using the same materials as Example 1, except that Compound 1-5 (HOMO: −5.58 eV, LUMO: −2.6 eV, PL λmax: 470 nm, onset wavelength: 435 nm) of Formula 6 as the first compound DF in the EML was used instead of the Compound 1-1.

### Example 6 (Ex. 6): Fabrication of OLED

An OLED was fabricated using the same materials as Example 5, except DczDBT (69 wt %) as the host, the Compound 1-5 (30 wt %) as the first compound and Compound 2-20 (1 wt %) of Formula 9 (as the second compound FD were applied in the EML.

### Example 7 (Ex. 7): Fabrication of OLED

An OLED was fabricated using the same materials as Example 6, except that Compound 2-21 of Formula 9 as the second compound FD in the EML was used instead of the Compound 2-20.

### Example 8 (Ex. 8): Fabrication of OLED

An OLED was fabricated using the same materials as Example 6, except that Compound 2-36 of Formula 9 as the second compound FD in the EML was used instead of the Compound 2-20.

### Example 9 (Ex. 9): Fabrication of OLED

An OLED was fabricated using the same materials as Example 1, except that Compound 1-7 (HOMO: −5.6 eV, LUMO: −2.7 eV, PL λmax: 472 nm, onset wavelength: 434 nm) of Formula 6 as the first compound DF in the EML was used instead of the Compound 1-1.

### Example 10 (Ex. 10): Fabrication of OLED

An OLED was fabricated using the same materials as Example 9, except DczDBT (69 wt %) as the host, the Compound 1-7 (30 wt %) as the first compound and Compound 2-20 (1 wt %) of Formula 9 as the second compound FD were applied in the EML.

### Example 11 (Ex. 11): Fabrication of OLED

An OLED was fabricated using the same materials as Example 10, except that Compound 2-21 of Formula 9 as the second compound FD in the EML was used instead of the Compound 2-20.

### Example 12 (Ex. 12): Fabrication of OLED

An OLED was fabricated using the same materials as Example 10, except that Compound 2-36 of Formula 9 as the second compound FD in the EML was used instead of the Compound 2-20.

### Example 13 (Ex. 13): Fabrication of OLED

An OLED was fabricated using the same materials as Example 1, except that Compound 1-16 (HOMO: −5.6 eV, LUMO: −2.6 eV, PL λmax: 473 nm, onset wavelength: 434 nm) of Formula 6 as the first compound DF in the EML was used instead of the Compound 1-1.

### Example 14 (Ex. 14): Fabrication of OLED

An OLED was fabricated using the same materials as Example 13, except DczDBT (69 wt %) as the host, the Compound 1-16 (30 wt %) as the first compound and Compound 2-20 (1 wt %) of Formula 9 as the second compound FD were applied in the EML.

### Example 15 (Ex. 15): Fabrication of OLED

An OLED was fabricated using the same materials as Example 14, except that Compound 2-21 of Formula 9 as the second compound FD in the EML was used instead of the Compound 2-20.

### Example 16 (Ex. 16): Fabrication of OLED

An OLED was fabricated using the same materials as Example 14, except that Compound 2-36 of Formula 9 as the second compound FD in the EML was used instead of the Compound 2-20.

### Comparative Example 1 (Com. 1): Fabrication of OLED

An OLED was fabricated using the same materials as Example 1, except that the following Ref. 1 Compound (HOMO: −5.5 eV, LUMO: −2.7 eV, PL λmax: 487 nm, onset wavelength: 449 nm) as the first compound DF in the EML was used instead of the Compound 1-1.

### Comparative Example 2 (Com. 2): Fabrication of OLED

An OLED was fabricated using the same materials as Comparative Example 1, except DczDBT (69 wt %) as the host, the Ref 1 Compound (30 wt %) as the first compound and Compound 2-20 (1 wt %) of Formula 9 as the second compound FD were applied in the EML.

### Comparative Example 3 (Com. 3): Fabrication of OLED

An OLED was fabricated using the same materials as Example 1, except that the following Ref. 2 Compound (HOMO: −5.6 eV, LUMO: −2.6 eV, PL λmax: 460 nm, onset wavelength: 421 nm) as the first compound DF in the EML was used instead of the Compound 1-1.

### Comparative Example 4 (Com. 4): Fabrication of OLED

An OLED was fabricated using the same materials as Comparative Example 3, except DczDBT (69 wt %) as the host, the Ref 2 Compound (30 wt %) as the first compound and Compound 2-20 (1 wt %) of Formula 9 as the second compound FD were applied in the EML.

### Comparative Example 5 (Com. 5): Fabrication of OLED

An OLED was fabricated using the same materials as Example 1, except that the following Ref. 3 Compound (HOMO: −5.6 eV, LUMO: −2.7 eV, PL λmax: 462 nm, onset wavelength: 426 nm) as the first compound DF in the EML was used instead of the Compound 1-1.

### Comparative Example 6 (Com. 6): Fabrication of OLED

An OLED was fabricated using the same materials as Comparative Example 6, except DczDBT (69 wt %) as the host, the Ref 3 Compound (30 wt %) as the first compound and Compound 2-20 (1 wt %) of Formula 9 as the second compound FD were applied in the EML.

### Comparative Example 7 (Com. 7): Fabrication of OLED

An OLED was fabricated using the same materials as Example 1, except that the following Ref. 4 Compound (HOMO: −5.7 eV, LUMO: −2.7 eV, PL λmax: 458 nm, onset wavelength: 422 nm) as the first compound DF in the EML was used instead of the Compound 1-1.

### Comparative Example 8 (Com. 8): Fabrication of OLED

An OLED was fabricated using the same materials as Comparative Example 6, except DczDBT (69 wt %) as the host, the Ref 3 Compound (30 wt %) as the first compound and Compound 2-20 (1 wt %) of Formula 9 as the second compound FD were applied in the EML.

[Reference Compounds]

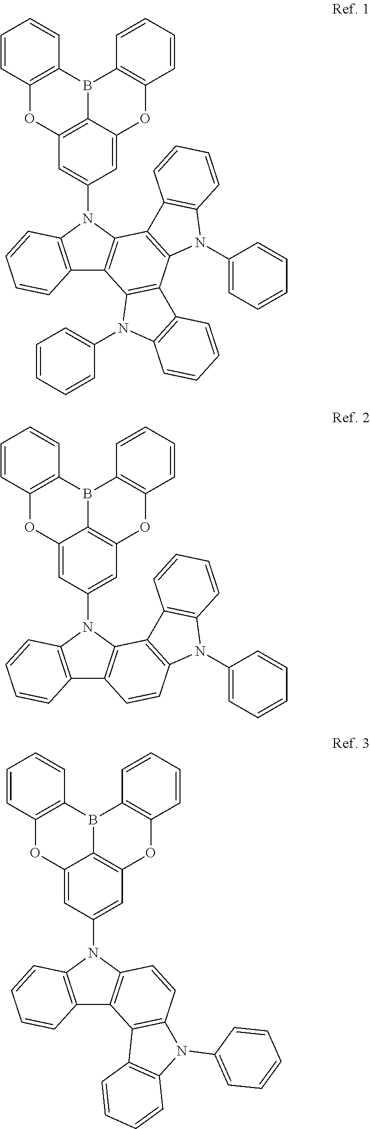 [SMILES: c1ccc(-n2c3ccccc3c3c2c2c4ccccc4n(-c4cc5c6c(c4)Oc4ccccc4B6c4ccccc4O5)c2c2c4ccccc4n(-c4ccccc4)c32)cc1 ; c1ccc(-n2c3ccccc3c3c2ccc2c4ccccc4n(-c4cc5c6c(c4)Oc4ccccc4B6c4ccccc4O5)c23)cc1 ; c1ccc(-n2c3ccccc3c3c4c5ccccc5n(-c5cc6c7c(c5)Oc5ccccc5B7c5ccccc5O6)c4ccc32)cc1]

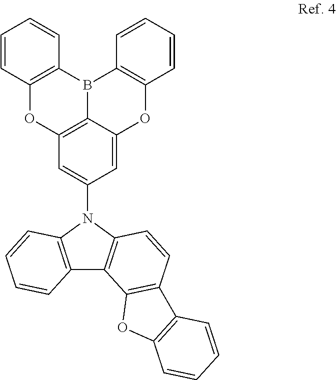 [SMILES: c1ccc2c(c1)Oc1cc(-n3c4ccccc4c4c5oc6ccccc6c5ccc43)cc3c1B2c1ccccc1O3]

### Experimental Example 1: Measurement of Luminous Properties of OLED

Each of the OLED fabricated in Ex. 1-16 and Ref 1-8 was connected to an external power source and then luminous properties for all the diodes were evaluated using a constant current source (KEITHLEY) and a photometer PR650 at room temperature. In particular, driving voltage (V), current efficiency (cd/A), external quantum efficiency (EQE, %) and maximum electroluminescence (EL λmax, nm) at 8.6 mA/cm² current density the OLEDs were measured. The measurement results for the OLEDs are shown in the following tables 1 and 2.

TABLE 1
Luminous Properties of OLED

| Sample | | DF | FD | V | cd/A | EQE | CIEy | EL λmax | λonsetDF |
|---|---|---|---|---|---|---|---|---|---|
| Ex. | 1 | 1-1 | — | 3.49 | 33.1 | 18.2 | 0.271 | 478 | 433 |
| Ex. | 2 | 1-1 | 2-23 | 3.6 | 28.2 | 24.1 | 0.159 | 470 | 433 |
| Ex. | 3 | 1-1 | 2-24 | 3.52 | 30.5 | 24.6 | 0.183 | 474 | 433 |
| Ex. | 4 | 1-1 | 2-39 | 3.94 | 34.2 | 24.7 | 0.197 | 470 | 433 |
| Ex. | 5 | 1-5 | — | 3.36 | 28.2 | 14.6 | 0.295 | 480 | 435 |
| Ex. | 6 | 1-5 | 2-23 | 3.63 | 26.6 | 23.8 | 0.153 | 472 | 435 |
| Ex. | 7 | 1-5 | 2-24 | 3.48 | 27.7 | 21.5 | 0.179 | 470 | 435 |
| Ex. | 8 | 1-5 | 2-39 | 3.2 | 27.5 | 20.6 | 0.192 | 472 | 435 |
| Ex. | 9 | 1-7 | — | 3.32 | 26.7 | 15.1 | 0.264 | 478 | 434 |
| Ex. | 10 | 1-7 | 2-23 | 3.6 | 24.5 | 22.7 | 0.146 | 470 | 434 |
| Ex. | 11 | 1-7 | 2-24 | 3.4 | 22.4 | 19 | 0.193 | 472 | 434 |
| Ex. | 12 | 1-7 | 2-39 | 3.8 | 35.8 | 22.6 | 0.232 | 472 | 434 |
| Ex. | 13 | 1-16 | — | 3.4 | 26.9 | 14.3 | 0.285 | 478 | 434 |
| Ex. | 14 | 1-16 | 2-23 | 3.62 | 25.3 | 24.2 | 0.145 | 472 | 434 |
| Ex. | 15 | 1-16 | 2-24 | 3.38 | 34.4 | 21.6 | 0.237 | 472 | 434 |
| Ex. | 16 | 1-16 | 2-39 | 3.8 | 35.9 | 20.8 | 0.26 | 472 | 434 |

DF: First Compound; FD: Second Compound; λonsetDF: Onset wavelength of First Compound

TABLE 2
Luminous Properties of OLED

| Sample | DF | FD | v | cd/A | EQE | CIEy | EL λmax | λonsetDF |
|---|---|---|---|---|---|---|---|---|
| Com. 1 | Ref. 1 | — | 3.46 | 43 | 20.1 | 0.354 | 490 | 449 |
| Com. 2 | Ref. 1 | 2-23 | 3.58 | 29.4 | 21.2 | 0.201 | 472 | 449 |
| Com. 3 | Ref. 2 | — | 3.56 | 13.2 | 7.5 | 0.251 | 474 | 421 |
| Com. 4 | Ref. 2 | 2-23 | 3.6 | 21.9 | 14.5 | 0.229 | 474 | 421 |
| Com. 5 | Ref. 3 | — | 3.25 | 15.5 | 9 | 0.248 | 474 | 426 |
| Com. 6 | Ref. 3 | 2-23 | 3.31 | 18.9 | 16.2 | 0.168 | 474 | 426 |
| Com. 7 | Ref. 4 | — | 3.94 | 14.6 | 8.9 | 0.226 | 470 | 422 |
| Com. 8 | Ref. 4 | 2-23 | 4.18 | 11.3 | 10.9 | 0.165 | 472 | 422 |

DF: First Compound; FD: Second Compound; λonsetDF: Onset wavelength of First Compound

As indicated in Tables 1 and 2, compared to the OLEDs fabricated in Ex. 1, 5, 9 and 13 in which the first compound as the sole dopant was applied into the EML, the OLEDs fabricated in Ex. 2-4, 6-8, 10-12 and 14-16 in which the first compound having plural electron donor moieties and onset wavelength between 430 nm and 440 nm and the second compound were applied into the EML exhibited luminous efficiency with great improvement and emitted deep blue light. On the other hand, compared to the OLEDs fabricated in Com. Com. 1, 3, 5 and 7 in which the first compound as the sole dopant was applied into the EML, the OLEDs fabricated in Com. 2, 4, 6 and 8 in which the first compound having only one electron donor moiety and onset wavelength less than 430 nm or more than 440 nm and the second compound were applied into the EML showed luminous efficiency with a little improvement or with greatly reduced.

More particularly, compared to the OLEDs fabricated in Com. 2, 4, 6 and 8 in which the first compound having only one electron donor moiety and the second compound were applied into the EML, the OLEDs fabricated in Ex. 2-4, 6-8, 10-12 and 14-16 in which the first compound having plural electron donor moieties and the second compound were applied into the EML reduced their driving voltages by maximally 23.4%, and improved their current efficiency and power efficiency by maximally 217.7% and 174.4%, respectively.

It will be apparent to those skilled in the art that various modifications and variations can be made in the OLED and the organic light emitting device including the OLED of the present disclosure without departing from the technical idea or scope of the disclosure. Thus, it is intended that the present disclosure cover the modifications and variations of this disclosure provided they come within the scope of the appended claims and their equivalents.

What is claimed is:

1. An organic light emitting diode comprising:
a first electrode;
a second electrode facing the first electrode; and
an emissive layer disposed between the first and second electrodes and comprising at least one emitting material layer,
wherein the at least one emitting material layer comprises a first compound and a second compound in a single-layered emitting material layer, or comprises a first emitting material layer comprising the first compound and a second emitting material layer comprising the second compound, and
wherein the first compound has the following structure of Formula 1 and the second compound has the following structure of Formula 7: 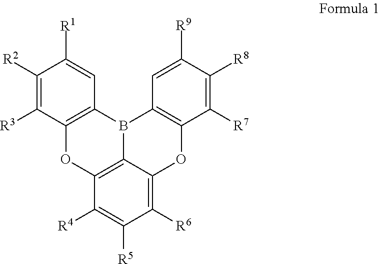
wherein, in Formula 1,
each of R¹ to R⁹ is independently hydrogen, deuterium, tritium, halogen, unsubstituted or substituted C₁-C₂₀ alkyl, unsubstituted or substituted C₁-C₂₀ alkyl amino, an unsubstituted or substituted C₆-C₃₀ aromatic group or an unsubstituted or substituted C₃-C₃₀ hetero aromatic group, wherein two to four of R¹ to R⁹ are a moiety having the following structure of Formula 2, 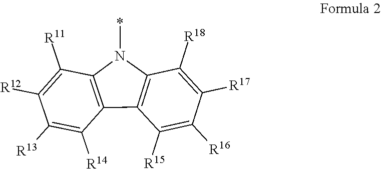
wherein, in Formula 2,
each of R¹¹ to R¹⁸ is independently hydrogen, deuterium, tritium, halogen, unsubstituted or substituted C₁-C₂₀ alkyl, unsubstituted or substituted C₁-C₂₀ alkyl silyl, unsubstituted or substituted C₁-C₂₀ alkyl amino, an unsubstituted or substituted C₆-C₃₀ aromatic group or an unsubstituted or substituted C₃-C₃₀ hetero aromatic group, or
adjacent two of R¹¹ to R¹⁸ form an unsubstituted or substituted hetero aromatic ring having the following structure of Formula 3,
wherein at least adjacent two of R¹¹ to R¹⁸ form an unsubstituted or substituted hetero aromatic ring having the following structure of Formula 3; and
asterisk indicates a linking position, 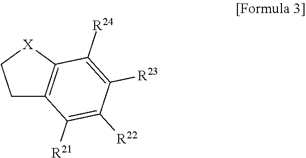
wherein, in Formula 3,
X is NR²⁵, O or S;
each of R²¹ to R²⁵ is independently hydrogen, deuterium, tritium, halogen, unsubstituted or substituted C₁-C₂₀ alkyl, unsubstituted or substituted C₁-C₂₀ alkyl silyl, unsubstituted or substituted C₁-C₂₀ alkyl amino, an unsubstituted or substituted C₆-C₃₀ aromatic group or an unsubstituted or substituted C₃-C₃₀ hetero aromatic group; and
a dotted line indicates a fused portion, 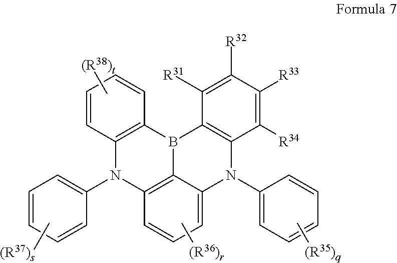
wherein, in Formula 7,
each of R³¹ to R³⁴ is independently hydrogen, deuterium, tritium, halogen, unsubstituted or substituted C₁-C₂₀ alkyl, unsubstituted or substituted C₁-C₂₀ alkyl silyl, unsubstituted or substituted C₁-C₂₀ alkyl amino, an unsubstituted or substituted C₆-C₃₀ aromatic group or an unsubstituted or substituted C₃-C₃₀ hetero aromatic group,
optionally,
two adjacent elements of R³¹ to R³⁴ form an unsubstituted or substituted fused ring having boron and nitrogen;
each of R³⁵ to R³⁸ is independently deuterium, tritium, halogen, unsubstituted or substituted C₁-C₂₀ alkyl, unsubstituted or substituted C₁-C₂₀ alkyl silyl, unsubstituted or substituted C₁-C₂₀ alkyl amino, an unsubstituted or substituted C₆-C₃₀ aromatic group or an unsubstituted or substituted C₃-C₃₀ hetero aromatic group, wherein each R³⁵ is identical to or different from each other when q is an integer of two or more, each R36 is identical to or different from each other when r is an integer of two or more, each R37 is identical to or different from each other when s is an integer of two or more and each R38 is identical to or different from each other when t is an integer of two or more;
each of q and s is independently an integer of 0 to 5;
r is an integer of 0 to 3; and
t is an integer of 0 to 4.

2. The organic light emitting diode of claim 1, wherein the first compound comprises an organic compound having the following structure of Formula 4: 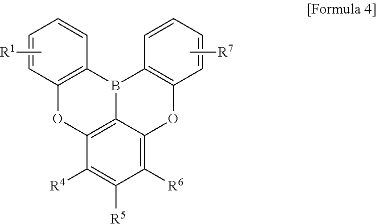
wherein, in Formula 4,
each of R¹, R⁴, R⁵, R⁶ and R⁷ is independently hydrogen, deuterium, protium, halogen, unsubstituted or substituted C₁-C₂₀ alkyl, unsubstituted or substituted C₁-C₂₀ alkyl amino, unsubstituted or substituted C₆-C₃₀ aryl or unsubstituted or substituted C₃-C₃₀ hetero aryl, wherein two of R¹, R⁴, R⁵, R⁶ and R⁷ have the structure of Formula 2.

3. The organic light emitting diode of claim 1, wherein the moiety having the structure of Formula 2 is selected from the following moieties:

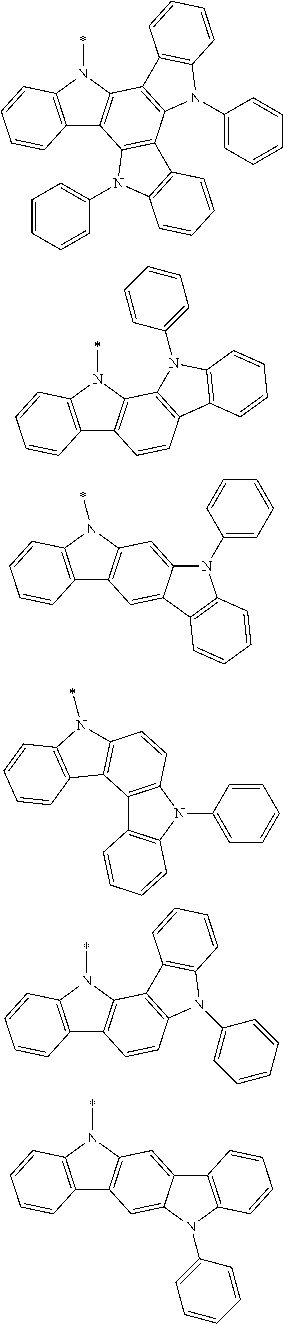

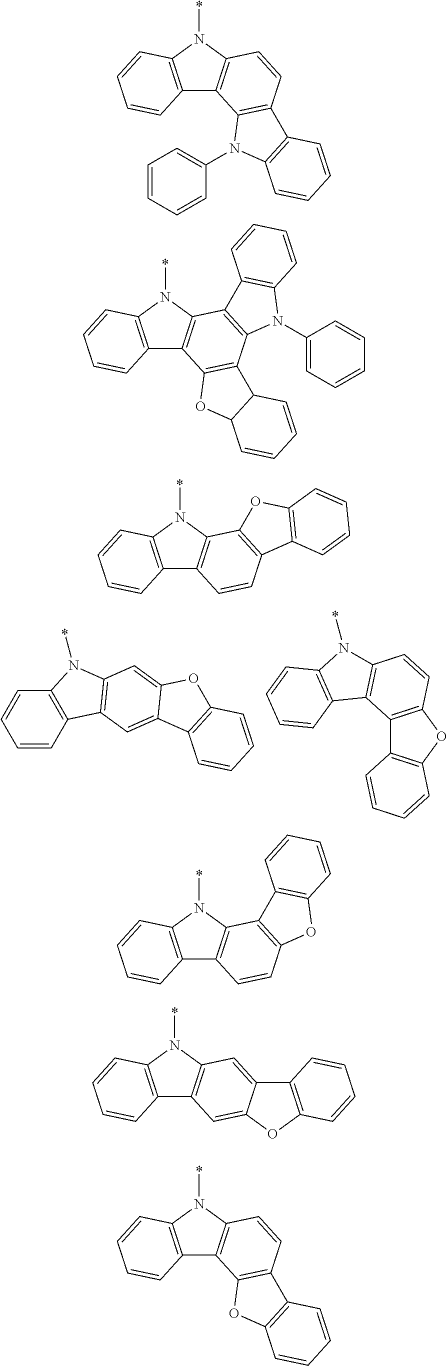

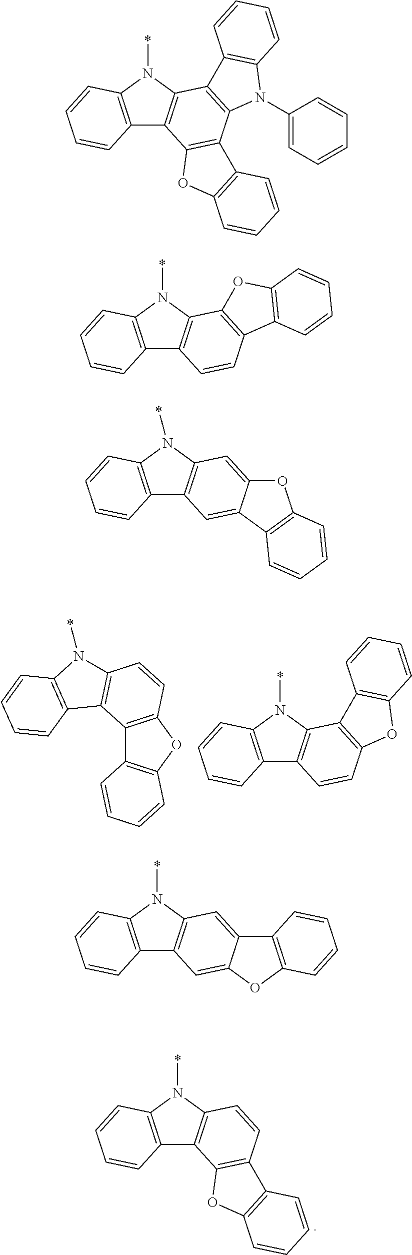

4. The organic light emitting diode of claim 1, wherein the first compound is selected from:

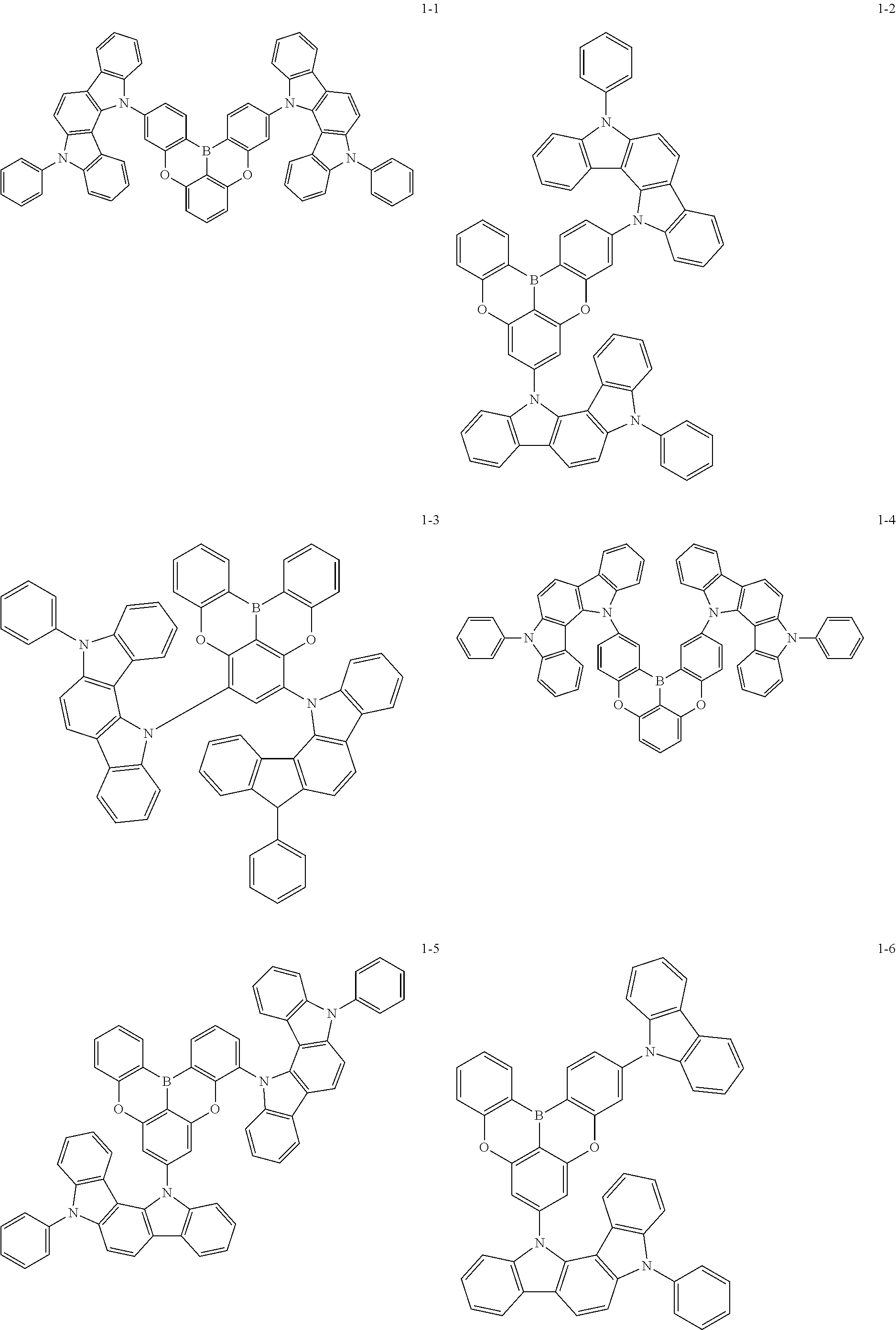

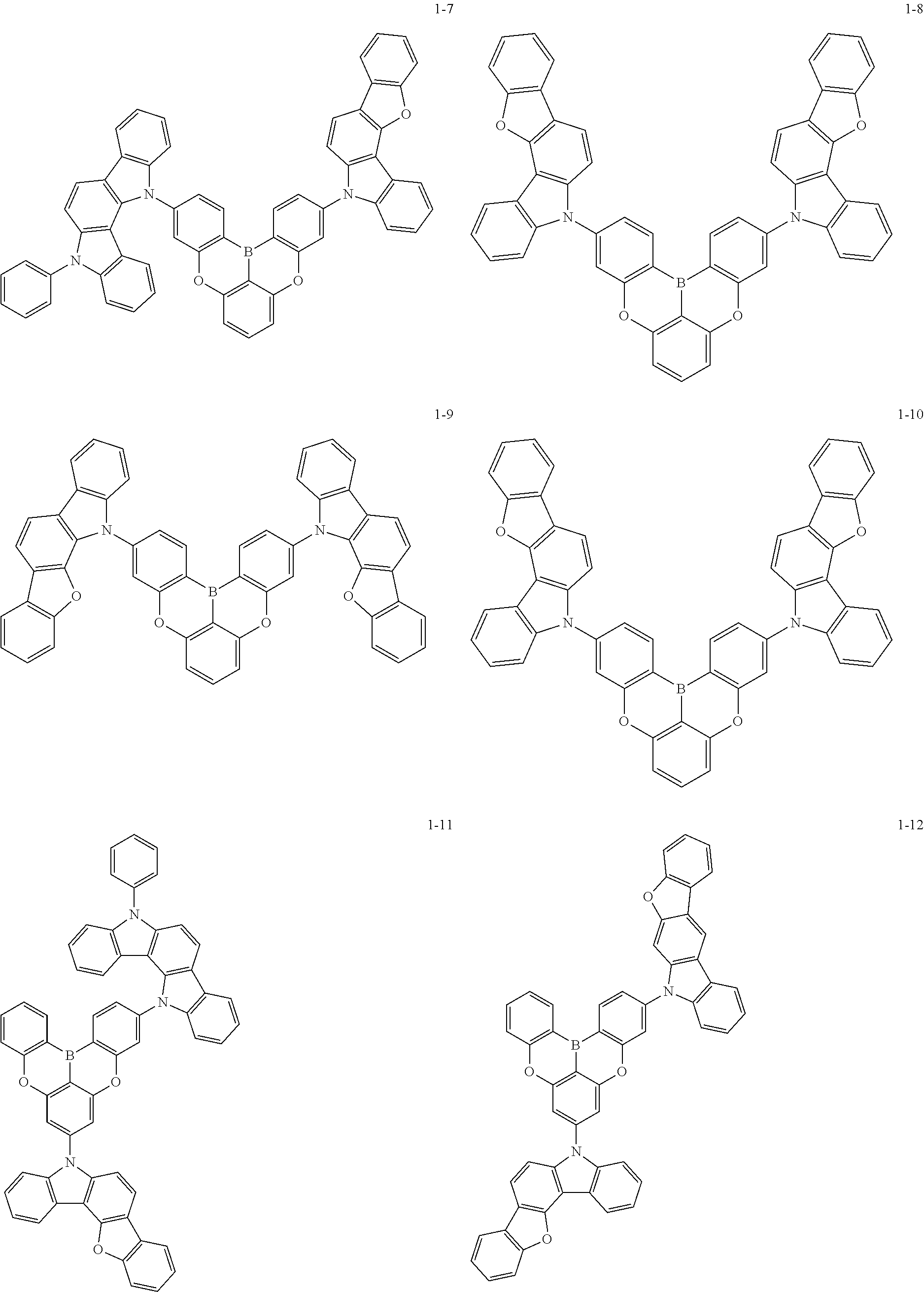

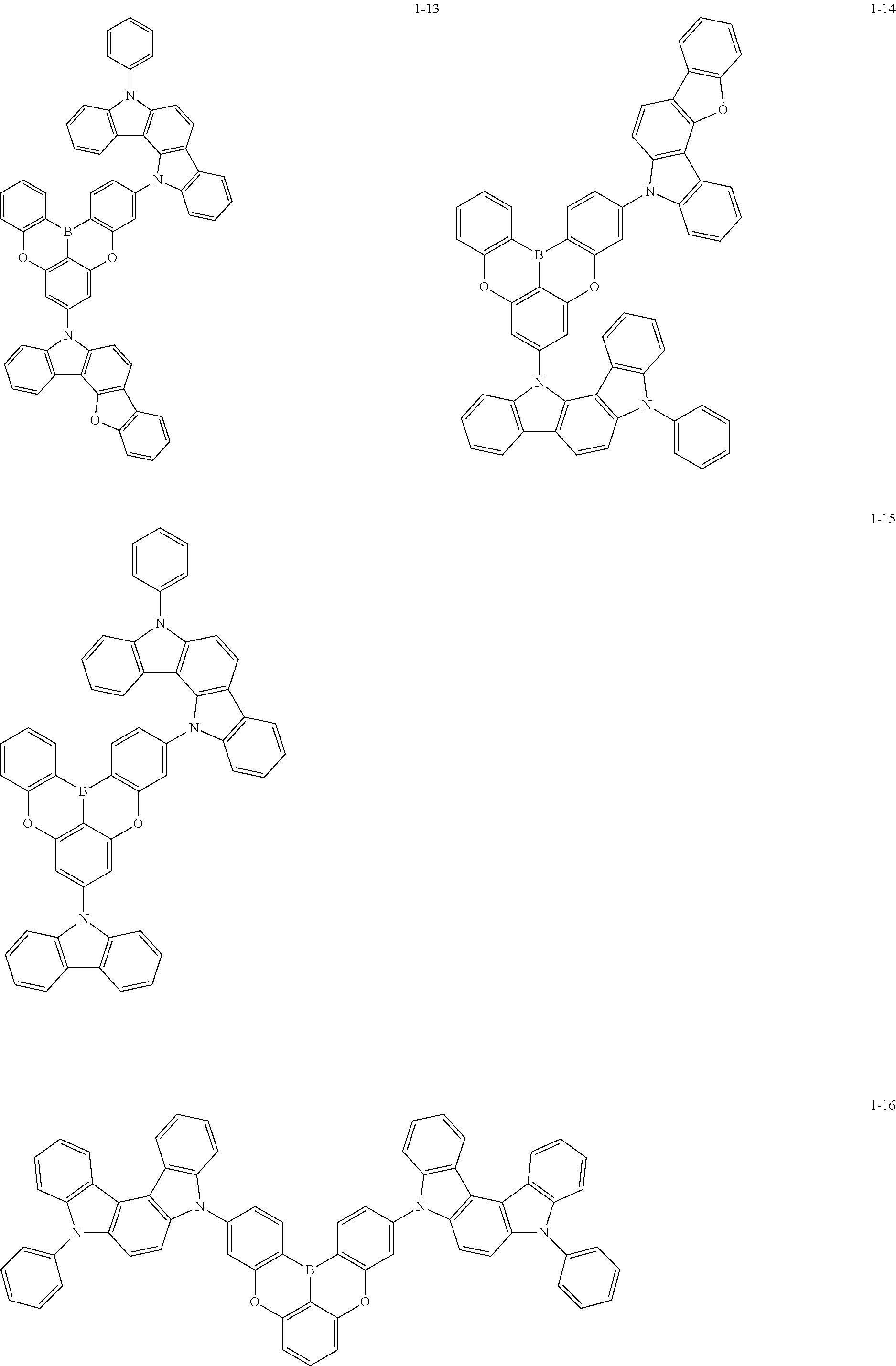 [SMILES: c1ccc(-n2c3ccccc3c3c2ccc2c4ccccc4n(-c4ccc5c(c4)Oc4cc(-n6c7ccccc7c7c8oc9ccccc9c8ccc76)cc6c4B5c4ccccc4O6)c23)cc1 ; c1ccc(-n2c3ccccc3c3c2ccc2c4ccccc4n(-c4cc5c6c(c4)Oc4cc(-n7c8ccccc8c8c9oc%10ccccc%10c9ccc87)ccc4B6c4ccccc4O5)c23)cc1 ; c1ccc(-n2c3ccccc3c3c2ccc2c4ccccc4n(-c4ccc5c(c4)Oc4cc(-n6c7ccccc7c7ccccc76)cc6c4B5c4ccccc4O6)c23)cc1 ; c1ccc(-n2c3ccccc3c3c4c5ccccc5n(-c5ccc6c(c5)Oc5cccc7c5B6c5ccc(-n6c8ccccc8c8c9c%10ccccc%10n(-c%10ccccc%10)c9ccc86)cc5O7)c4ccc32)cc1]

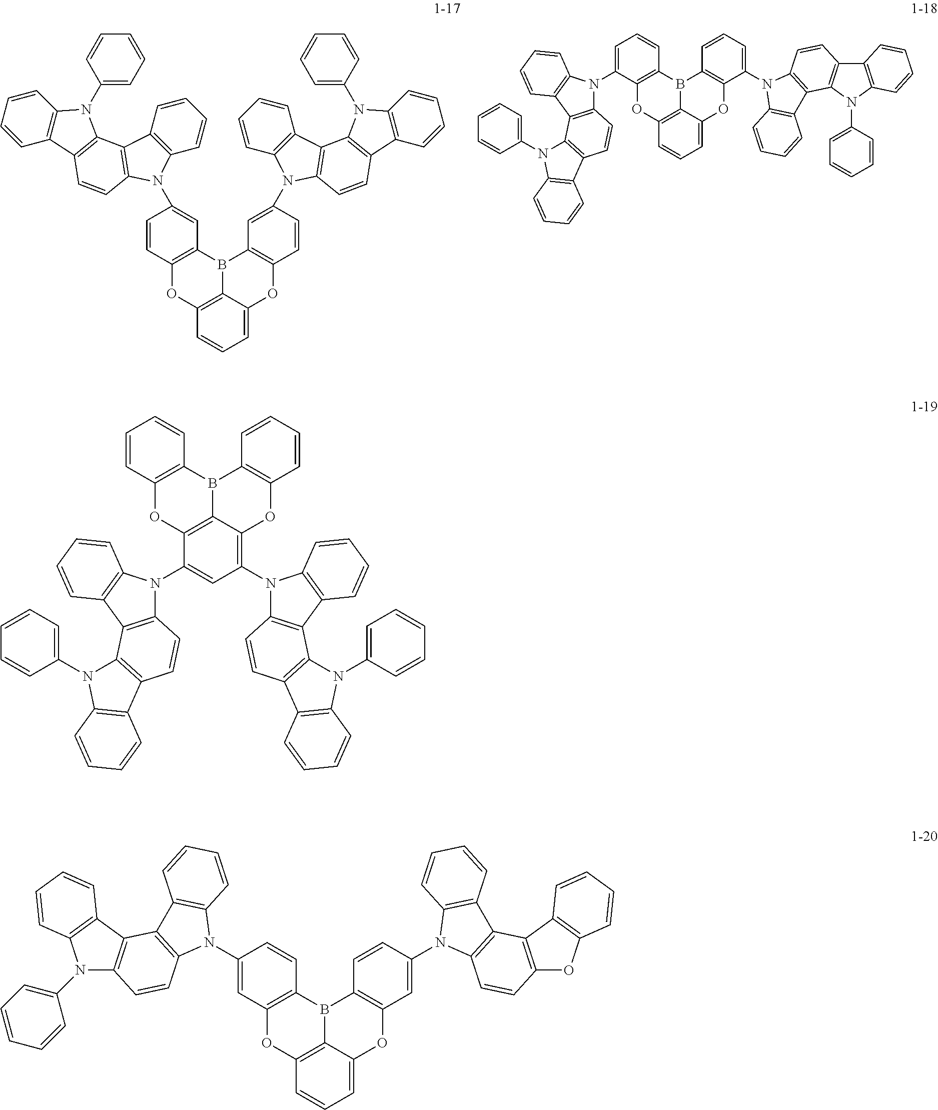

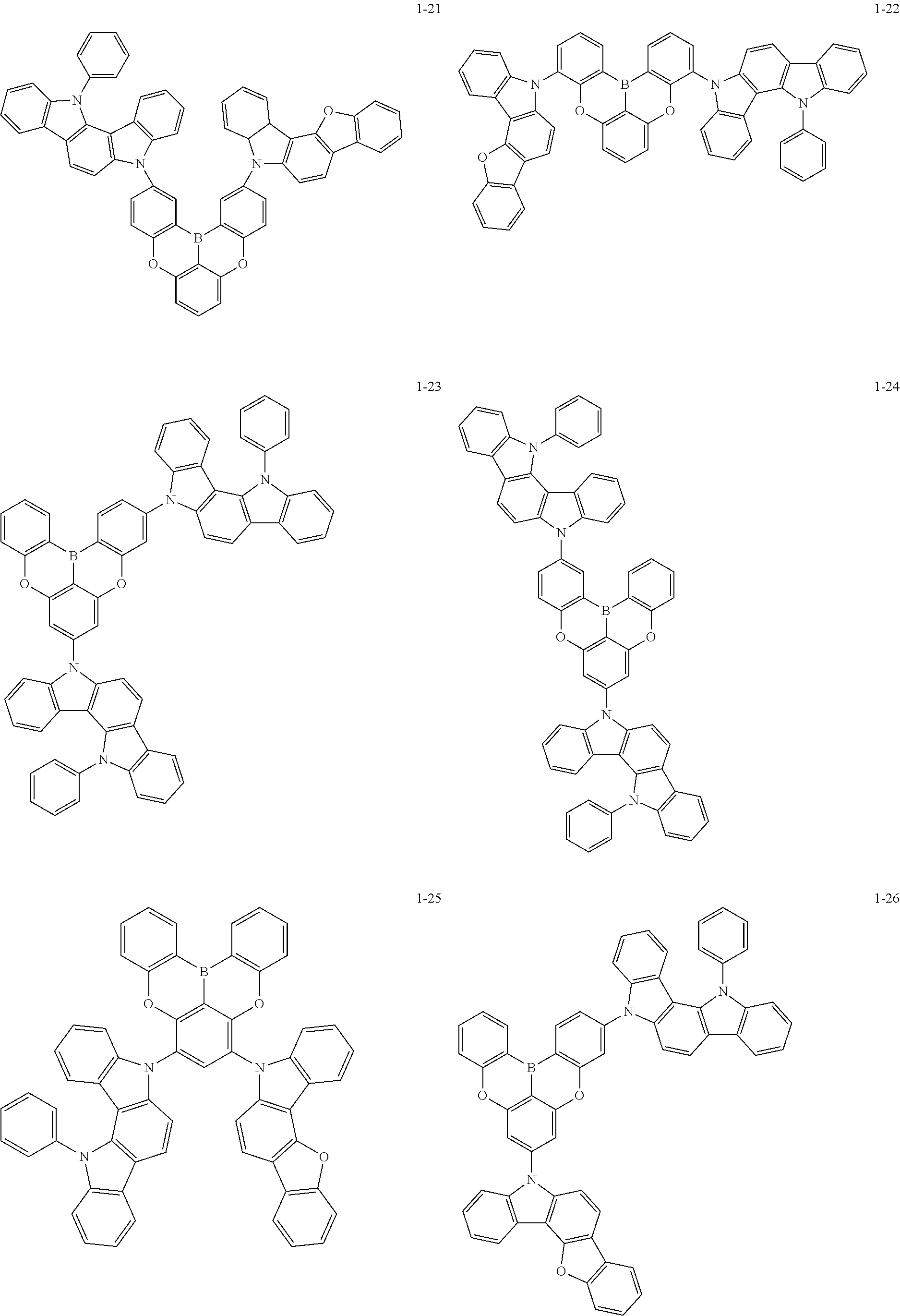

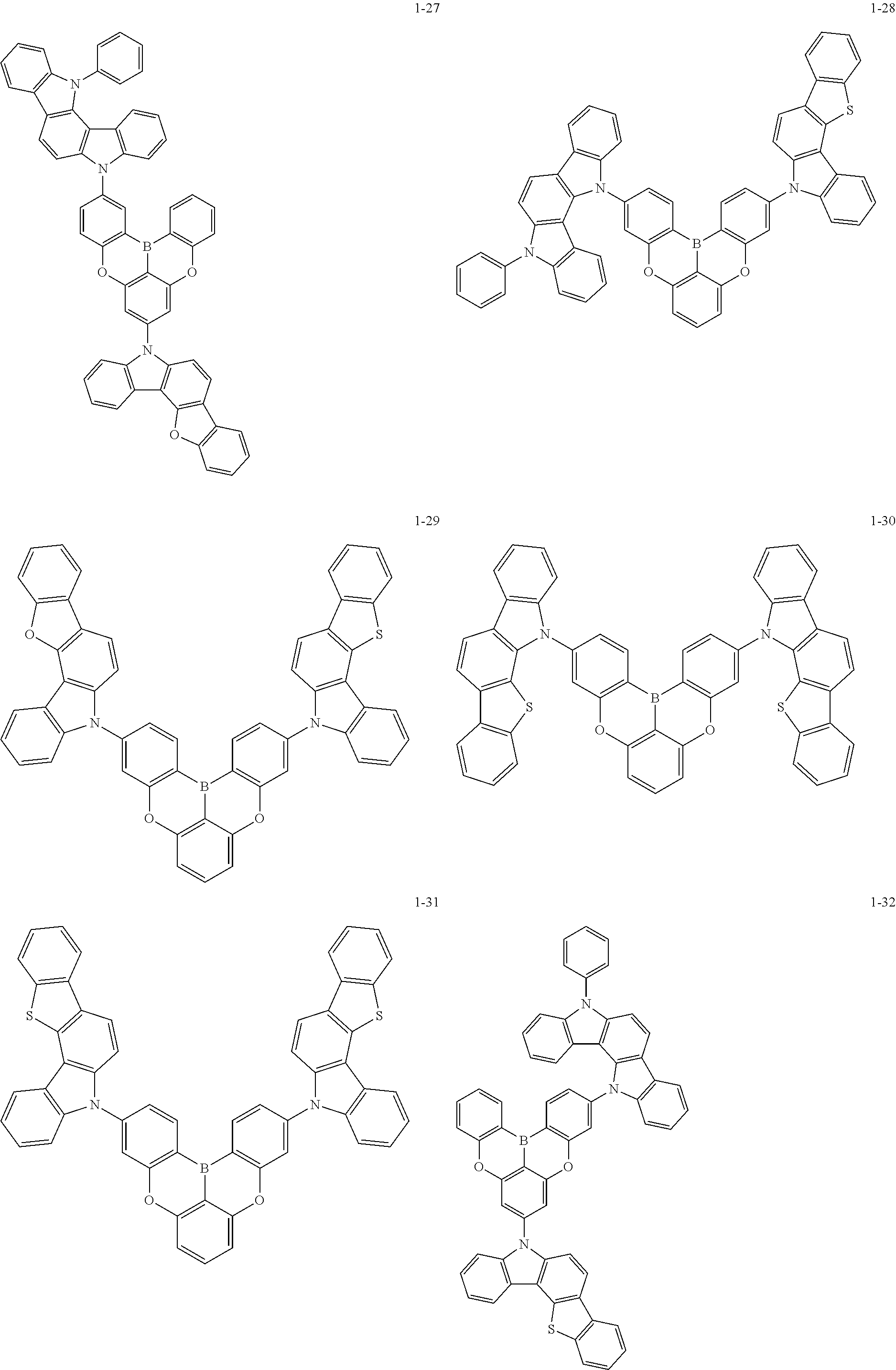

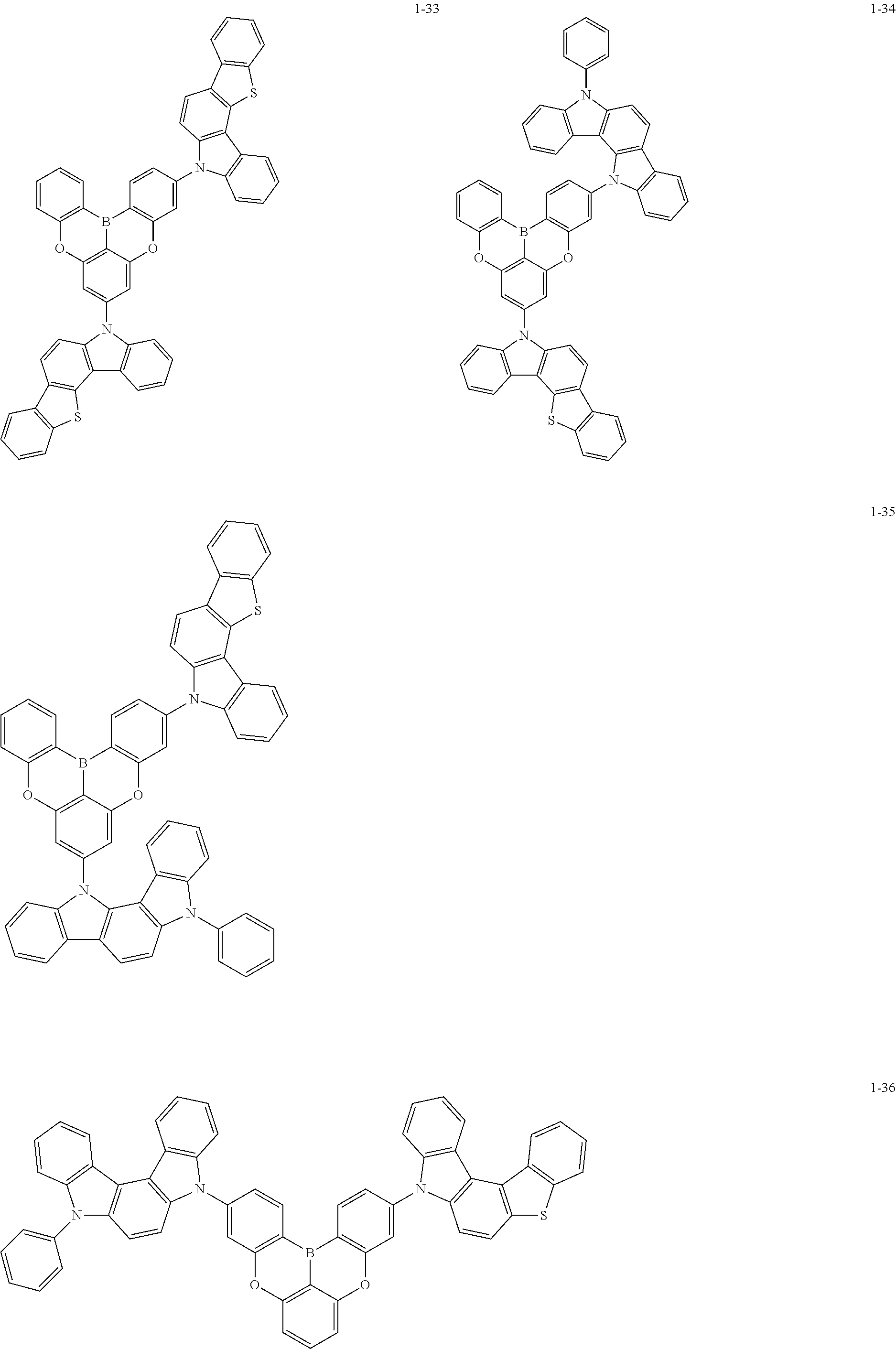 [SMILES: c1ccc2c(c1)Oc1cc(-n3c4ccccc4c4c5sc6ccccc6c5ccc43)cc3c1B2c1ccc(-n2c4ccccc4c4c5sc6ccccc6c5ccc42)cc1O3 ; c1ccc(-n2c3ccccc3c3c2ccc2c4ccccc4n(-c4ccc5c(c4)Oc4cc(-n6c7ccccc7c7c8sc9ccccc9c8ccc76)cc6c4B5c4ccccc4O6)c23)cc1 ; c1ccc(-n2c3ccccc3c3c2ccc2c4ccccc4n(-c4cc5c6c(c4)Oc4cc(-n7c8ccccc8c8c9sc%10ccccc%10c9ccc87)ccc4B6c4ccccc4O5)c23)cc1 ; c1ccc(-n2c3ccccc3c3c4c5ccccc5n(-c5ccc6c(c5)Oc5cccc7c5B6c5ccc(-n6c8ccccc8c8c9c(ccc86)sc6ccccc69)cc5O7)c4ccc32)cc1]

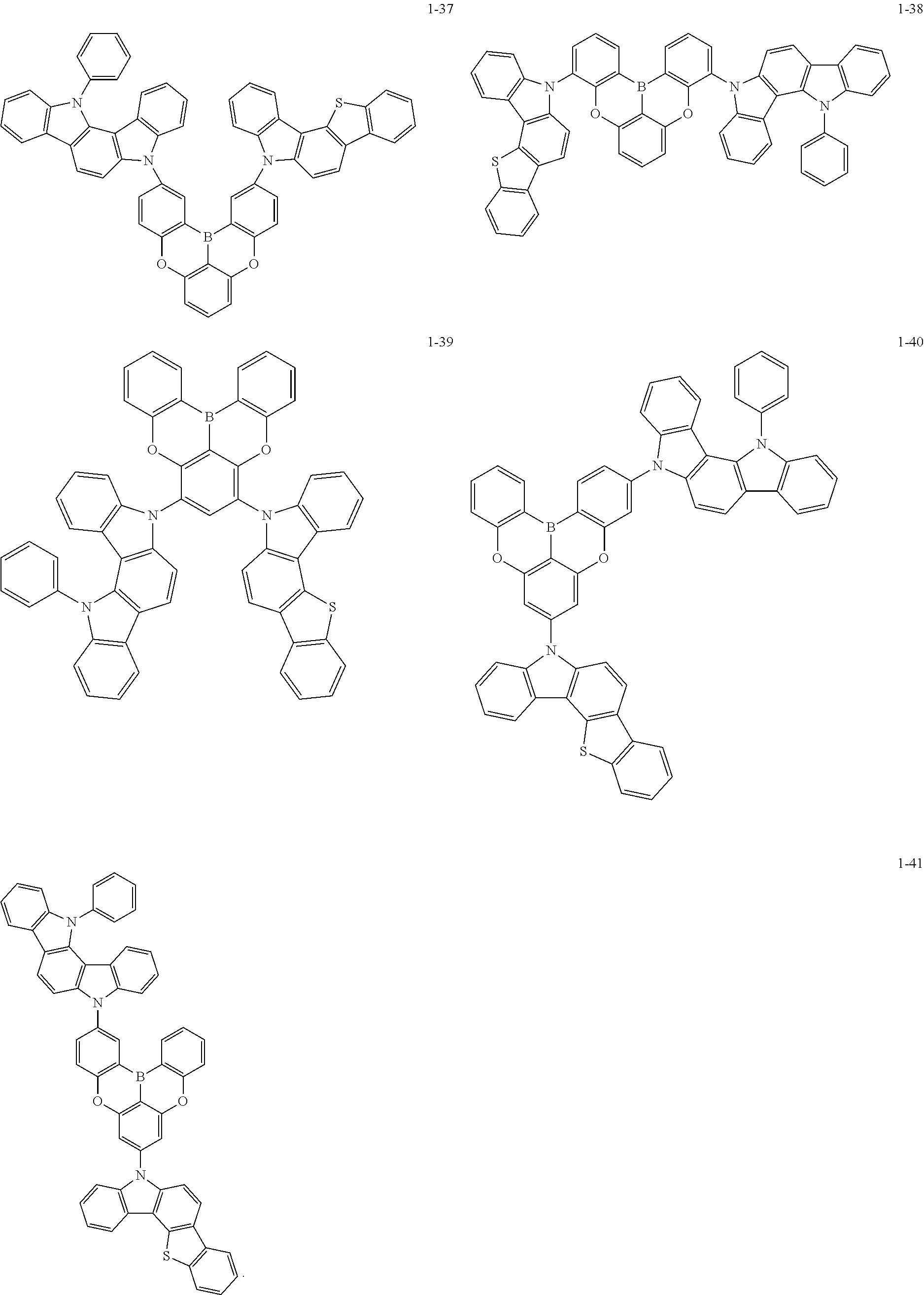

5. The organic light emitting diode of claim 1, wherein the second compound comprises an organic compound having the following structure of Formula 8A to 8C: 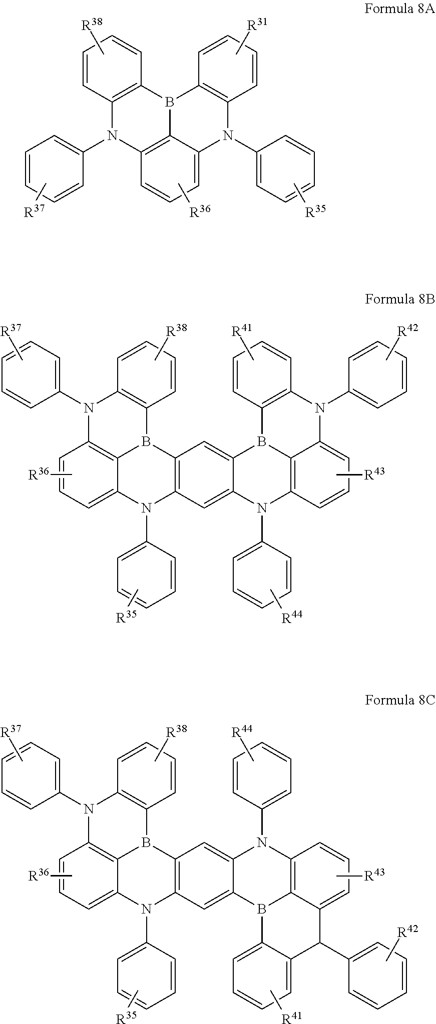
wherein, in Formulae 8A to 8C,
each of R³¹, R³⁵ to R³⁸ and R⁴¹ to R⁴⁴ is independently hydrogen, deuterium, tritium, halogen, unsubstituted or substituted C₁-C₂₀ alkyl, unsubstituted or substituted C₁-C₂₀ alkyl silyl, unsubstituted or substituted C₁-C₂₀ alkyl amino, unsubstituted or substituted C₆-C₃₀ aryl or unsubstituted or substituted C₃-C₃₀ hetero aryl.

6. The organic light emitting diode of claim 1, wherein the second compound is selected from:

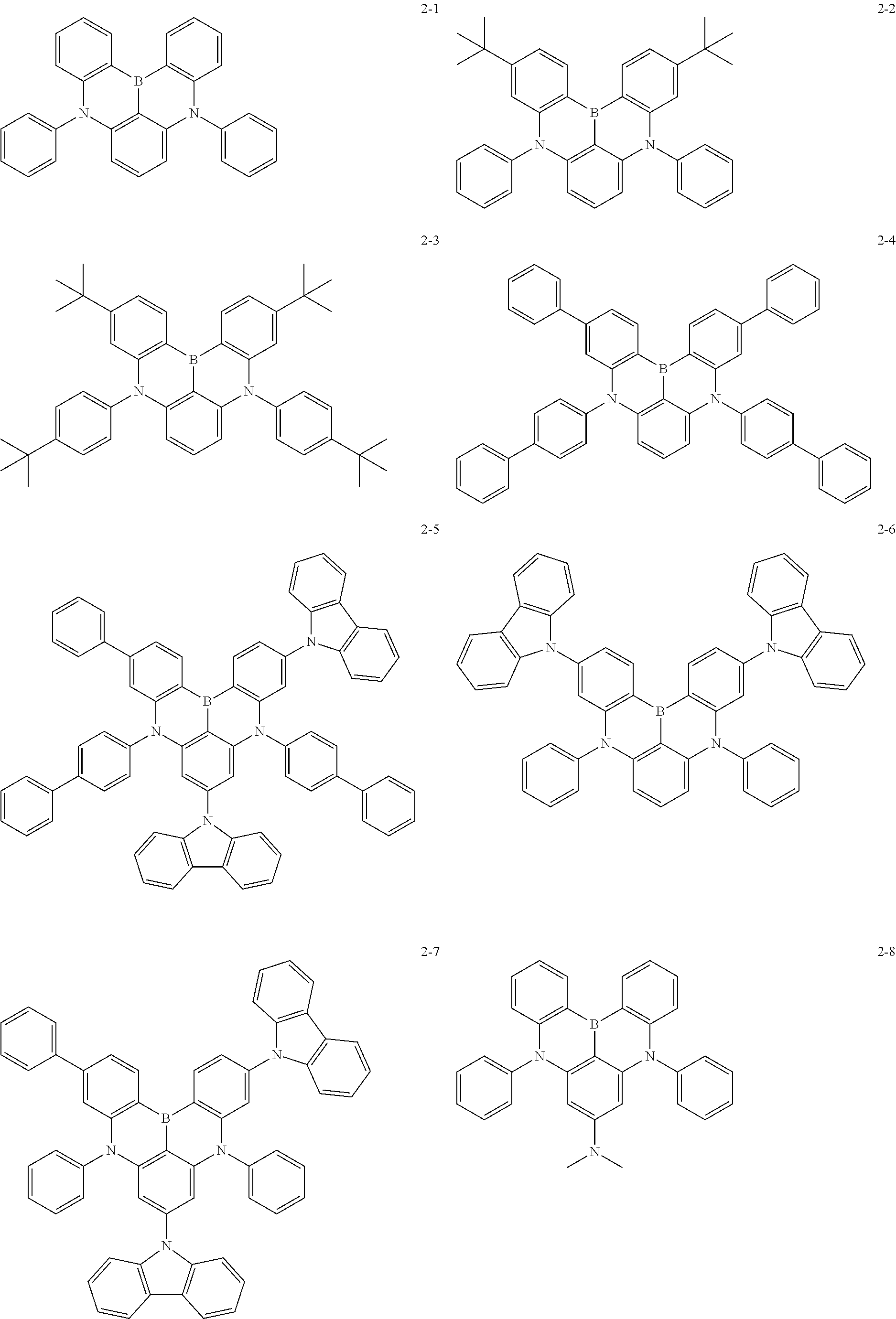

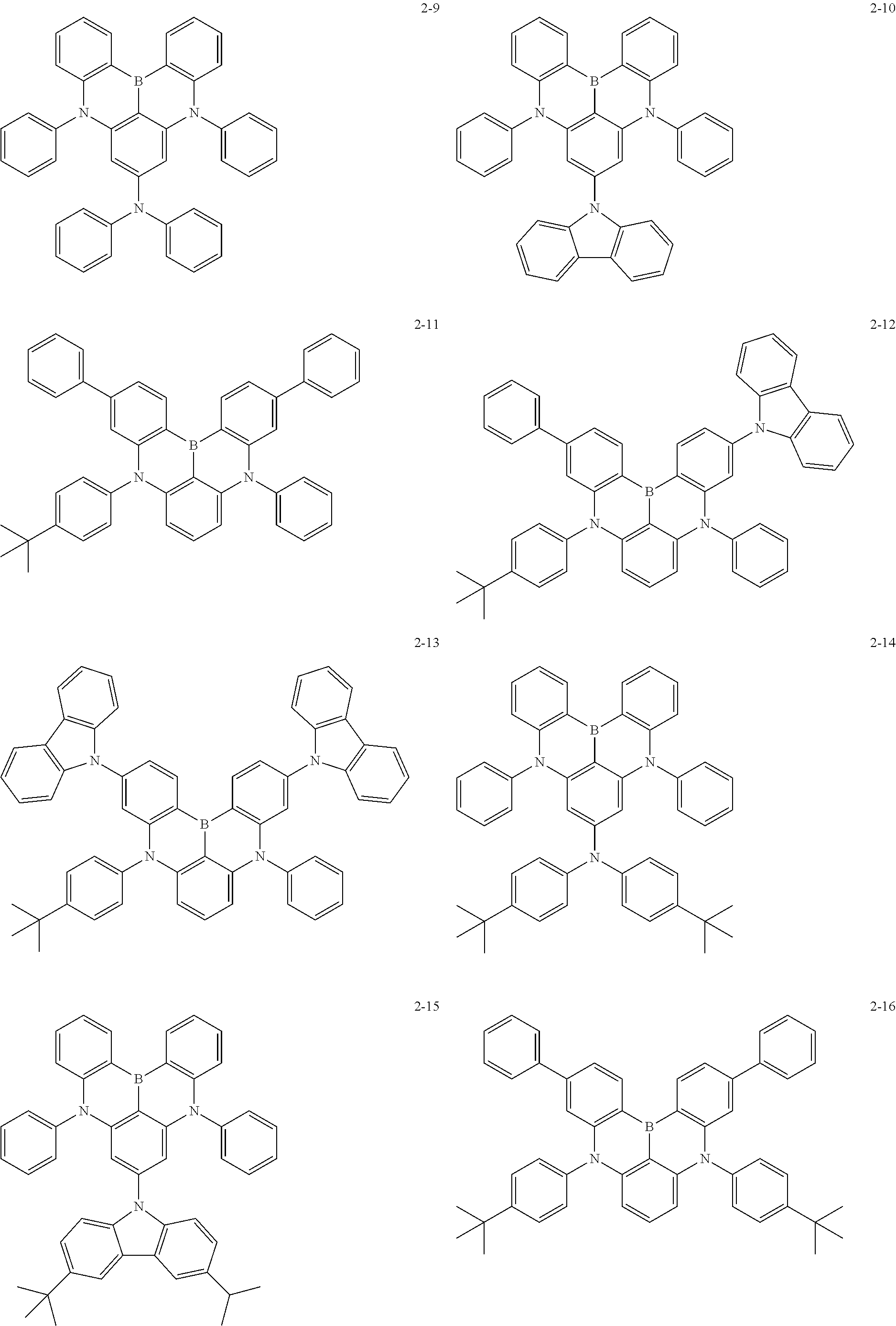

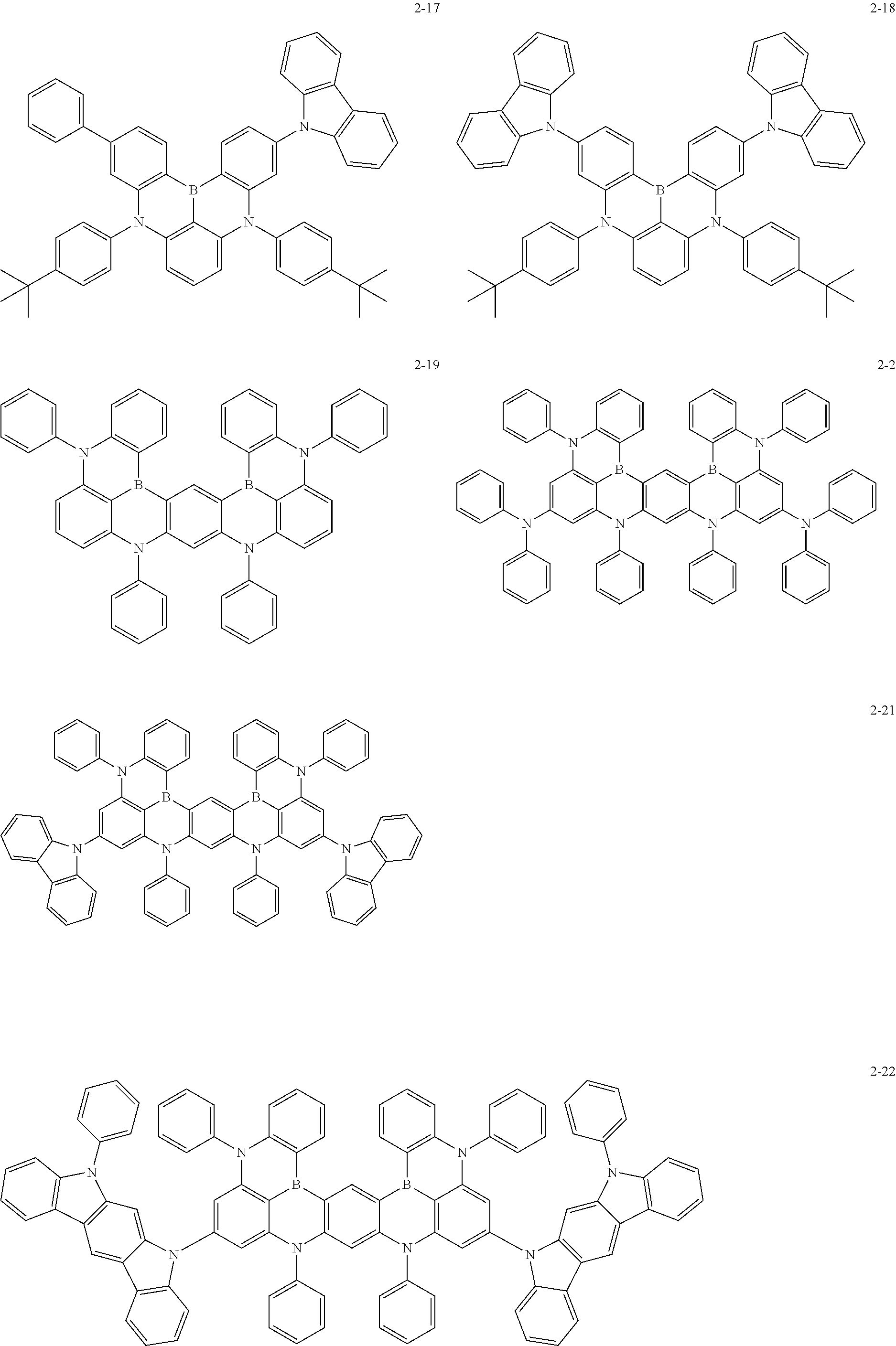

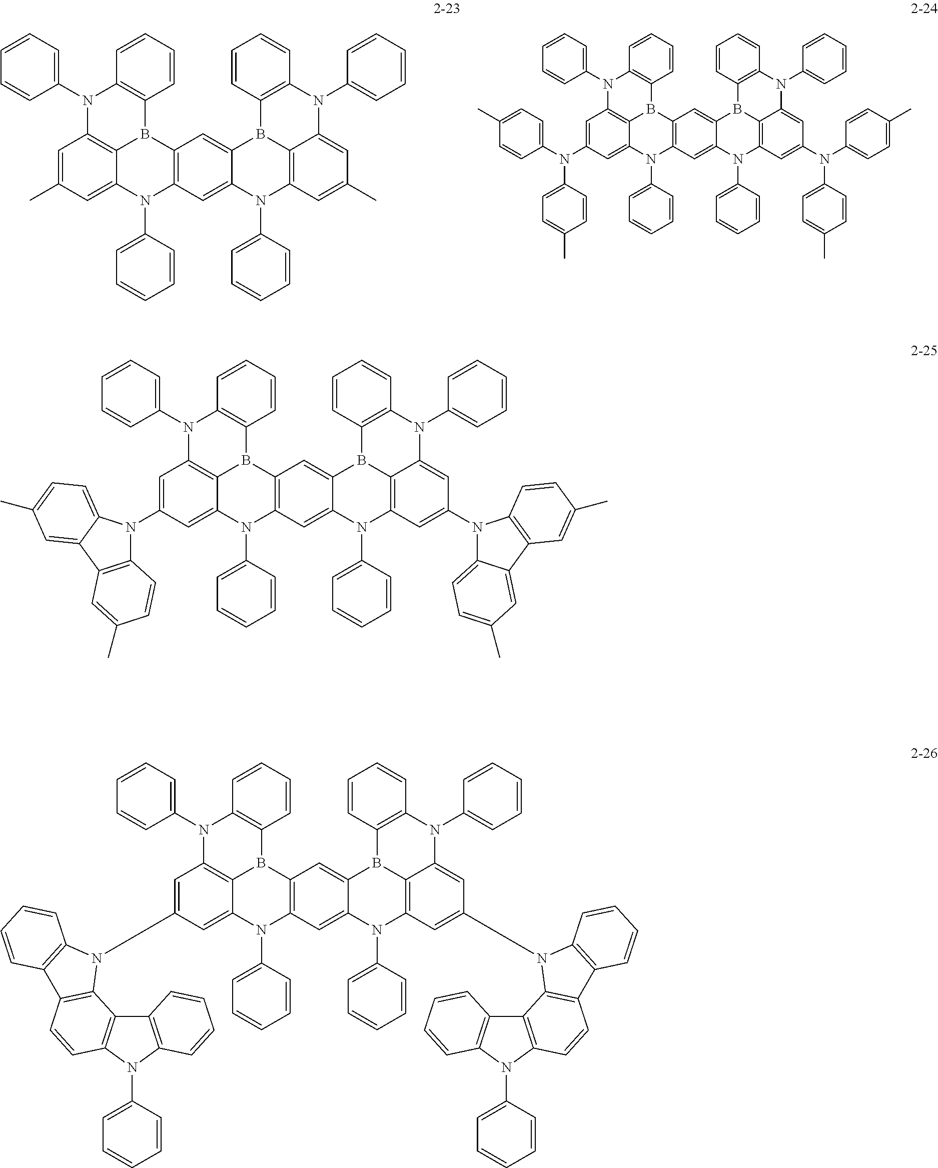

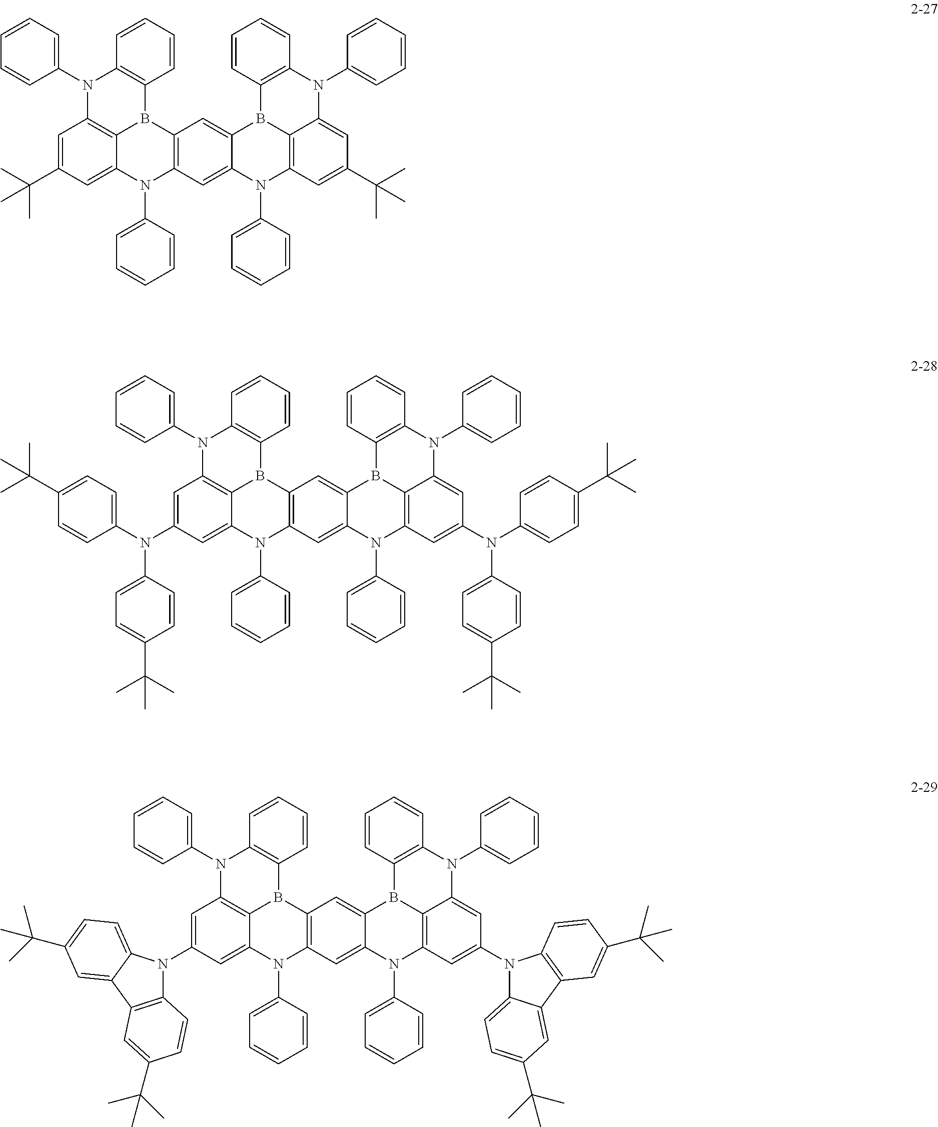

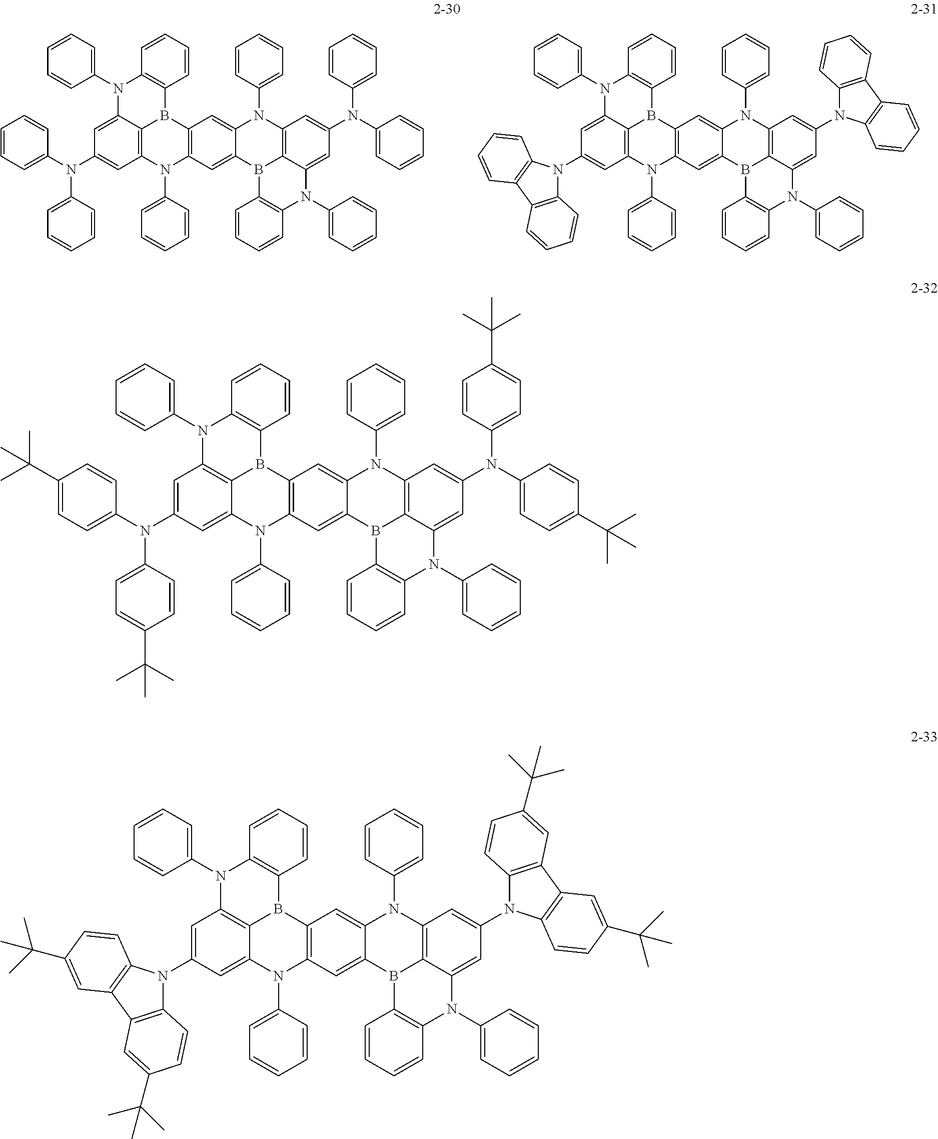

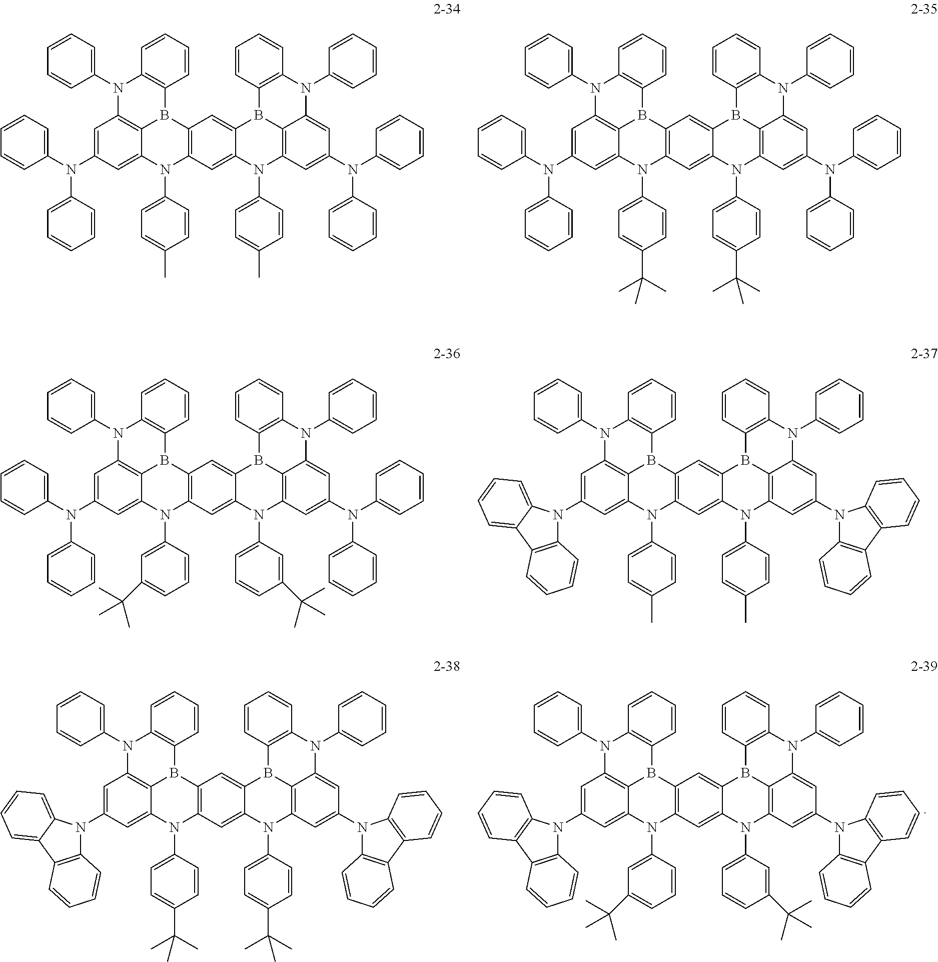

7. The organic light emitting diode of claim 1, wherein the at least one emitting material layer comprises a single-layered emitting material layer.

8. The organic light emitting diode of claim 7, the single-layered emitting material layer further comprises a third compound.

9. The organic light emitting diode of claim 8, wherein the single-layered emitting material layer comprises the first compound of about 10 to about 40% by weight, the second compound of about 0.1 to about 5% by weight and the third compound of about 55 to about 85% by weight.

10. The organic light emitting diode of claim 1, wherein the at least one emitting material layer comprises a first emitting material layer disposed between the first and second electrodes and a second emitting material layer disposed between the first electrode and the first emitting material layer or between the first emitting material layer and the second electrode, and
wherein the first emitting material layer comprises the first compound and the second emitting material layer comprises the second compound.

11. The organic light emitting diode of claim 10, wherein the first emitting material layer further comprises a third compound and the second emitting material layer further comprises a fourth compound.

12. The organic light emitting diode of claim 10, wherein the at least one emitting material layer further comprises a third emitting material layer disposed oppositely to the second emitting material layer with respect to the first emitting material layer.

13. The organic light emitting diode of claim 12, wherein the third emitting material layer comprises a fifth compound and a sixth compound, and wherein the fifth compound comprises the organic compound having the structure of Formula 7.

14. The organic light emitting diode of claim 1, wherein the emissive layer comprises a first emitting part disposed between the first and second electrodes, a second emitting part disposed between the first emitting part and the second electrode and a charge generation layer disposed between the first and second emitting parts, and
wherein at least one of the first emitting part and the second emitting part comprises the at least one emitting material layer.

15. The organic light emitting diode of claim 14, wherein the first emitting part comprises the at least one emitting material layer, and the second emitting part emits at least one of red light and green light.

16. The organic light emitting diode of claim 14, wherein the emissive layer further comprises a third emitting part disposed between the second emitting part and the second electrode and a second charge generation layer disposed between the second and third emitting part, and wherein at least one of the first emitting part and the third emitting part comprises the at least one emitting material layer.

17. An organic light emitting device, comprising:
a substrate; and
the organic light emitting diode according to claim 1 and disposed over the substrate.

18. An organic light emitting display device, comprising:
a substrate; and
a display comprising an array of pixels on the substrate,
wherein each pixel comprises one or more individually addressable organic light emitting diodes according to claim 1.

19. The organic light emitting diode of claim 1, wherein in Formula 1, each of R⁴ to R⁶ is independently hydrogen, deuterium, or tritium.

20. The organic light emitting diode of claim 1, wherein in Formula 1, at least two of R², R⁵ and R⁸ is a moiety having the structure of Formula 2, R⁴ and R⁶ are each independently a moiety having the structure of Formula 2, R² and R⁸ are each independently a moiety having the structure of Formula 2, R² and R⁵ are each independently a moiety having the structure of Formula 2, or R⁵ and R⁸ are each independently a moiety having the structure of Formula 2.

21. The organic light emitting diode of claim 1, wherein in Formula 7, each of R³¹ to R³⁸ is independently hydrogen, deuterium, tritium, halogen, or an unsubstituted or substituted C₁-C₈ alkyl.

22. The organic light emitting diode of claim 1, wherein in Formula 7, at least two of R³¹ to R³⁸ is independently an unsubstituted or substituted C₁-C₂₀ alkyl amino, an unsubstituted or substituted C₆-C₃₀ aromatic group or an unsubstituted or substituted C₃-C₃₀ hetero aromatic group.

23. The organic light emitting diode of claim 1, wherein in Formula 7, at least two of R³¹ to R³⁸ is independently an unsubstituted or substituted carbazole.
